(19) United States
(12) Patent Application Publication
(10) Pub. No.: US 2026/0090197 A1
(43) Pub. Date: Mar. 26, 2026

(54) ORGANIC OPTOELECTRONIC DEVICE AND DISPLAY DEVICE

(71) Applicant: SAMSUNG SDI CO., LTD., Yongin-si (KR)

(72) Inventors: Youngkyoung JO, Suwon-si (KR); Youngmook LIM, Suwon-si (KR); Kyoungrok KIM, Suwon-si (KR); Jongwoo WON, Suwon-si (KR); Sunwoong SHIN, Suwon-si (KR); Gibeom PARK, Suwon-si (KR); Junghoon KIM, Suwon-si (KR); Bongyong KIM, Suwon-si (KR); Ho Kuk JUNG, Suwon-si (KR)

(21) Appl. No.: 19/332,276

(22) Filed: Sep. 18, 2025

(30) Foreign Application Priority Data
Sep. 24, 2024 (KR) 10-2024-0129242

(51) Int. Cl. H10K 50/15; H10K 85/60; H10K 101/00

(52) U.S. Cl. CPC H10K 50/156; H10K 85/622; H10K 85/626; H10K 85/633; H10K 85/636; H10K 85/654; H10K 85/656; H10K 85/6572; H10K 85/6574; H10K 85/6576; H10K 2101/90

(57) ABSTRACT

An organic optoelectronic device, including an anode and a cathode facing each other, a light emitting layer between the anode and the cathode, a hole transport layer between the anode and the light emitting layer, and a hole transport auxiliary layer between the light emitting layer and the hole transport layer, wherein the light emitting layer includes a first compound represented by Chemical Formula 1 and a second compound represented by Chemical Formula 2, and the hole transport auxiliary layer includes a third compound represented by Chemical Formula 3 and a display device comprising the organic optoelectronic device.

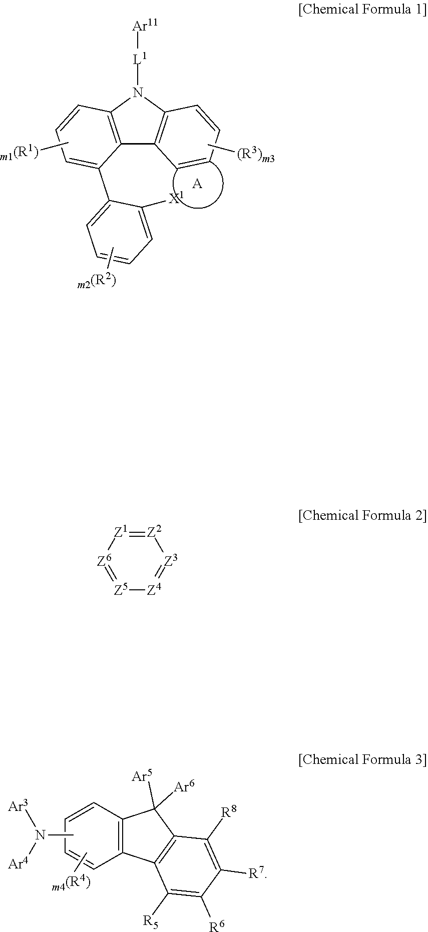

### CROSS-REFERENCE TO RELATED APPLICATION

This application claims priority to and the benefit of Korean Patent Application No. 10-2024-0129242 filed in the Korean Intellectual Property Office on Sep. 24, 2024, the entire contents of which are incorporated herein by reference.

### BACKGROUND

### 1. Field

Embodiments relate to an organic optoelectronic device and a display device.

### 2. Description of the Related Art

An organic optoelectronic device (e.g., organic optoelectronic diode) is a device capable of converting electrical energy and optical energy to each other.

Organic optoelectronic devices may be divided into two types according to a principle of operation. One is a photoelectric device that generates electrical energy by separating excitons formed by light energy into electrons and holes, and transferring the electrons and holes to different electrodes, respectively and the other is light emitting device that generates light energy from electrical energy by supplying voltage or current to the electrodes.

Examples of the organic optoelectronic device may include an organic photoelectric device, an organic light emitting diode, an organic solar cell, and an organic photoconductor drum.

Among them, organic light emitting diodes (OLEDs) are attracting much attention in recent years due to increasing demands for flat panel display devices. The organic light emitting diode is a device that converts electrical energy into light, and the performance of the organic light emitting diode may be influenced by an organic material between electrodes.

### SUMMARY

The embodiments may be realized by providing an organic optoelectronic device, including an anode and a cathode facing each other, a light emitting layer between the anode and the cathode, a hole transport layer between the anode and the light emitting layer, and a hole transport auxiliary layer between the light emitting layer and the hole transport layer wherein the light emitting layer includes a first compound represented by Chemical Formula 1 and a second compound represented by Chemical Formula 2, and the hole transport auxiliary layer includes a third compound represented by Chemical Formula 3:

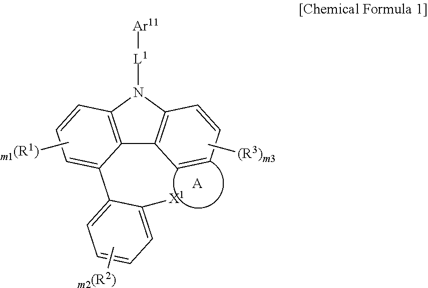

wherein, in Chemical Formula 1, A is a substituted or unsubstituted benzene ring or a substituted or unsubstituted indole ring, X¹ is C or N, L¹ is a single bond or a substituted or unsubstituted C6 to C20 arylene group, R¹ to R³ are each independently hydrogen, deuterium, a cyano group, a halogen, a substituted or unsubstituted amine group, a substituted or unsubstituted C1 to C30 alkyl group, a substituted or unsubstituted C6 to C30 aryl group, or a substituted or unsubstituted C2 to C30 heterocyclic group, m1 is an integer of 1 to 3, m2 is an integer of 1 to 4, m3 is an integer of 1 or 2, when m1 is 2 or 3, each R¹ is the same or different from each other, when m2 is 2, 3, or 4, each R² is the same or different from each other, when m3 is 2, each R³ is the same or different from each other, and Ar¹¹ is a substituted or unsubstituted aryl group, a substituted or unsubstituted heterocyclic group, or an amine group represented by Chemical Formula a,

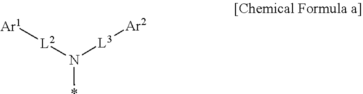

wherein, in Chemical Formula a, L² and L³ are each independently a single bond or a substituted or unsubstituted C6 to C20 arylene group, Ar¹ and Ar² are each independently a substituted or unsubstituted C6 to C20 aryl group or a substituted or unsubstituted C2 to C30 heterocyclic group;

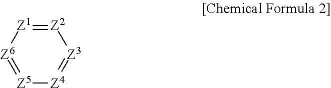

wherein, in Chemical Formula 2, Z¹ to Z⁶ are each independently N or C-L^{a}-R^{a}, provided that at least two of Z¹ to Z⁶ are N, each L^{a} is independently a single bond, a substituted or unsubstituted C6 to C20 arylene group, a substituted or unsubstituted C2 to C20 heterocyclic group, or a combination thereof, each R^{a} is independently hydrogen, deuterium, a cyano group, a halogen, a substituted or unsubstituted C1 to C30 alkyl group, a substituted or unsubstituted C6 to C30 aryl group, or a substituted or unsubstituted C2 to C30 heterocyclic group, a substituted or unsubstituted silyl group, a substituted or unsubstituted amine group, or a combination thereof, and each R^{a} is separately present or adjacent groups thereof are linked to each other to form a substituted or unsubstituted aliphatic monocyclic or polycyclic ring, a substituted or unsubstituted aromatic monocyclic or polycyclic ring, or a substituted or unsubstituted heteroaromatic monocyclic or polycyclic ring;

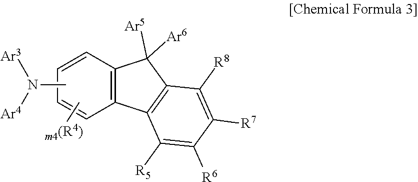

wherein, in Chemical Formula 3, Ar³ and Ar⁴ are each independently a substituted or unsubstituted C6 to C30 aryl group or a substituted or unsubstituted C2 to C30 heterocyclic group, Ar⁵ and Ar⁶ are each independently a substituted or unsubstituted C1 to C30 alkyl group or a substituted or unsubstituted C6 to C30 aryl group, R⁴ to R⁸ are each independently hydrogen, deuterium, a cyano group, a halogen, a substituted or unsubstituted C1 to C30 alkyl group, a substituted or unsubstituted C6 to C30 aryl group, or a substituted or unsubstituted C2 to C30 heterocyclic group, m4 is an integer of 1 to 3, and when m4 is 2 or 3, each R⁴ is the same or different from each other.

The embodiments may be realized by providing a display device including the organic optoelectronic device according to an embodiment.

### BRIEF DESCRIPTION OF THE DRAWING

Features will become apparent to those of skill in the art by describing in detail exemplary embodiments with reference to the attached drawing in which:

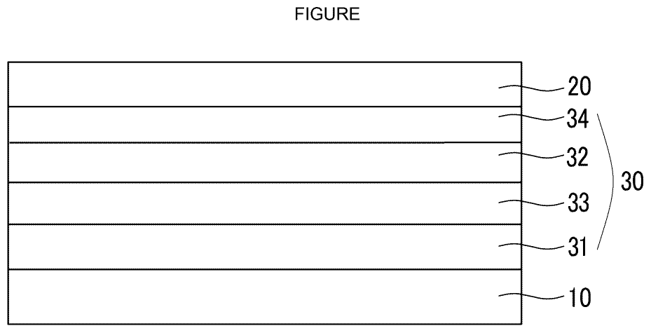

the FIG. 1s a cross-sectional view showing an organic light emitting diode according to some example embodiments.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, or one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, when a definition is not otherwise provided, “substituted” refers to replacement of at least one hydrogen of a substituent or a compound by deuterium, a halogen, a hydroxyl group, an amino group, a substituted or unsubstituted C1 to C30 amine group, a nitro group, a substituted or unsubstituted C1 to C40 silyl group, a C1 to C30 alkyl group, a C1 to C10 alkylsilyl group, a C6 to C30 arylsilyl group, a C3 to C30 cycloalkyl group, a C3 to C30 heterocycloalkyl group, a C6 to C30 aryl group, a C2 to C30 heteroaryl group, a C to C20 alkoxy group, a C1 to C10 trifluoroalkyl group, a cyano group, or a combination thereof.

In one example, the “substituted” refers to replacement of at least one hydrogen of a substituent or a compound by deuterium, a C1 to C30 alkyl group, a C1 to C10 alkylsilyl group, a C6 to C30 arylsilyl group, a C3 to C30 cycloalkyl group, a C3 to C30 heterocycloalkyl group, a C6 to C30 aryl group, a C2 to C30 heteroaryl group, or a cyano group. In a specific example, the “substituted” refers to replacement of at least one hydrogen of a substituent or a compound by deuterium, a C1 to C20 alkyl group, a C3 to C20 cycloalkyl group, a C6 to C30 aryl group, or a cyano group. In a specific example, the “substituted” refers to replacement of at least one hydrogen of a substituent or a compound by deuterium, a C1 to C5 alkyl group, a C3 to C10 cycloalkyl group, a C6 to C18 aryl group, or a cyano group. In a specific example, the “substituted” refers to replacement of at least one hydrogen of a substituent or a compound by deuterium, a cyano group, a methyl group, an ethyl group, a propyl group, a butyl group, a tert-butyl group, a cyclopropyl group, a phenyl group, a biphenyl group, a terphenyl group, or a naphthyl group.

As used herein, “unsubstituted” refers to non-replacement of a hydrogen atom by another substituent and remaining of the hydrogen atom.

As used herein, “hydrogen substitution (—H)” may include “deuterium substitution (-D)” or “tritium substitution (-T).”

As used herein, when a definition is not otherwise provided, “hetero” refers to one including one to three heteroatoms selected from N, O, S, P, and Si, and remaining carbons in one functional group. As used herein, the term “or” is not an exclusive term, e.g., “A or B” would include A, B, or A and B.

As used herein, “aryl group” refers to a group including at least one hydrocarbon aromatic moiety, and all elements of the hydrocarbon aromatic moiety have p-orbitals which form conjugation, for example a phenyl group, a naphthyl group, and the like, two or more hydrocarbon aromatic moieties may be linked by a sigma bond and may be, for example a biphenyl group, a terphenyl group, a quarterphenyl group, and the like, and two or more hydrocarbon aromatic moieties may be fused directly or indirectly to provide a non-aromatic fused ring, for example a fluorenyl group.

The aryl group may include a monocyclic, polycyclic, or fused ring polycyclic (i.e., rings sharing adjacent pairs of carbon atoms) functional group.

As used herein, “heterocyclic group” is a generic concept of a heteroaryl group, and may include at least one heteroatom selected from N, O, S, P, and Si instead of carbon (C) in a cyclic compound such as aryl group, a cycloalkyl group, a fused ring thereof, or a combination thereof. When the heterocyclic group is a fused ring, the entire ring or each ring of the heterocyclic group may include one or more heteroatoms.

For example, “heteroaryl group” may refer to aryl group including at least one heteroatom selected from N, O, S, P, and Si. Two or more heteroaryl groups may be linked by a sigma bond directly, or when the heteroaryl group includes two or more rings, the two or more rings may be fused. When the heteroaryl group is a fused ring, each ring may include one to three heteroatoms.

More specifically, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted triphenylene group, a substituted or unsubstituted perylenyl group, a substituted or unsubstituted fluorenyl group, a substituted or unsubstituted indenyl group, or a combination thereof.

More specifically, the substituted or unsubstituted C2 to C30 heterocyclic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted carbazolyl group, a substituted or unsubstituted dibenzofuranyl group, or a substituted or unsubstituted dibenzothiophenyl group, or a combination thereof.

As used herein, hole characteristics refer to an ability to donate an electron to form a hole when an electric field is applied and that a hole formed in the anode may be easily injected into the light emitting layer and transported in the light emitting layer due to conductive characteristics according to a highest occupied molecular orbital (HOMO) level.

In addition, electron characteristics refer to an ability to accept an electron when an electric field is applied and that electron formed in the cathode may be easily injected into the light emitting layer and transported in the light emitting layer due to conductive characteristics according to a lowest unoccupied molecular orbital (LUMO) level.

Hereinafter, an organic optoelectronic device according to some example embodiments is described.

The organic optoelectronic device may be a suitable device to convert electrical energy into photoenergy and vice versa, e.g., an organic photoelectric device, an organic light emitting diode, an organic solar cell, or an organic photoconductor drum.

Herein, an organic light emitting diode as one example of an organic optoelectronic device is described, but embodiments may be applied to other organic optoelectronic devices in the same way.

The FIG. 1s a cross-sectional view showing an organic optoelectronic device according to some example embodiments.

Referring to the FIGURE, an organic optoelectronic device according to one embodiment may include, e.g., an anode 10 and a cathode 20 facing each other, and an organic layer 30 between the anode 10 and the cathode 20.

The anode 10 may be made of a conductor having a large work function to help hole injection, and may be, e.g., a metal, a metal oxide, or a conductive polymer. The anode 10 may be, e.g., a metal such as nickel, platinum, vanadium, chromium, copper, zinc, gold, or the like or an alloy thereof; a metal oxide such as zinc oxide, indium oxide, indium tin oxide (ITO), indium zinc oxide (IZO), or the like; a combination of a metal and an oxide such as ZnO and Al or SnO₂ and Sb; a conductive polymer such as poly(3-methylthiophene), poly(3,4-(ethylene-1,2-dioxy)thiophene) (PEDOT), polypyrrole, or polyaniline.

The cathode 20 may be made of a conductor having a small work function to help electron injection, and may be, e.g., a metal, a metal oxide, or a conductive polymer. The cathode 20 may be, e.g., a metal such as magnesium, calcium, sodium, potassium, titanium, indium, yttrium, lithium, gadolinium, aluminum, silver, tin, lead, cesium, barium, or the like, or an alloy thereof; a multi-layer structure material such as LiF/Al, LiO₂/Al, LiF/Ca, or BaF₂/Ca.

The organic layer 30 may include, e.g., a hole transport layer 31, a light emitting layer 32, and a hole transport auxiliary layer 33 between the hole transport layer 31 and the light emitting layer 32.

The hole transport layer 31 is a layer for facilitating hole transfer from the anode 10 to the light emitting layer 32, and may include, e.g., an amine compound.

The amine compound may include, e.g., at least one aryl group or heteroaryl group. The amine compound may be, e.g., represented by Chemical Formula a or Chemical Formula b.

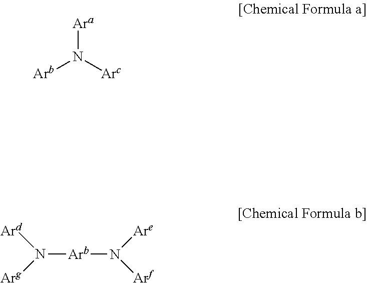

In Chemical Formula a or b, Ar^{a} to Ar^{g} may each independently be, e.g., hydrogen, deuterium, a substituted or unsubstituted C1 to C20 alkyl group, a substituted or unsubstituted C6 to C30 aryl group, a substituted or unsubstituted C2 to C30 heteroaryl group, or a combination thereof.

In an implementation, at least one of Ar^{a} to Ar^{c} and at least one of Ar^{d} to Ar^{g} may be, e.g., a substituted or unsubstituted C6 to C30 aryl group, a substituted or unsubstituted C2 to C30 heteroaryl group, or a combination thereof.

Ar^{h} may be, e.g., a single bond, a substituted or unsubstituted C1 to C20 alkylene group, a substituted or unsubstituted C6 to C30 arylene group, a substituted or unsubstituted C2 to C30 heteroarylene group, or a combination thereof.

The light emitting layer 32 may include, e.g., at least two types of hosts and dopants. The host may include, e.g., a first compound having bipolar characteristics with relatively strong hole characteristics and a second compound having bipolar characteristics with relatively strong electron characteristics.

The first compound may be a compound having relatively strong bipolar characteristics and may be represented by Chemical Formula 1.

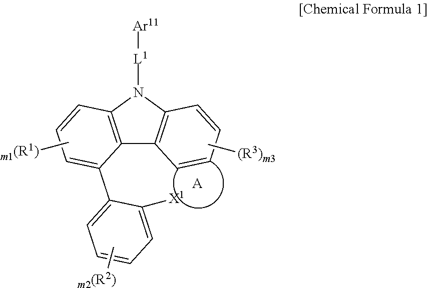

In Chemical Formula 1, A may be, e.g., a substituted or unsubstituted benzene ring or a substituted or unsubstituted indole ring.

X¹ may be, e.g., C or N.

L¹ may be, e.g., a single bond or a substituted or unsubstituted C6 to C20 arylene group.

R¹ to R³ may each independently be or include, e.g., hydrogen, deuterium, a cyano group, a halogen, a substituted or unsubstituted amine group, a substituted or unsubstituted C1 to C30 alkyl group, a substituted or unsubstituted C6 to C30 aryl group, or a substituted or unsubstituted C2 to C30 heterocyclic group.

m1 may be, e.g., an integer of 1 to 3.

m2 may be e.g., an integer of 1 to 4.

m3 may be, e.g., an integer of 1 or 2.

In an implementation, m1 may be 2 or 3, and each R¹ may be the same or different from each other.

In an implementation, m2 may be 2, 3, or 4, and each R² may be the same or different from each other.

In an implementation, m3 may be 2, and each R³ may be the same or different from each other.

Ar¹¹ may be, e.g., a substituted or unsubstituted aryl group, a substituted or unsubstituted heterocyclic group, or an amine group represented by Chemical Formula a.

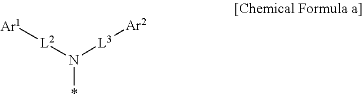

In Chemical Formula a, L² and L³ may each independently be, e.g., a single bond or a substituted or unsubstituted C6 to C20 arylene group.

Ar¹ and Ar² may each independently be, e.g., a substituted or unsubstituted C6 to C20 aryl group or a substituted or unsubstituted C2 to C30 heterocyclic group.

Chemical Formula 1 may be, e.g., represented by Chemical Formula 1A or Chemical Formula 1B.

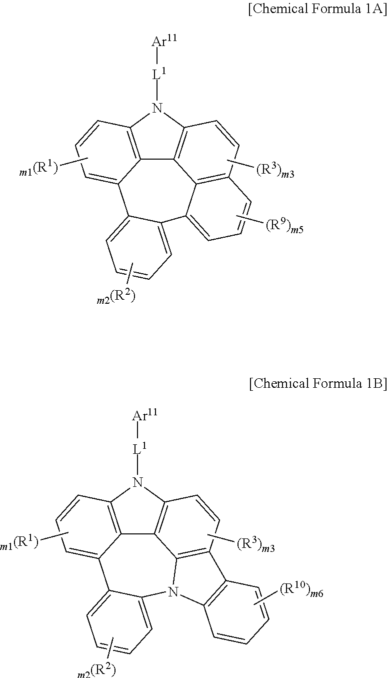

In Chemical Formula 1A and Chemical Formula 1B, L¹, Ar¹¹, R¹ to R³, and m1 to m3 may be defined the same as those described above.

R⁹ and R¹⁰ may each independently be, e.g., hydrogen, deuterium, a cyano group, a halogen, a substituted or unsubstituted amine group, a substituted or unsubstituted C1 to C30 alkyl group, a substituted or unsubstituted C6 to C30 aryl group, or a substituted or unsubstituted C2 to C30 heterocyclic group.

m5 may be, e.g., an integer of 1 to 3.

m6 may be, e.g., an integer of 1 to 4.

In an implementation, m5 may be 2 or 3, and each R⁹ may be the same or different from each other.

In an implementation, m6 may be 2, 3, or 4, and each R¹⁰ may be the same or different from each other.

In an implementation, L¹ may be a single bond, a substituted or unsubstituted phenylene group, a substituted or unsubstituted biphenylene group, or a substituted or unsubstituted naphthylenylene group.

In an implementation, Ar¹¹ may be, e.g., a substituted or unsubstituted phenyl group, a substituted or unsubstituted biphenyl group, a substituted or unsubstituted terphenyl group, a substituted or unsubstituted naphthyl group, a substituted or unsubstituted anthracenyl group, a substituted or unsubstituted phenanthrenyl group, a substituted or unsubstituted triphenylene group, a substituted or unsubstituted chrysenyl group, a substituted or unsubstituted fluorenyl group, a substituted or unsubstituted 9,9′-spirobifluorenyl group, a substituted or unsubstituted dibenzofuranyl group, a substituted or unsubstituted dibenzothiophenyl group, or an amine group represented by Chemical Formula a.

In an implementation, in Chemical Formula a, L² and L³ may each independently be, e.g., a single bond, a substituted or unsubstituted phenylene group, or a substituted or unsubstituted biphenylene group.

In an implementation, in Chemical Formula a, Ar¹ and Ar² may each independently be, e.g., a substituted or unsubstituted phenyl group, a substituted or unsubstituted biphenyl group, a substituted or unsubstituted naphthyl group, a substituted or unsubstituted dibenzofuranyl group, or a substituted or unsubstituted dibenzothiophenyl group.

In an implementation, R¹ to R³ may each independently be, e.g., hydrogen, deuterium, a cyano group, a halogen, a substituted or unsubstituted C1 to C10 alkyl group, or a substituted or unsubstituted C6 to C12 aryl group.

In an implementation, R¹ to R³ may each independently be, e.g., hydrogen, deuterium, a cyano group, a substituted or unsubstituted C1 to C6 alkyl group, or a substituted or unsubstituted phenyl group.

In an implementation, R⁹ and R¹⁰ may each independently be, e.g., hydrogen, deuterium, a cyano group, a halogen group, a substituted or unsubstituted C1 to C10 alkyl group, or a substituted or unsubstituted C6 to C12 aryl group.

In an implementation, R⁹ and R¹⁰ may each independently be, e.g., hydrogen, deuterium, a cyano group, a substituted or unsubstituted C1 to C6 alkyl group, or a substituted or unsubstituted phenyl group.

The first compound may be, e.g., a compound of Group 1.

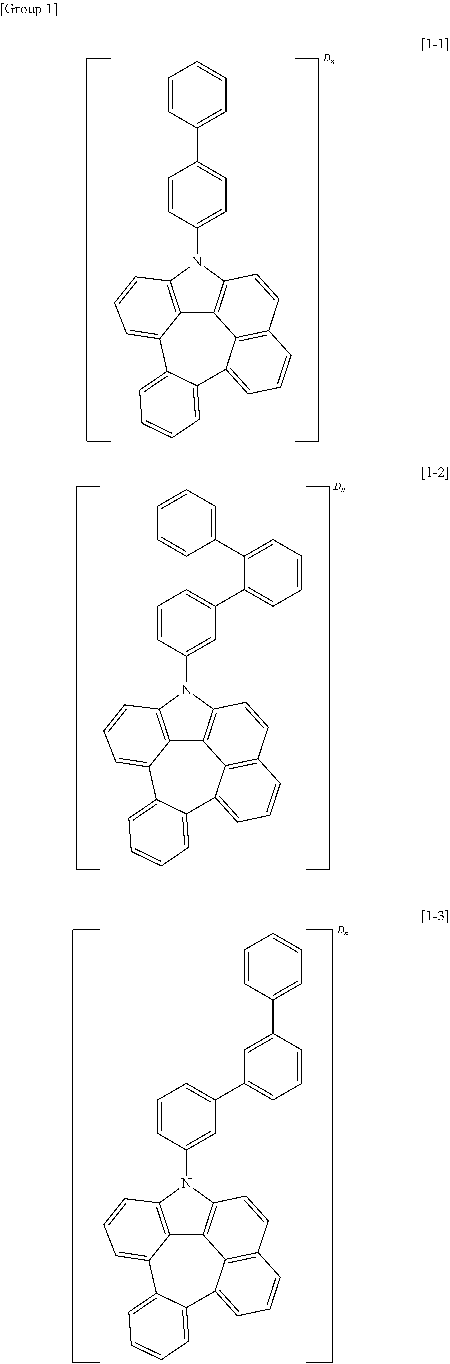

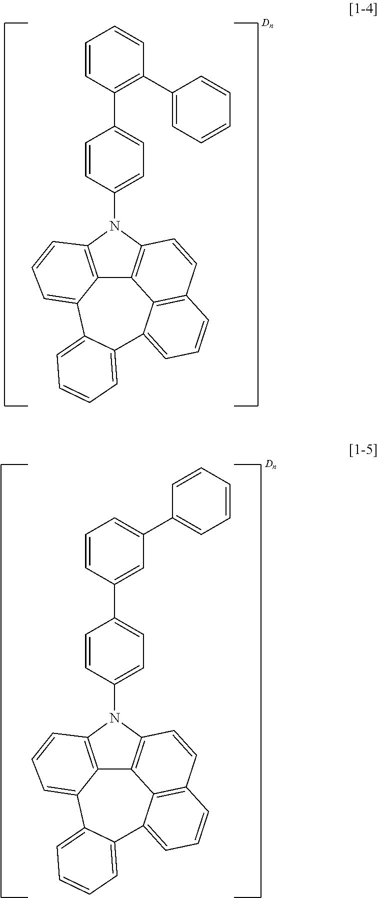

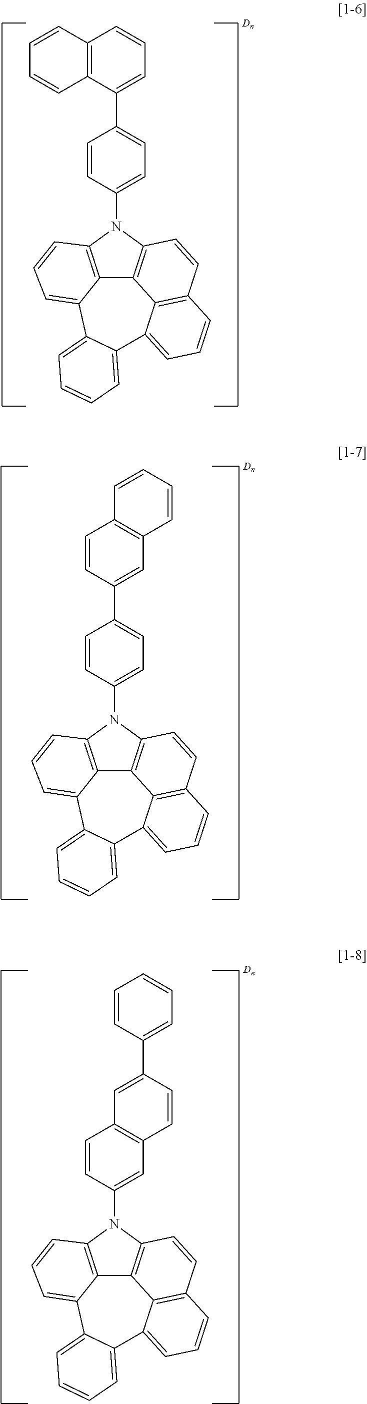

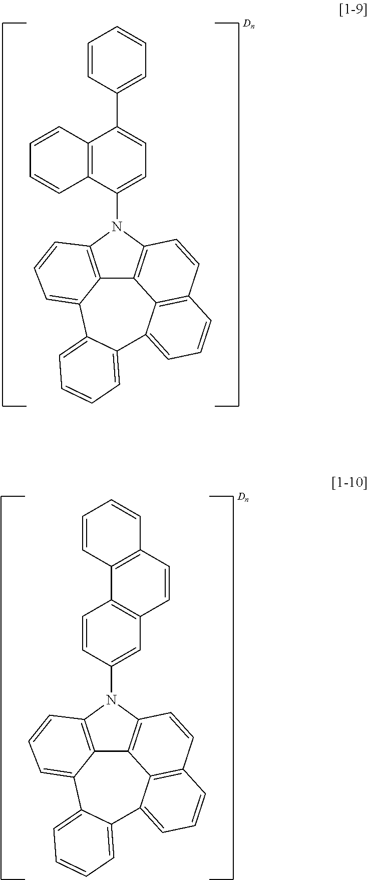

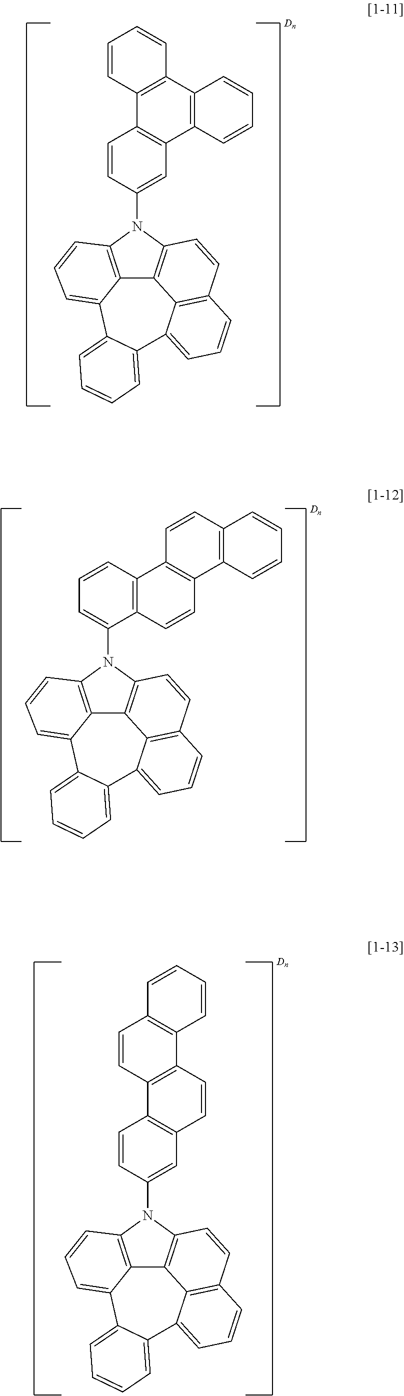

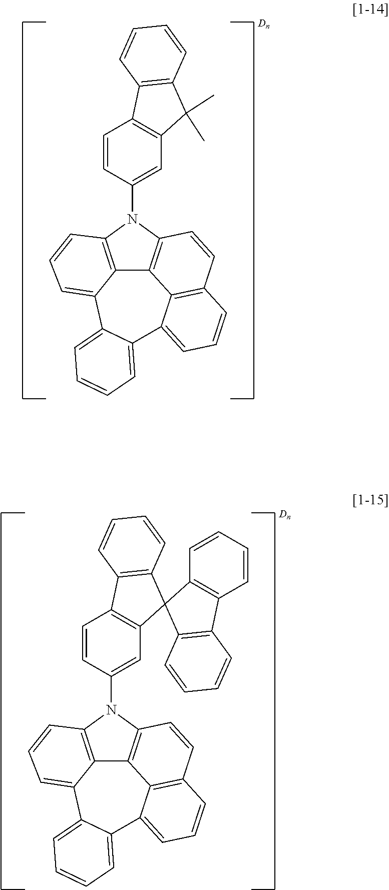

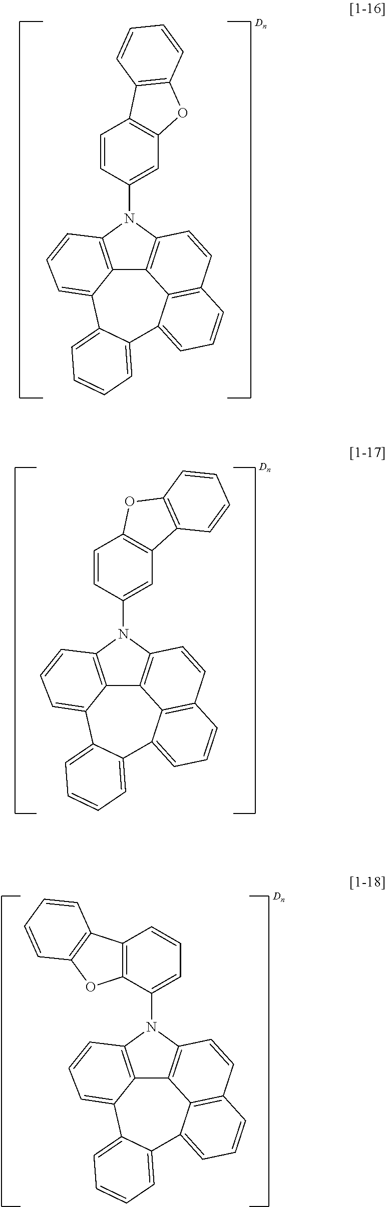

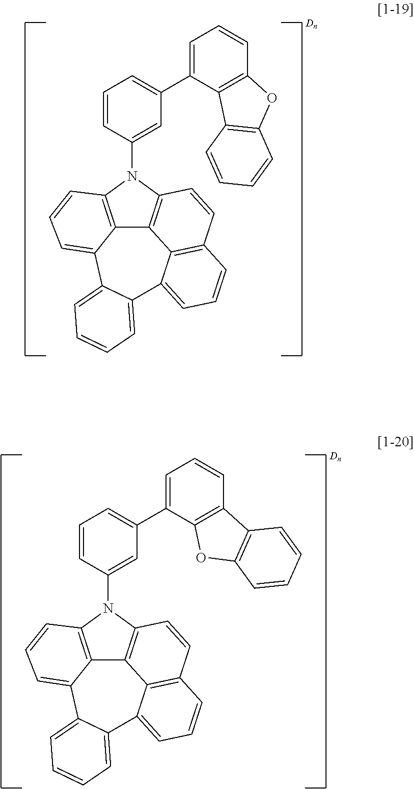

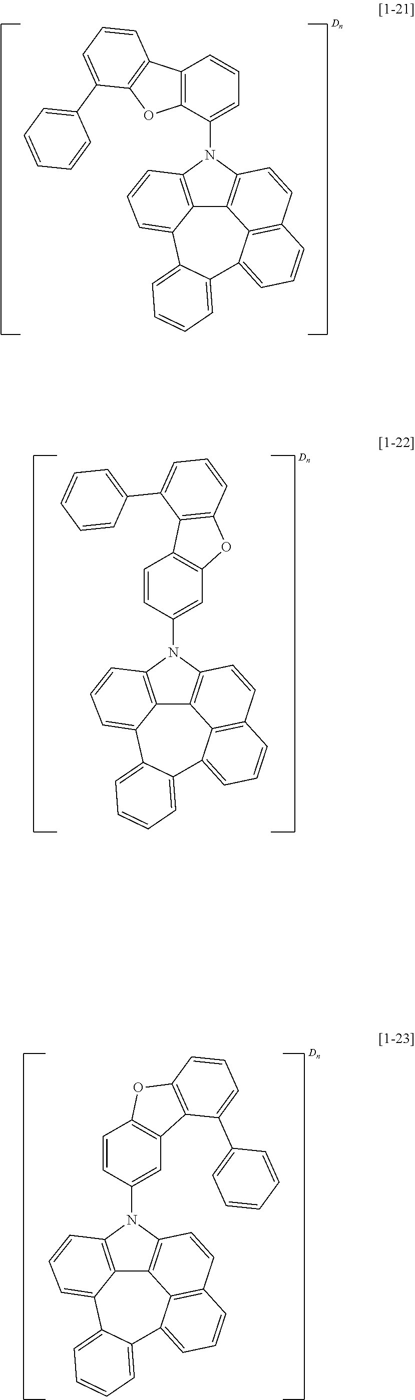

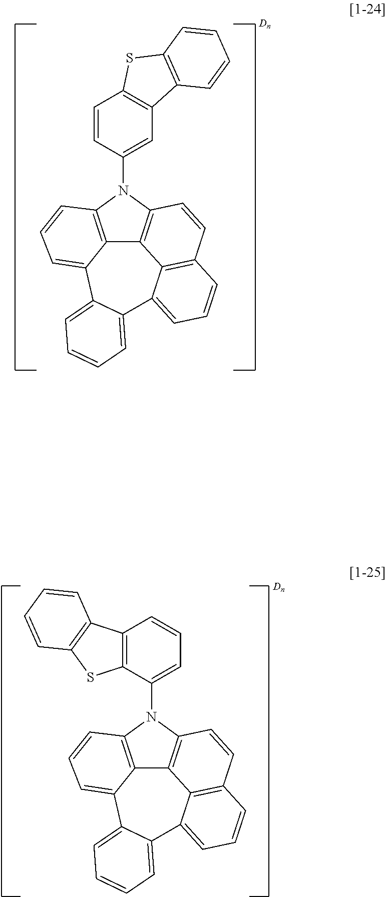

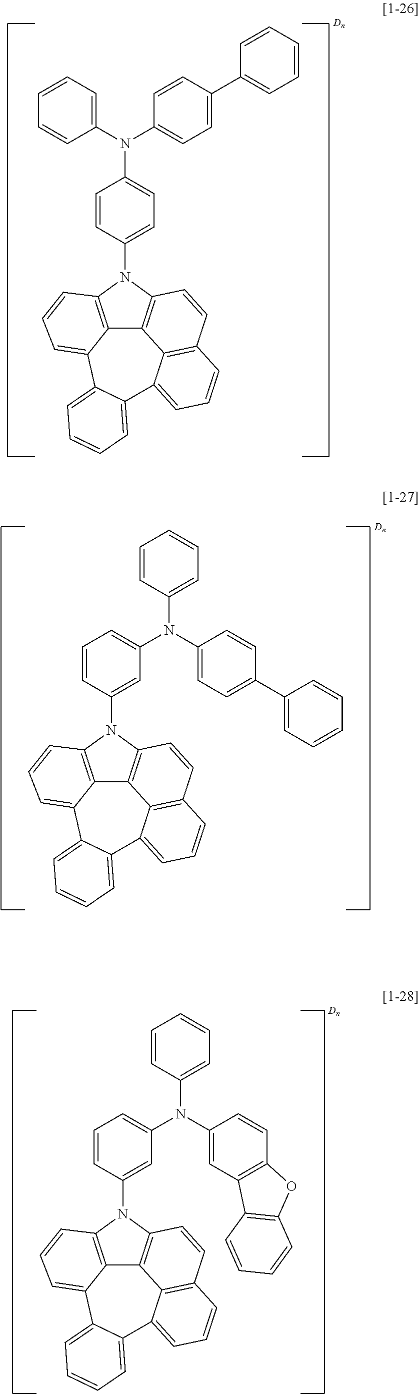

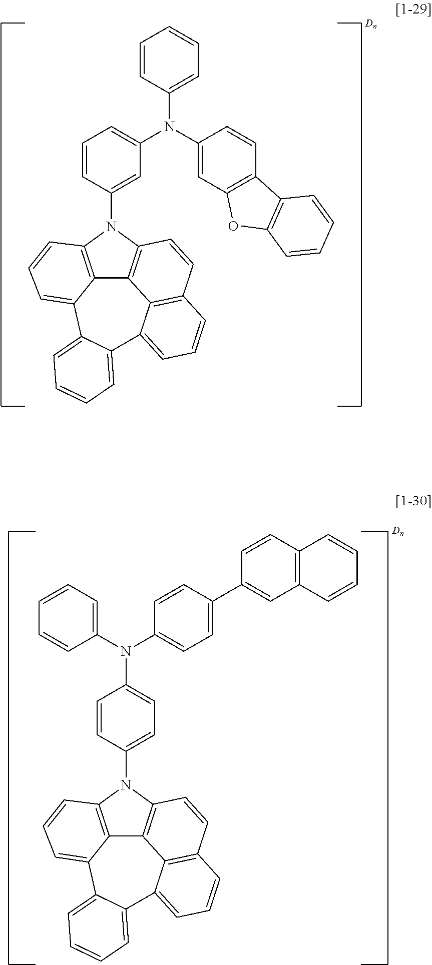

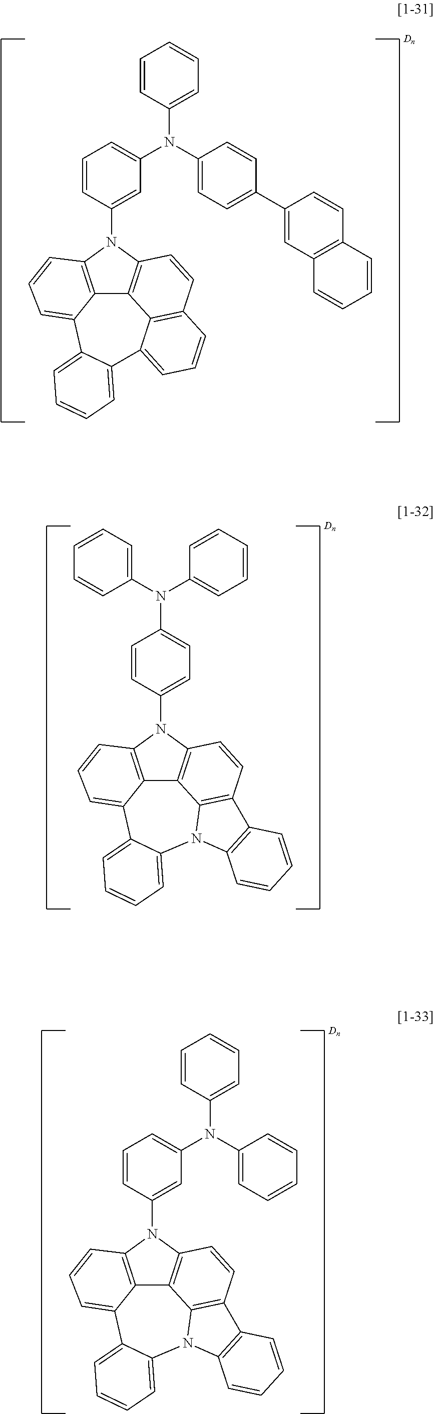

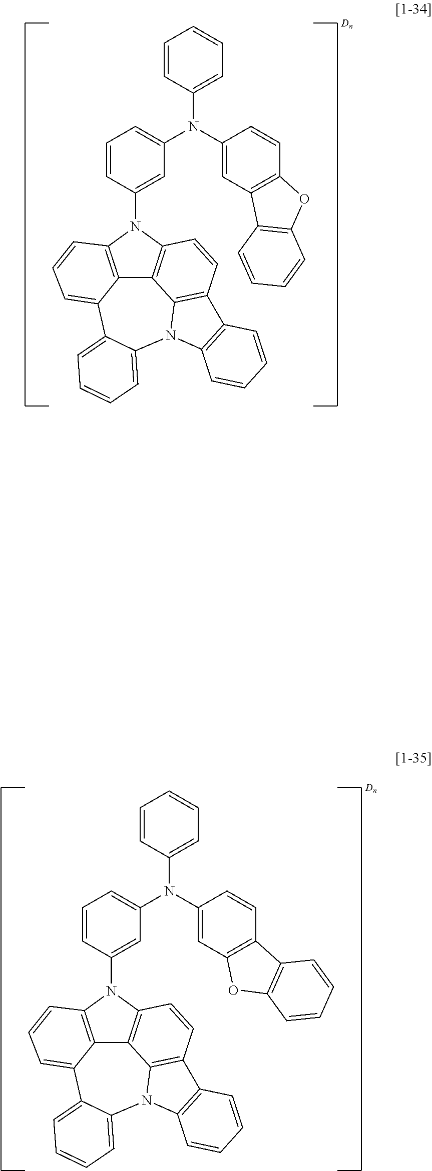

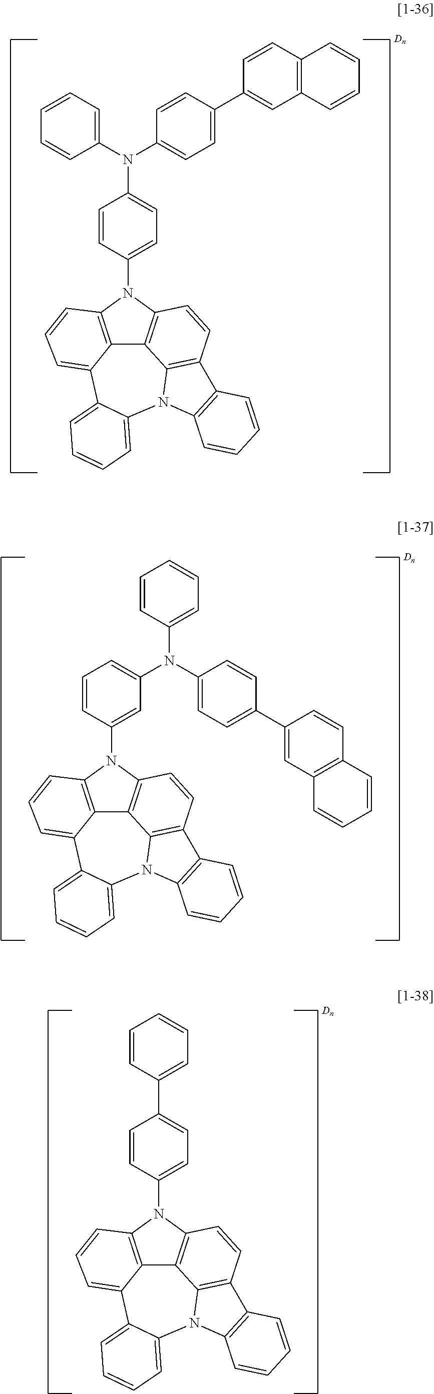

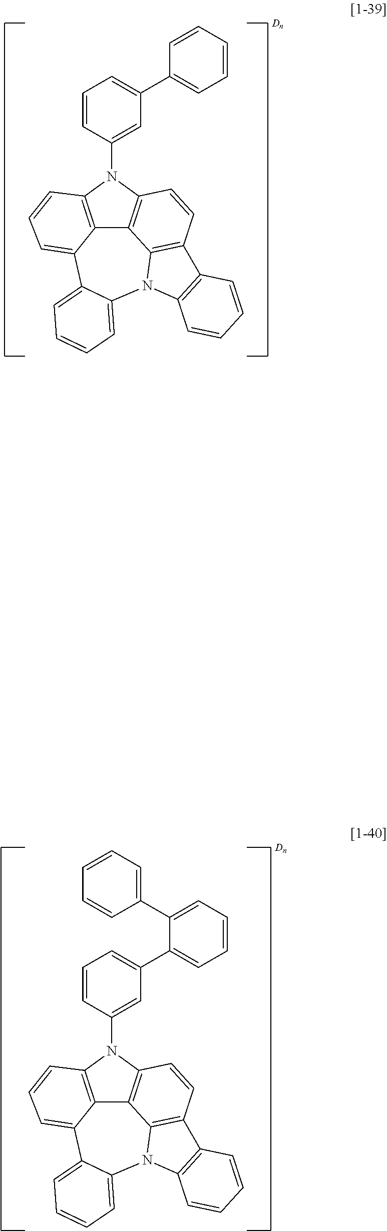

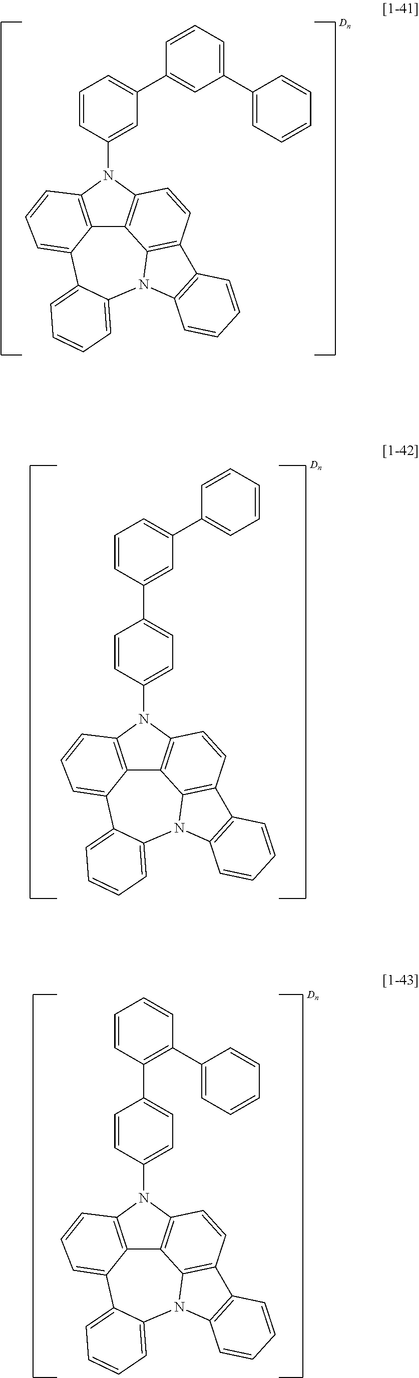

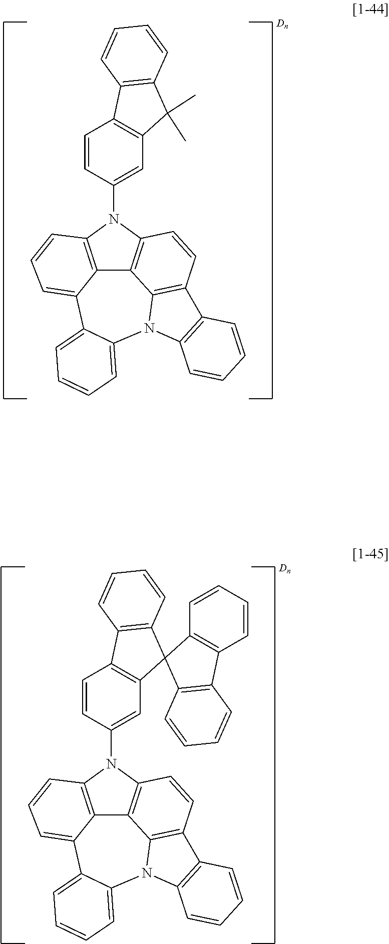

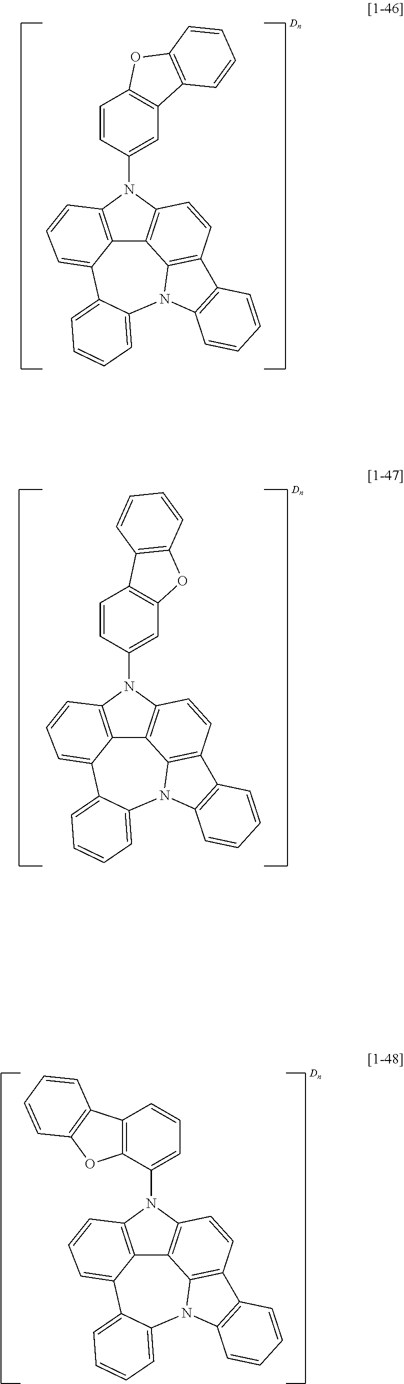

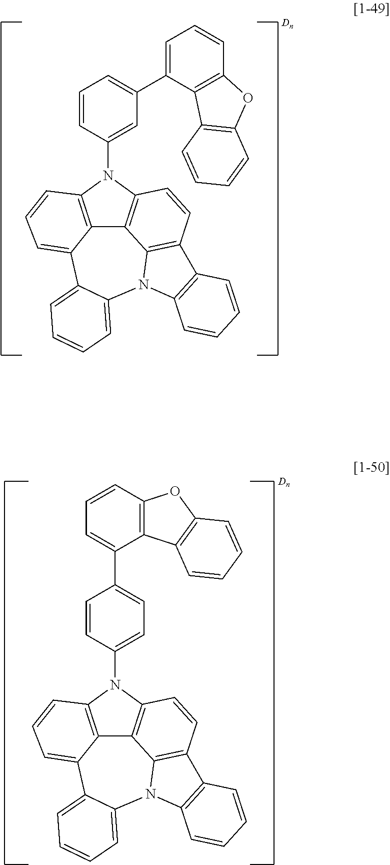

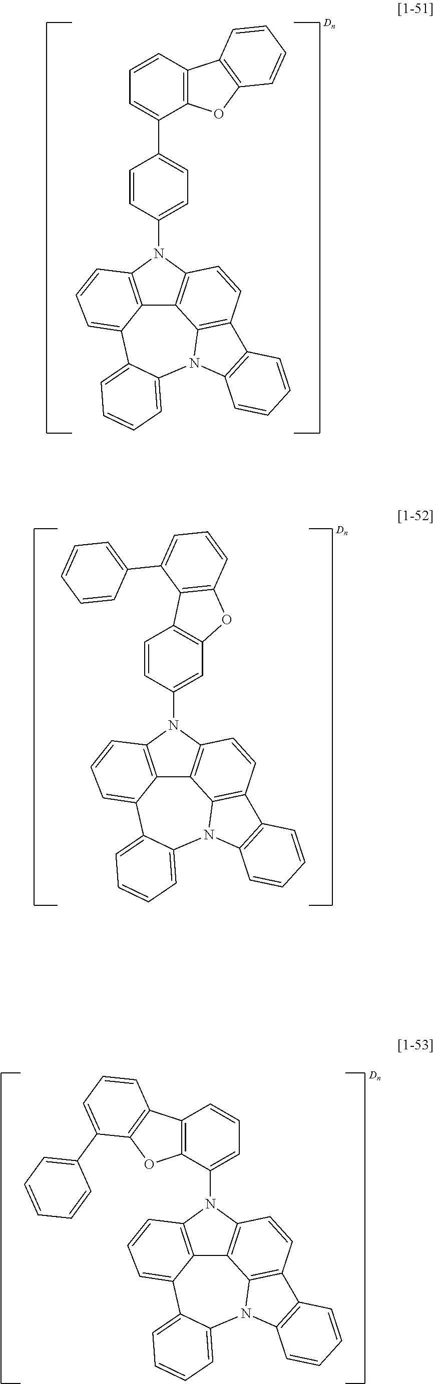

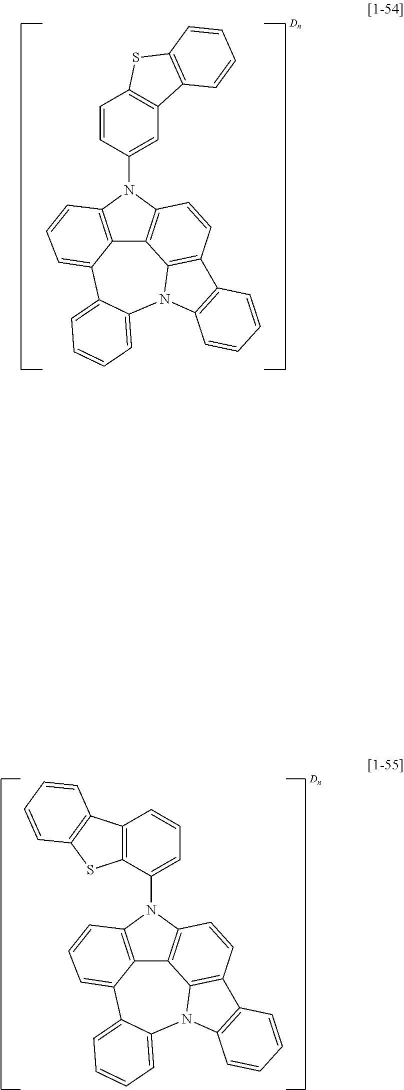

(Dn means the number of deuterium atoms substituted, n is an integer greater than or equal to 0, and the maximum number of n corresponds to the number of substitutable hydrogen positions)

Because the second compound may help effectively expand the LUMO energy band by including a nitrogen-containing hexagonal moiety, it may be included together with the aforementioned first compound to help increase the balance between holes and electrons, thereby helping significantly improve the life-span characteristics of a device to which it is applied.

The second compound may be represented, e.g., by Chemical Formula 2.

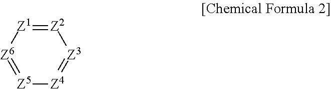

In Chemical Formula 2, Z¹ to Z⁶ may each independently be or include, e.g., N or C-L^{a}-R^{a}.

In an implementation, at least two of Z¹ to Z⁶ may be N.

Each L^{a} may independently be or include, e.g., a single bond, a substituted or unsubstituted C6 to C20 arylene group, a substituted or unsubstituted C2 to C20 heterocyclic group, or a combination thereof.

Each R^{a} may independently be or include, e.g., hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof.

Each R^{a} may be separately present or adjacent groups thereof may be linked to each other to form a substituted or unsubstituted aliphatic monocyclic or polycyclic ring, a substituted or unsubstituted aromatic monocyclic or polycyclic ring, or a substituted or unsubstituted heteroaromatic monocyclic or polycyclic ring.

In an implementation, two of Z¹ to Z⁶ may be nitrogen (N) and the rest may be C-L^{a}-R^{a}.

In an implementation, Z¹ and Z³ may be nitrogen, Z² may be N or C-L^{a}-R^{a}, Z⁴ may be N or C-L^{a}-R^{a}, Z⁵ may be N or C-L^{a}-R^{a}, and Z⁶ may be N or C-L^{a}-R^{a}.

In an implementation, three of Z¹ to Z⁶ may be nitrogen (N) and the rest may be C-L^{a}-R^{a}.

In an implementation, Z¹, Z³, and Z⁵ may be nitrogen, Z² may be N or C-L^{a}-R^{a}, Z⁴ may be N or C-L^{a}-R^{a}, and Z⁶ may be N or C-L^{a}-R^{a}.

In an implementation, depending on the specific substituent of R^{a}, the second compound may be, e.g., represented by one of Chemical Formula 2A to Chemical Formula 2E.

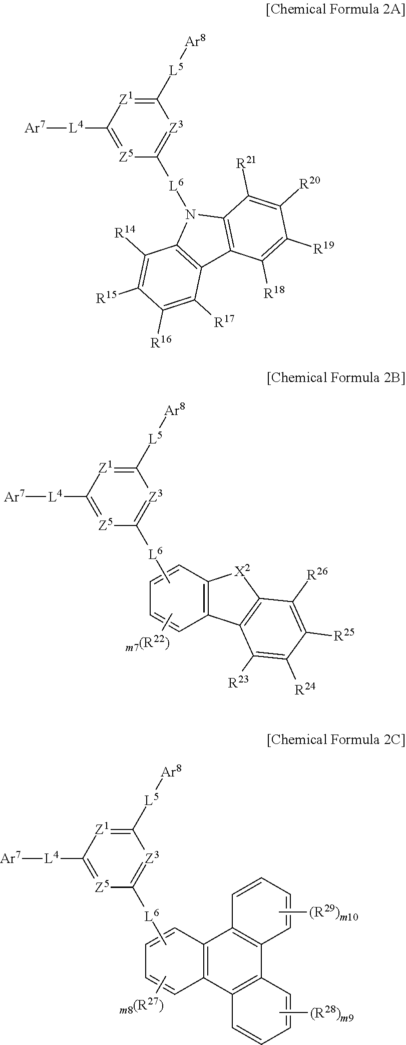

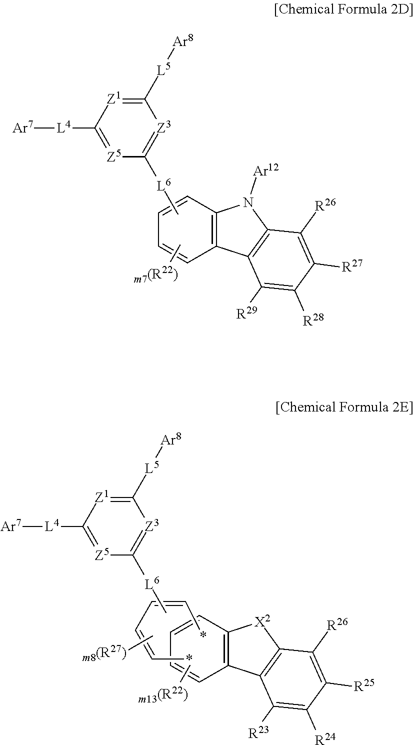

In Chemical Formula 2A to Chemical Formula 2E, Z¹, Z³, and Z⁵ may each independently be, e.g., N or C-L^{a}-R^{a}.

In an implementation, at least two of Z¹, Z³, and Z⁵ may be N.

X² may be, e.g., O, S, or NR^{b}.

L^{a} and L⁴ to L⁶ may each independently be, e.g., a single bond, a substituted or unsubstituted C6 to C20 arylene group, a substituted or unsubstituted C2 to C20 heterocyclic group, or a combination thereof.

R^{a}, R^{b}, and R¹⁴ to R²⁹ may each independently be, e.g., hydrogen, deuterium, a cyano group, a halogen, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, or a combination thereof.

R¹⁴ to R²¹ may each be separately present or adjacent groups thereof may be linked to each other to form a substituted or unsubstituted aromatic monocyclic or polycyclic ring.

R²³ to R²⁶ are each separately present or adjacent groups thereof are linked to each other to form a substituted or unsubstituted aromatic monocyclic or polycyclic ring,

Ar⁷, Ar⁸, and Ar¹² may each independently be, e.g., a substituted or unsubstituted C6 to C30 aryl group, a substituted or unsubstituted C2 to C30 heterocyclic group, or a combination thereof.

R^{a}, Ar⁷, and Ar⁸ may each separately be present or adjacent groups of R^{a}, Ar⁷, and Ar⁸ may be linked to each other to form a substituted or unsubstituted aromatic monocyclic or polycyclic ring or a substituted or unsubstituted heteroaromatic monocyclic or polycyclic ring.

m7 and m8 may each independently be, e.g., an integer of 1 to 3.

m9 and m10 may each independently be, e.g., an integer of 1 to 4.

m13 may be, e.g., an integer of 1 or 2.

In an implementation, m7 may be 2 or 3, and each R²² may be the same or different from each other.

In an implementation, m8 may be 2 or 3, and each R²⁷ may be the same or different from each other.

In an implementation, m9 may be 2, 3, or 4, and each R²⁸ may be the same or different from each other.

In an implementation, m10 may be 2, 3, or 4, and each R²⁹ may be the same or different from each other.

In an implementation, m13 may be 2, and each R²² may be the same or different from each other.

As used herein, the indication that adjacent groups are linked to each other to form a substituted or unsubstituted aromatic or heteroaromatic monocyclic or polycyclic ring means that any two adjacent substituents may be linked to each other to form a ring. In an implementation, in Chemical Formula 2A, adjacent groups of R¹⁴ to R²¹ and adjacent groups of R²³ to R²⁶ may be linked to each other to form a substituted or unsubstituted aromatic monocyclic ring. Here, the aromatic monocyclic ring formed may be, e.g., a substituted or unsubstituted phenyl group.

In an implementation, adjacent groups of R¹⁴ to R²¹ and adjacent groups of R²³ to R²⁶ may be linked to each other to form a substituted or unsubstituted aromatic polycyclic ring, and the aromatic polycyclic ring formed may be, e.g., a substituted or unsubstituted naphthyl group.

In an implementation, adjacent groups of R¹⁴ to R²¹ and adjacent groups of R²³ to R²⁶ may be linked to each other to form a substituted or unsubstituted heteroaromatic polycyclic ring, and the heteroaromatic polycyclic ring formed may be, e.g., a substituted or unsubstituted indolyl group, a substituted or unsubstituted benzofuranyl group, a substituted or unsubstituted benzothiophenyl group, or the like.

In an implementation, Chemical Formula 2A may be, e.g., represented by one of Chemical Formula 2A-I to Chemical Formula 2A-X.

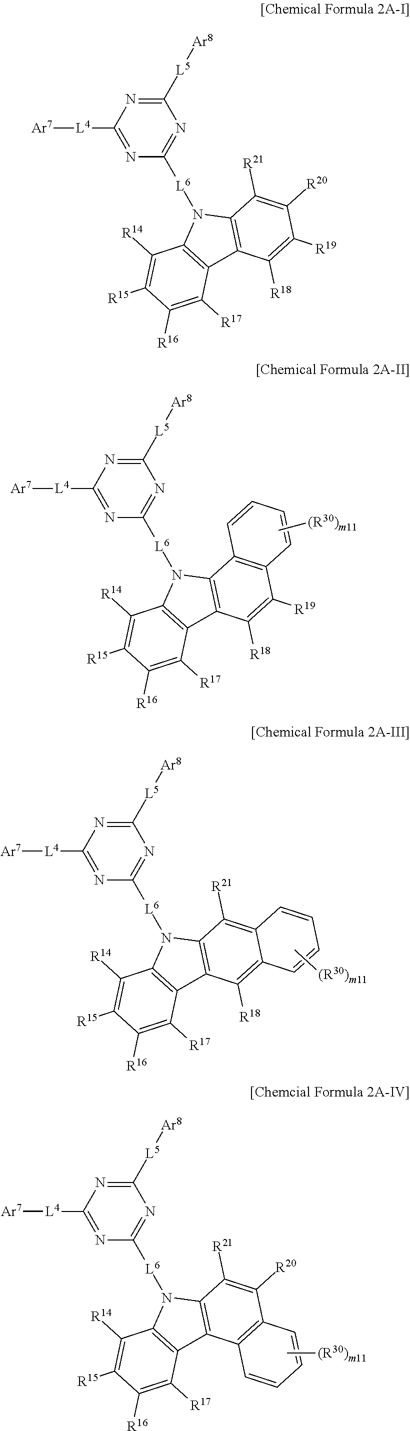

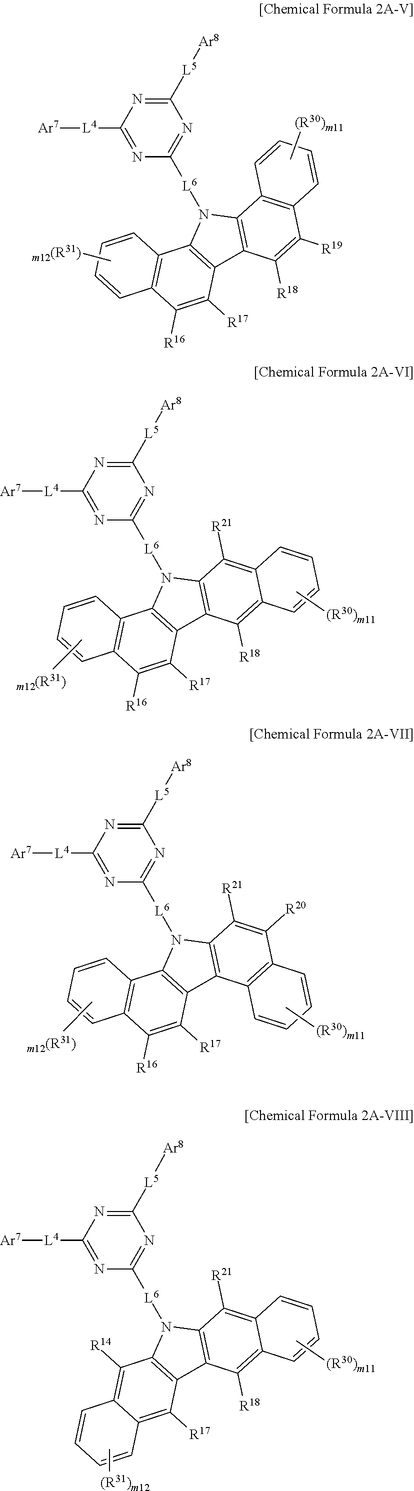

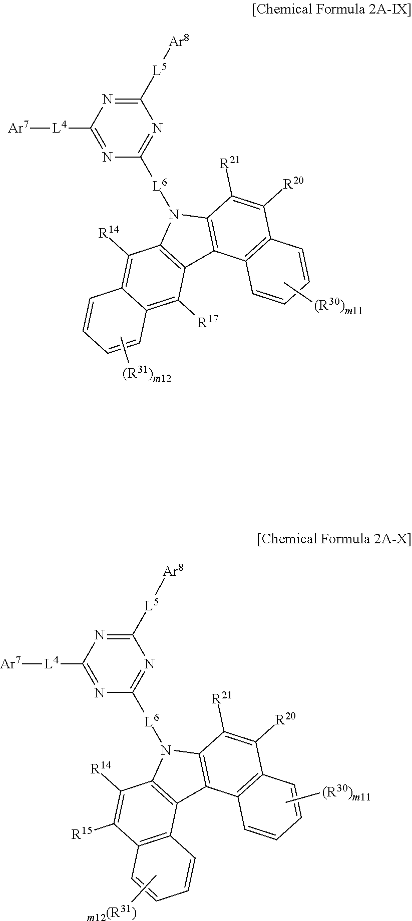

In Chemical Formula 2A-I to Chemical Formula 2A-X, L⁴ to L⁶ may each independently be, e.g., a single bond, a substituted or unsubstituted phenylene group, a substituted or unsubstituted biphenylene group, a substituted or unsubstituted naphthylene group, a substituted or unsubstituted dibenzofuranylene group, or a substituted or unsubstituted dibenzothiophenylene group.

Ar⁷ and Ar⁸ may each independently be, e.g., a substituted or unsubstituted phenyl group, a substituted or unsubstituted biphenyl group, a substituted or unsubstituted terphenyl group, a substituted or unsubstituted naphthyl group, a substituted or unsubstituted triphenylene group, a substituted or unsubstituted carbazolyl group, a substituted or unsubstituted dibenzofuranyl group, or a substituted or unsubstituted dibenzothiophenyl group.

R¹⁴ to R²¹, R³⁰, and R³¹ may each independently be, e.g., hydrogen, deuterium, a substituted or unsubstituted C1 to C10 alkyl group, a substituted or unsubstituted phenyl group, a substituted or unsubstituted dibenzofuranyl group, or a substituted or unsubstituted dibenzothiophenyl group.

m11 and m12 may each independently be, e.g., an integer of 1 to 4.

In an implementation, Chemical Formula 2B may be, e.g., represented by one of Chemical Formula 2B-I to Chemical Formula 2B-VII.

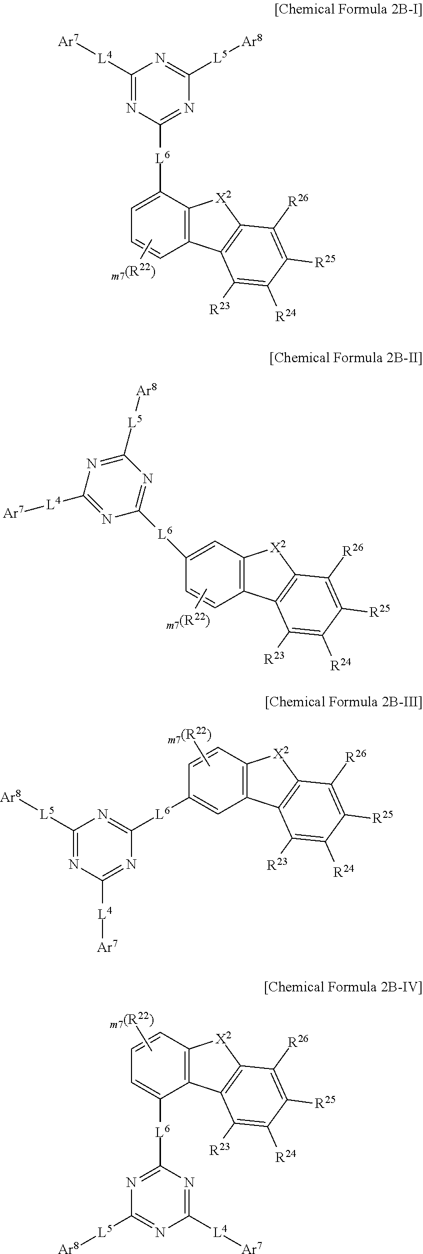

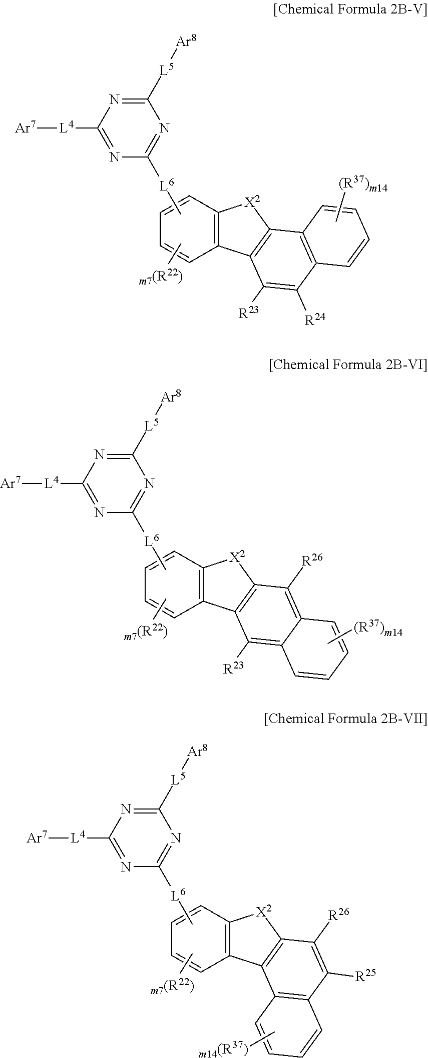

In Chemical Formula 2B-I to Chemical Formula 2B-VII, each substituent may be defined the same as those of Chemical Formula 2B.

R³⁷ may be, e.g., hydrogen, deuterium, a substituted or unsubstituted C1 to C10 alkyl group, a substituted or unsubstituted phenyl group, a substituted or unsubstituted naphthyl group, a substituted or unsubstituted dibenzofuranyl group, or a substituted or unsubstituted dibenzothiophenyl group.

m7 may be, e.g., an integer of 1 to 3.

m14 may be, e.g., an integer of 1 to 4.

In an implementation, in Chemical Formula 2B-I to Chemical Formula 2B-VII, L⁴ to L⁶ may each independently be, e.g., a single bond, a substituted or unsubstituted phenylene group, a substituted or unsubstituted biphenylene group, a substituted or unsubstituted naphthylene group, a substituted or unsubstituted dibenzofuranylene group, or a substituted or unsubstituted dibenzothiophenylene group.

X² may be, e.g., O or S.

Ar⁷ and Ar⁸ may each independently be, e.g., a substituted or unsubstituted phenyl group, a substituted or unsubstituted biphenyl group, a substituted or unsubstituted terphenyl group, a substituted or unsubstituted naphthyl group, a substituted or unsubstituted triphenylene group, a substituted or unsubstituted chrysenyl group, a substituted or unsubstituted carbazolyl group, a substituted or unsubstituted dibenzofuranyl group, a substituted or unsubstituted dibenzothiophenyl group, a substituted or unsubstituted naphthobenzofuranyl group, or a substituted or unsubstituted naphthobenzothiophenyl group.

R²² to R²⁶ and R³⁷ may each independently be, e.g., hydrogen, deuterium, a substituted or unsubstituted C1 to C10 alkyl group, a substituted or unsubstituted phenyl group, a substituted or unsubstituted naphthyl group, a substituted or unsubstituted dibenzofuranyl group, or a substituted or unsubstituted dibenzothiophenyl group.

m7 may be, e.g., an integer of 1 to 3.

m14 may be, e.g., an integer of 1 to 4.

In an implementation, Chemical Formula 2C may be, e.g., represented by Chemical Formula 2C-I or Chemical Formula 2C-II.

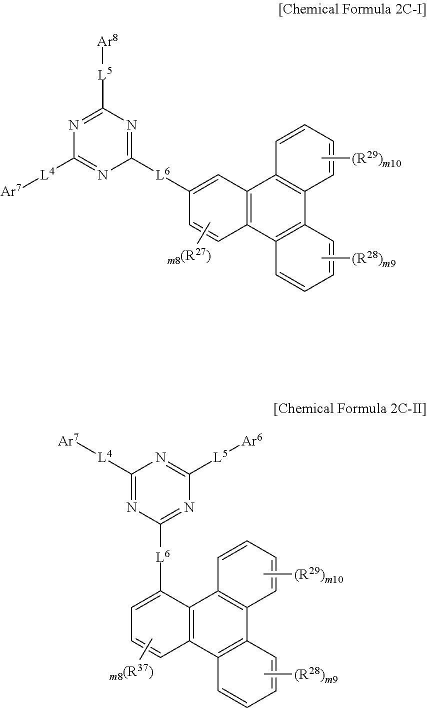

In Chemical Formula 2C-I and Chemical Formula 2C-II, each substituent may be defined the same as those in Chemical Formula 2C.

In an implementation, in Chemical Formula 2C-I and Chemical Formula 2C-II, L⁴ to L⁶ may each independently be, e.g., a single bond or a substituted or unsubstituted phenylene group.

Ar⁷ and Ar⁸ may each independently be, e.g., a substituted or unsubstituted phenyl group, a substituted or unsubstituted biphenyl group, a substituted or unsubstituted terphenyl group, a substituted or unsubstituted naphthyl group, a substituted or unsubstituted dibenzofuranyl group, a substituted or unsubstituted dibenzothiophenyl group, a substituted or unsubstituted naphthobenzofuranyl group, or a substituted or unsubstituted naphthobenzothiophenyl group.

R²⁷ to R²⁹ may each independently be, e.g., hydrogen, deuterium, a substituted or unsubstituted C1 to C10 alkyl group, a substituted or unsubstituted phenyl group, a substituted or unsubstituted naphthyl group, a substituted or unsubstituted dibenzofuranyl group, or a substituted or unsubstituted dibenzothiophenyl group.

m8 may be, e.g., an integer of 1 to 3.

m9 and m10 may each independently be, e.g., an integer of 1 to 4.

In an implementation, Chemical Formula 2 may be, e.g., represented by Chemical Formula 2B-IV.

The second compound may be, e.g., a compound of Group 2.

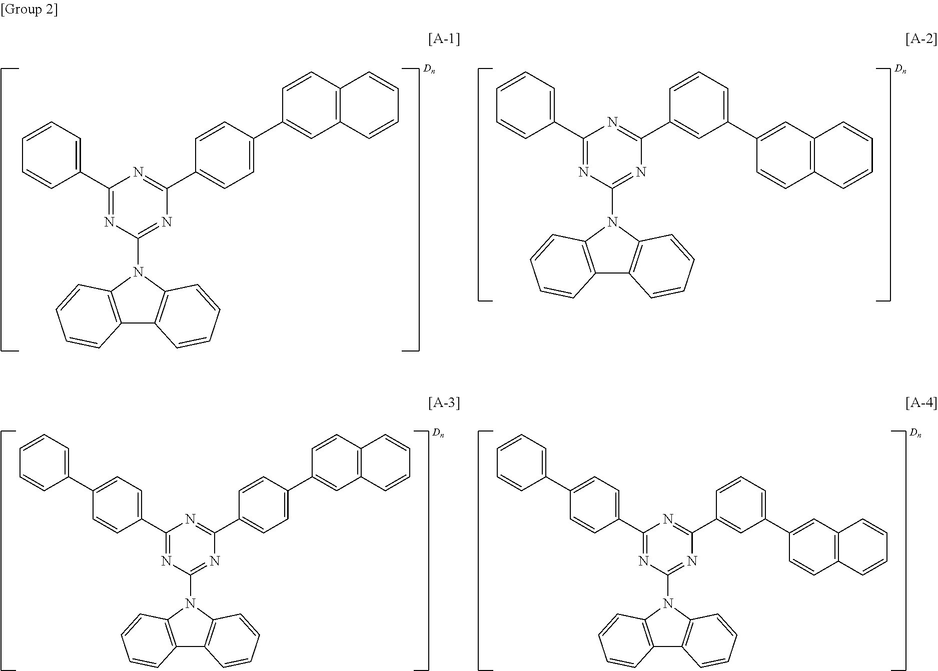

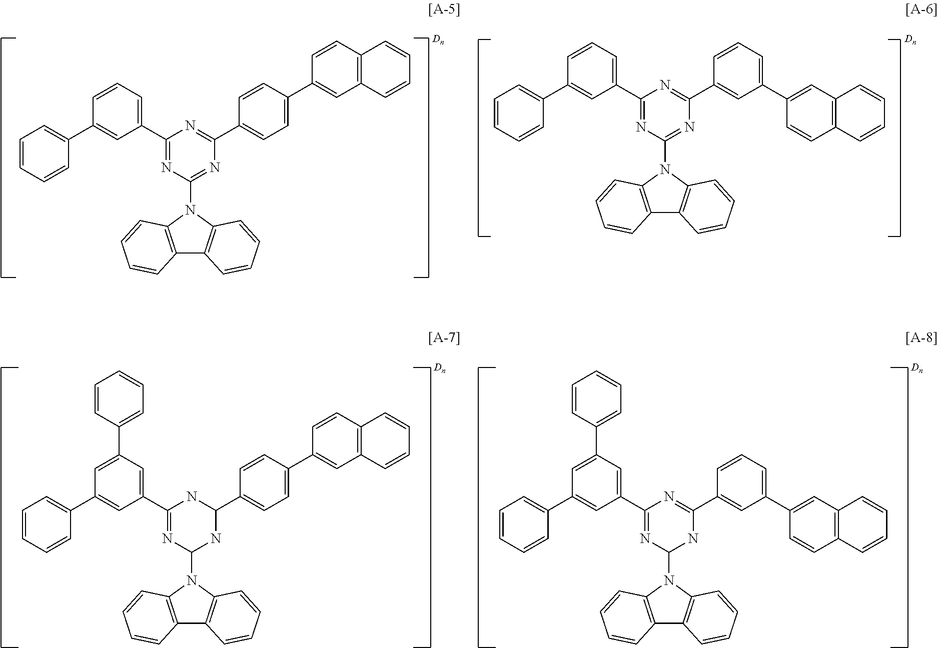

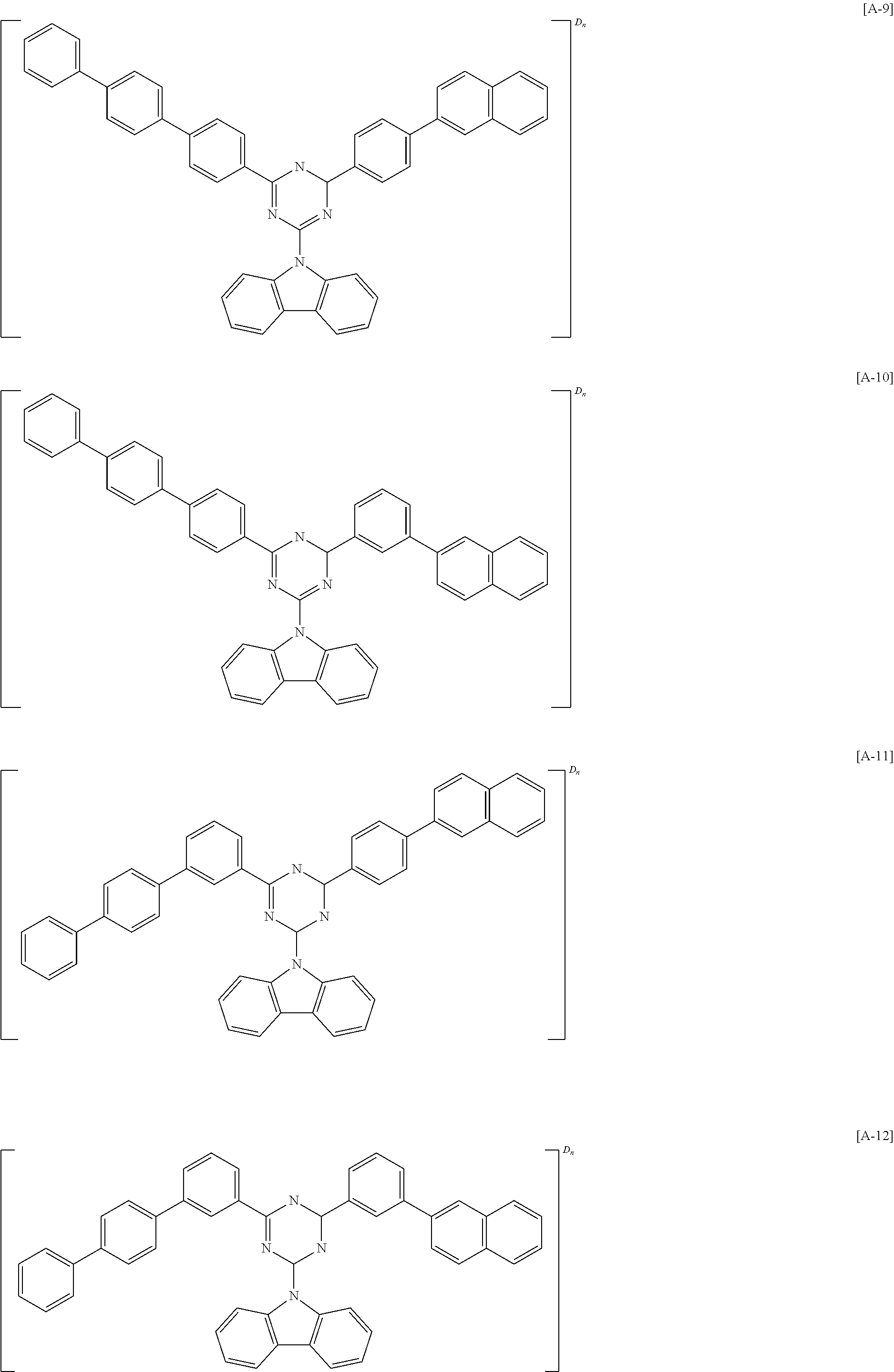

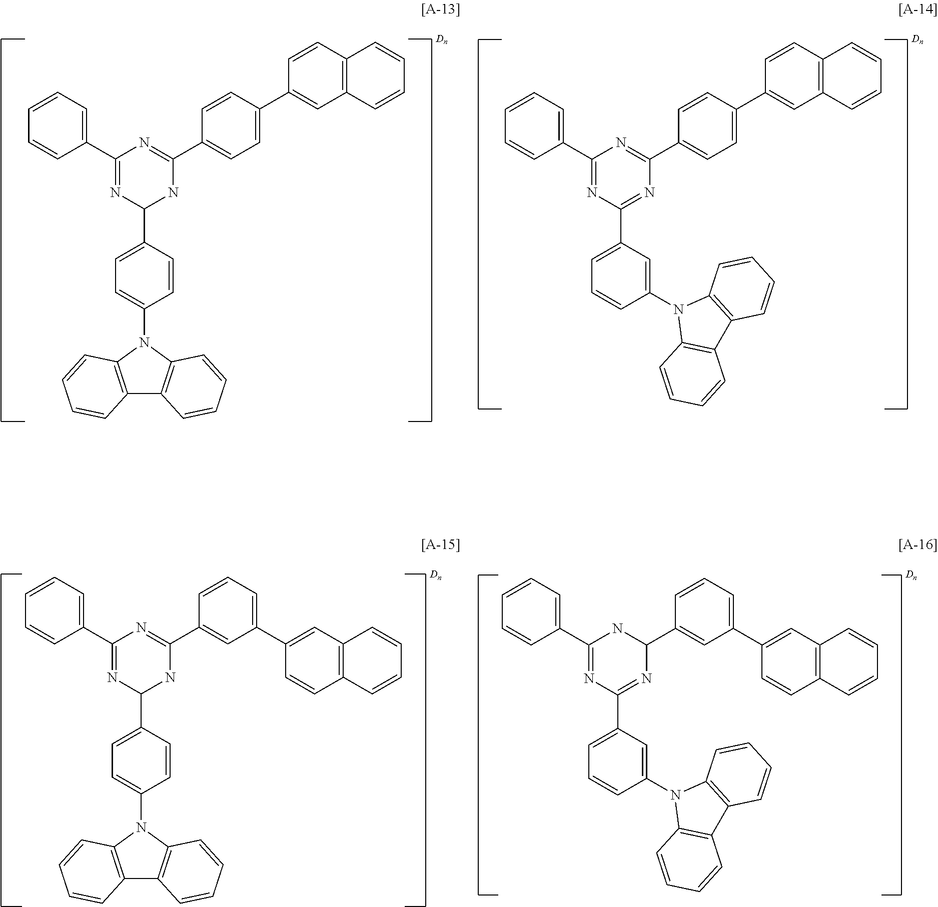

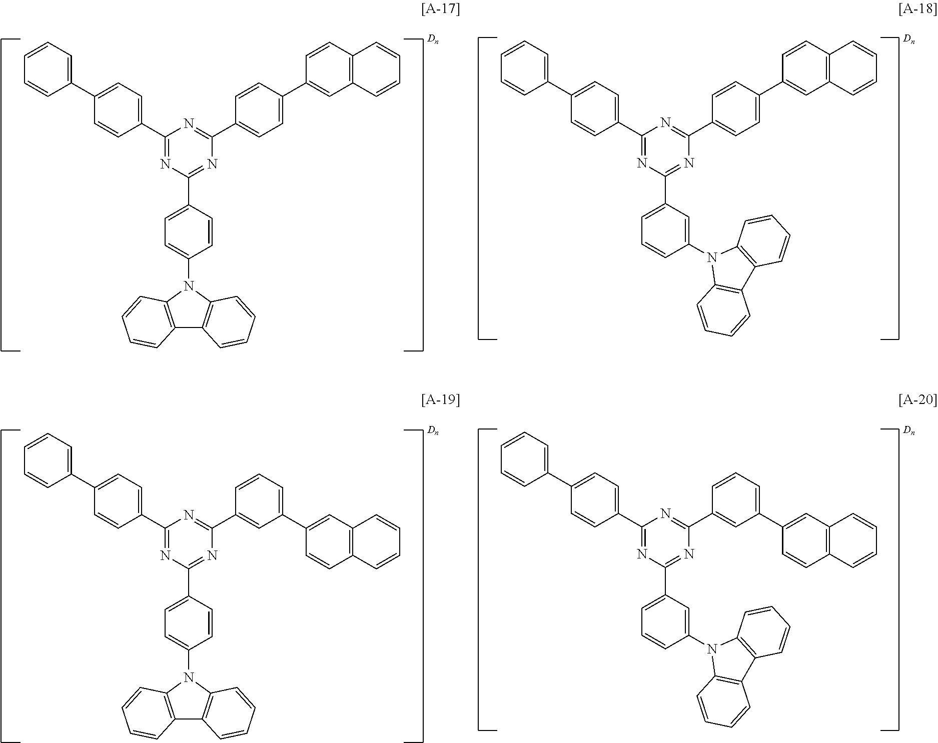

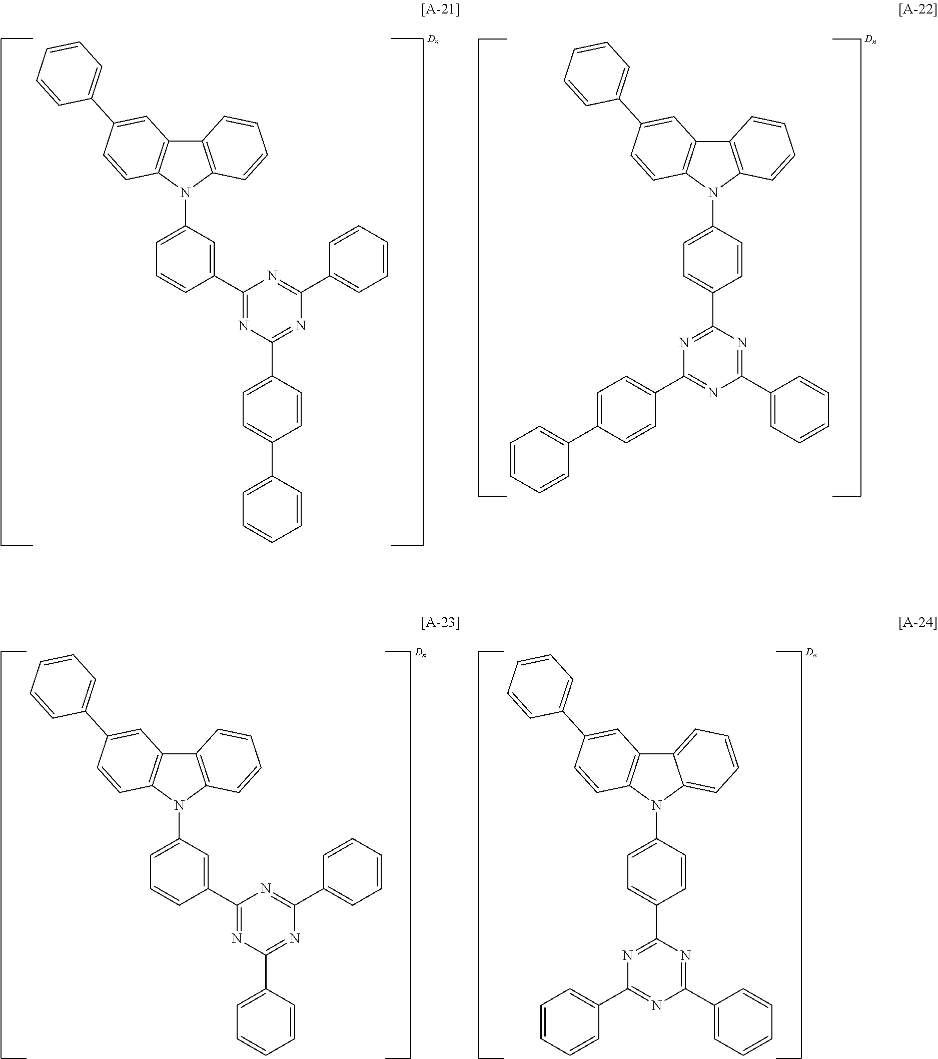

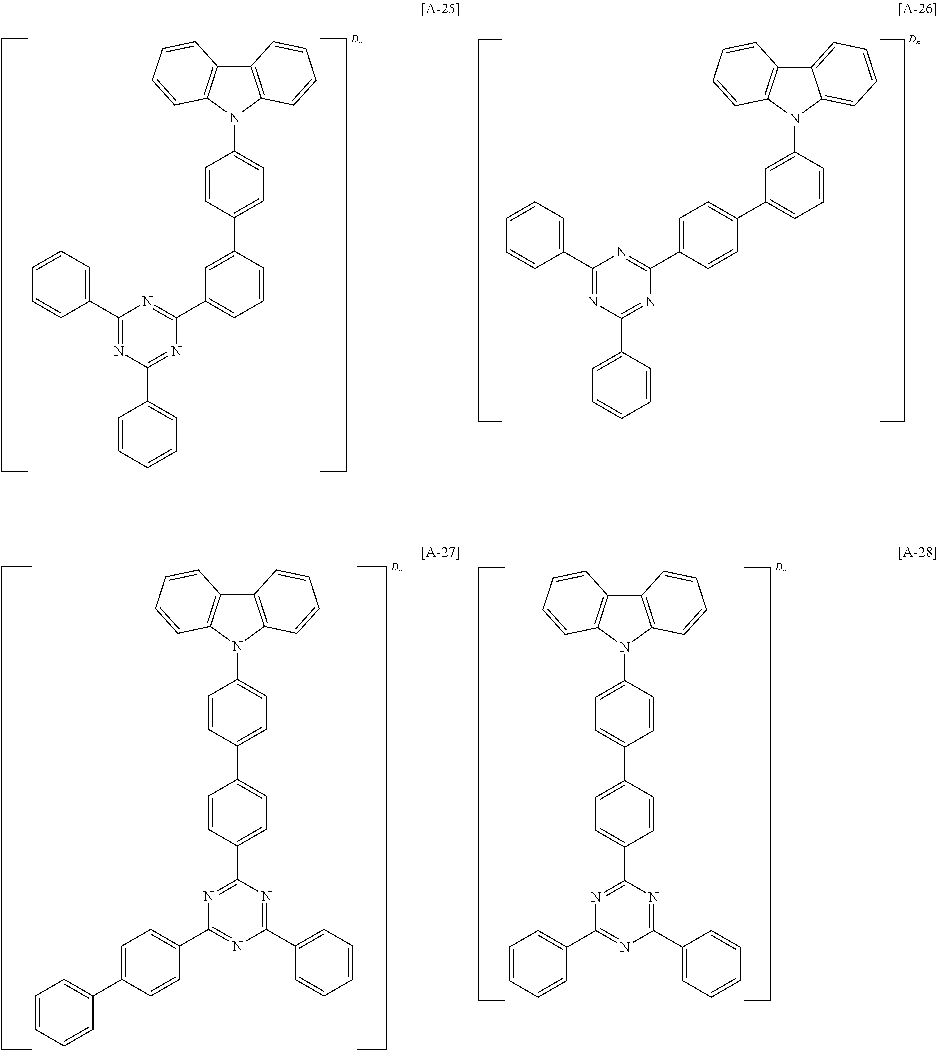

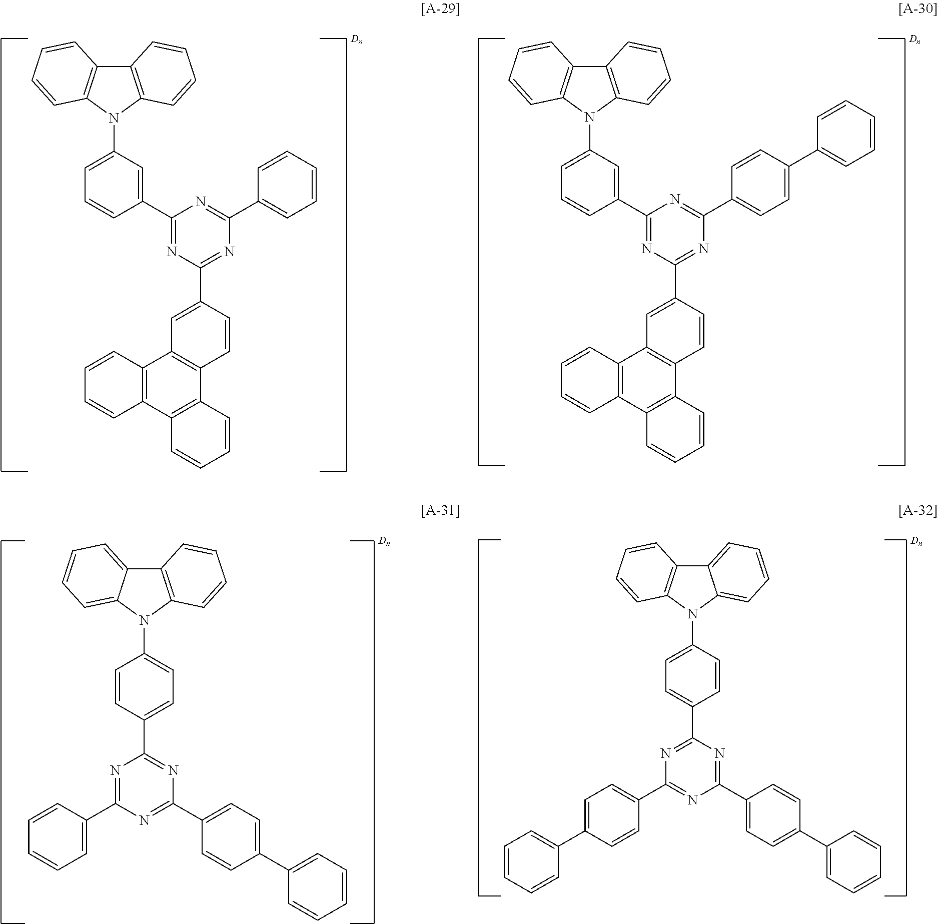

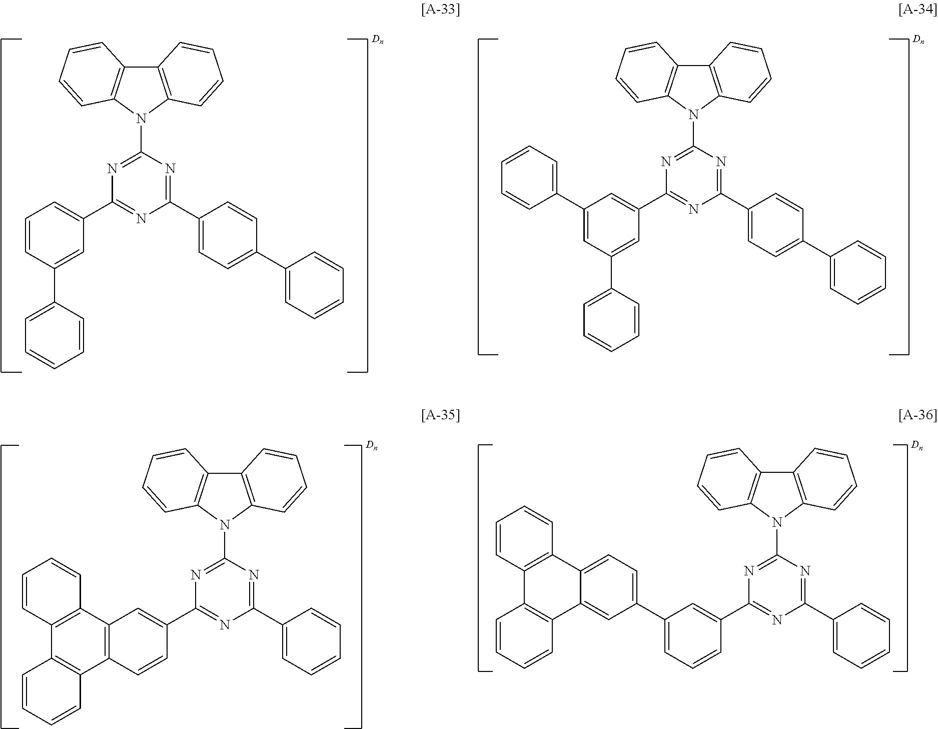

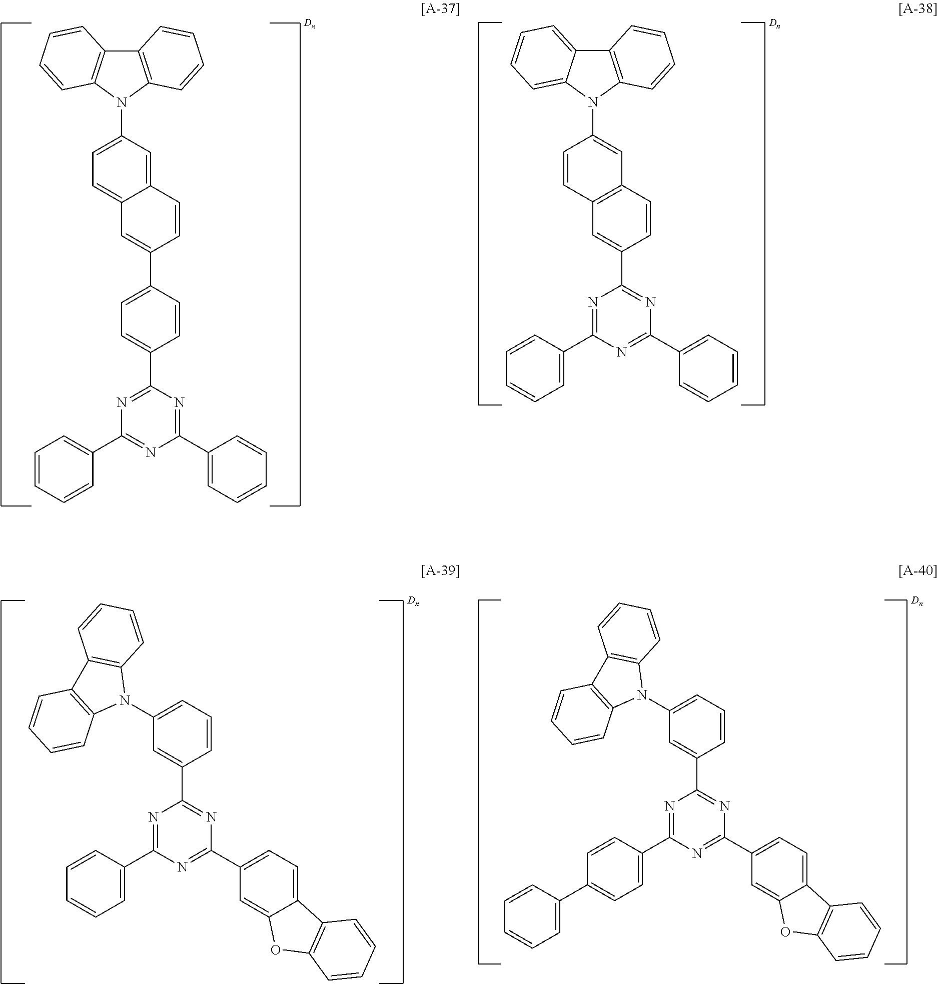

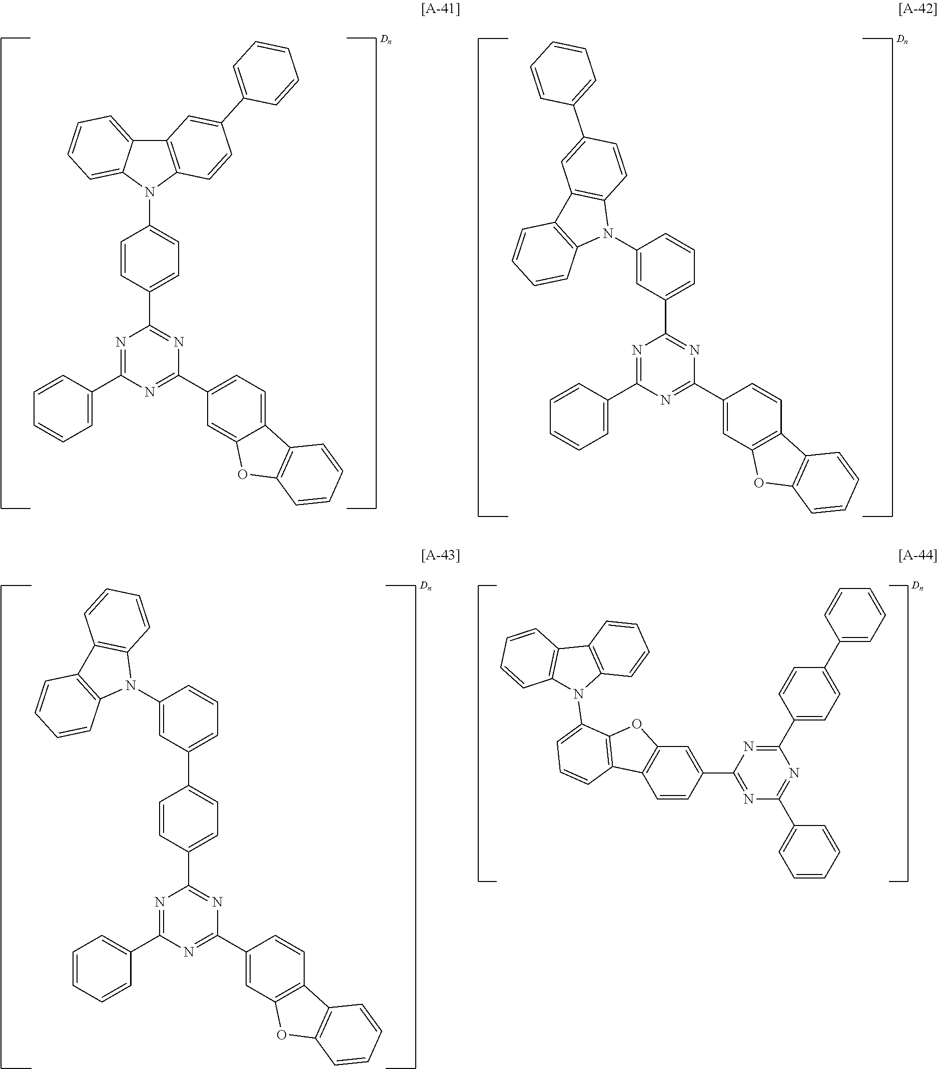

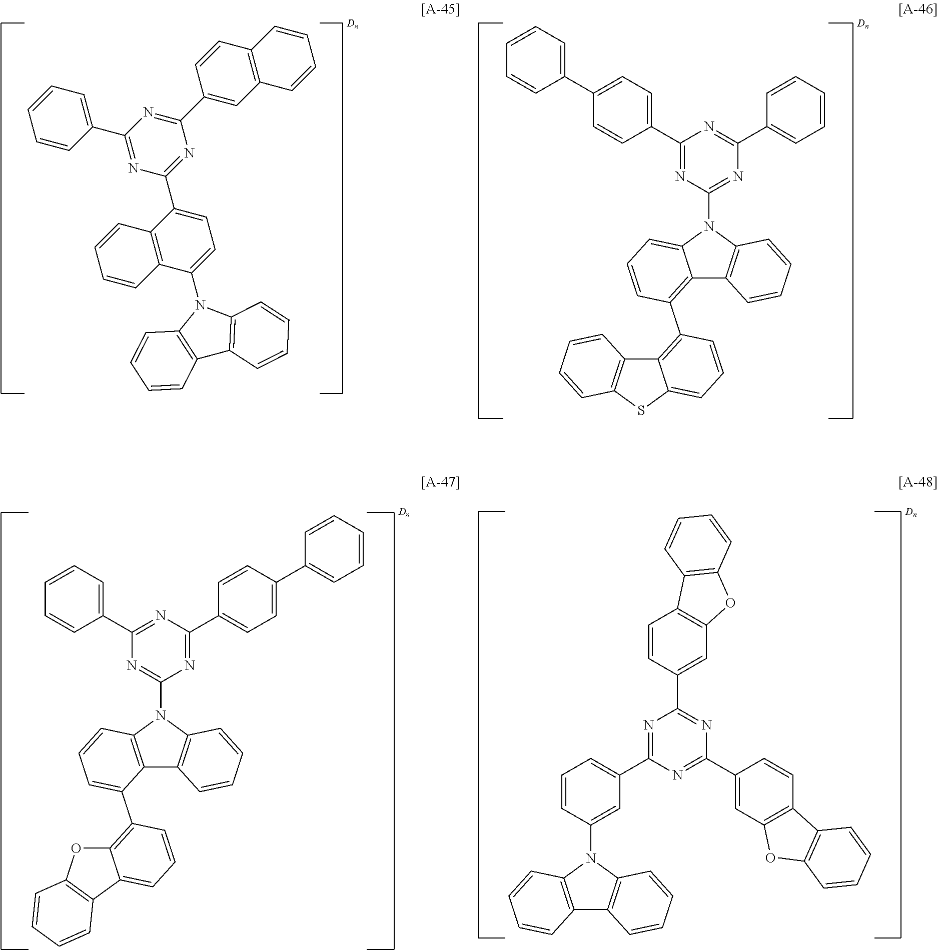

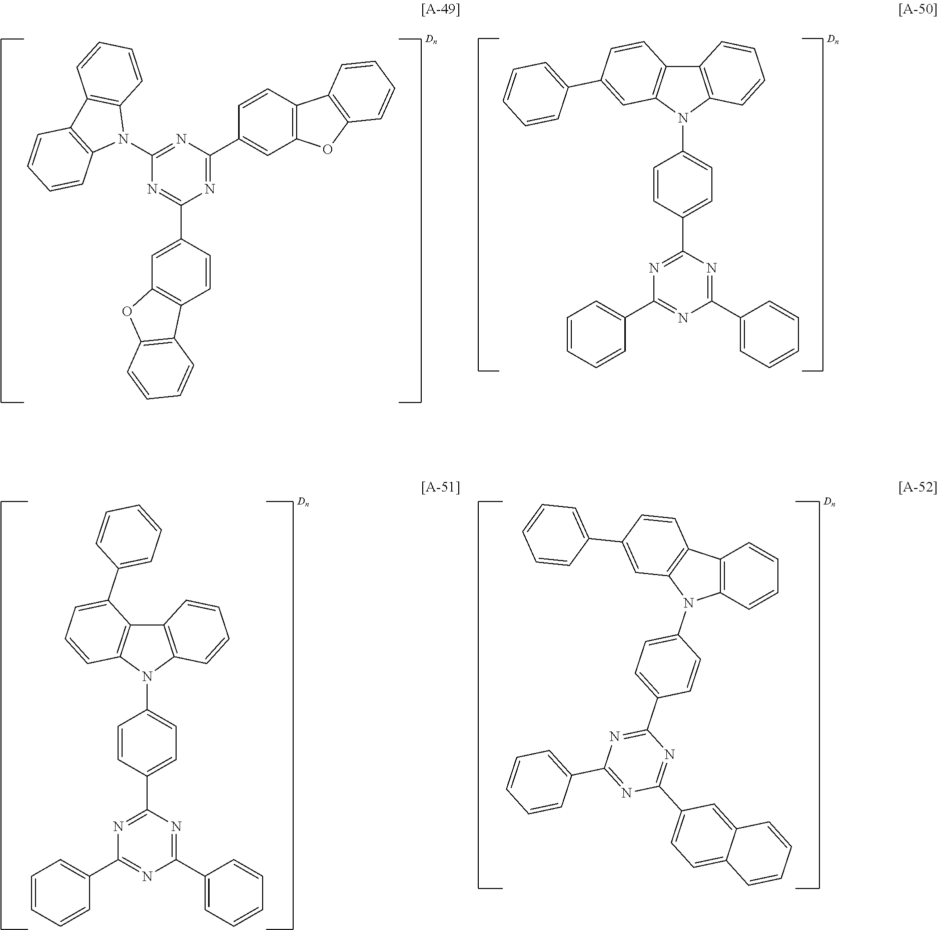

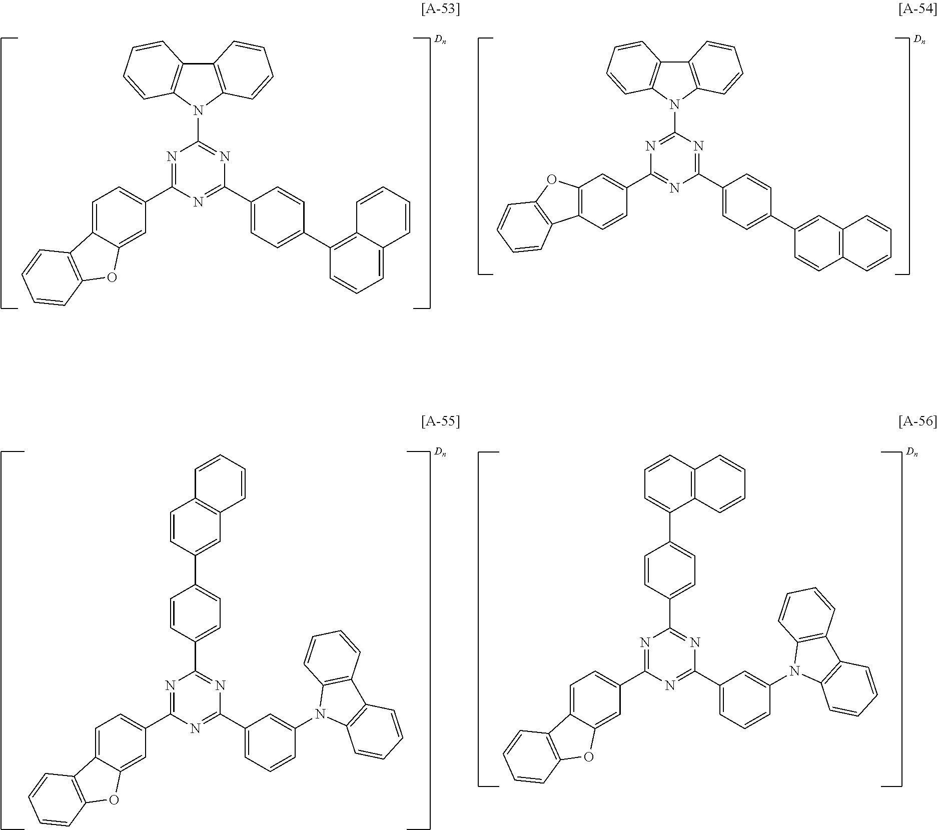

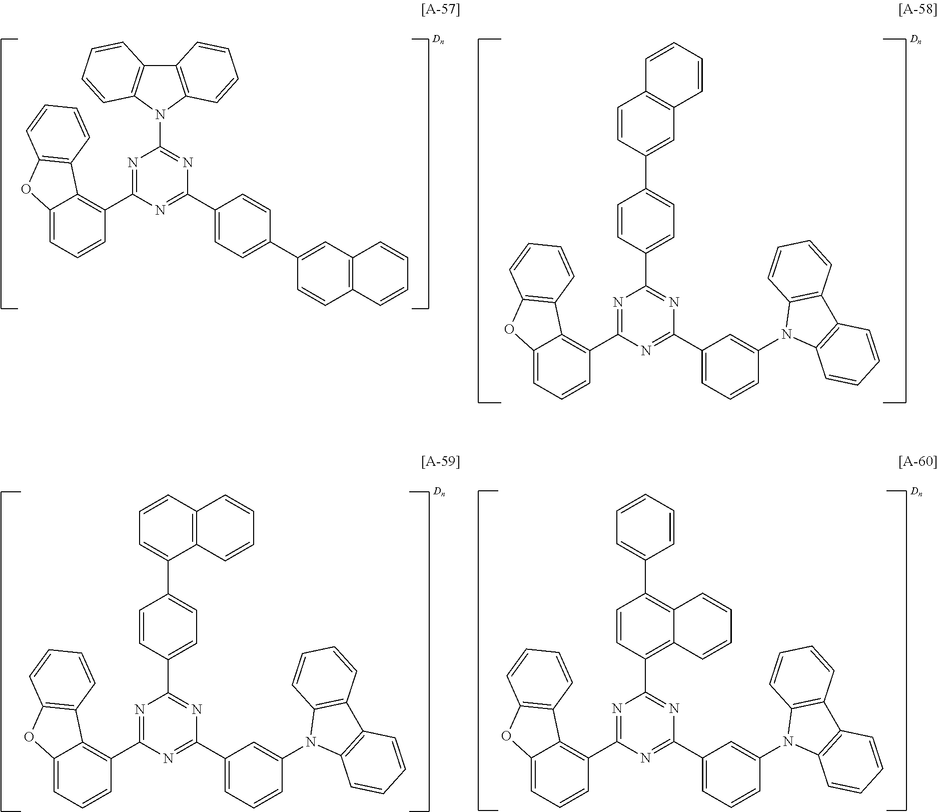

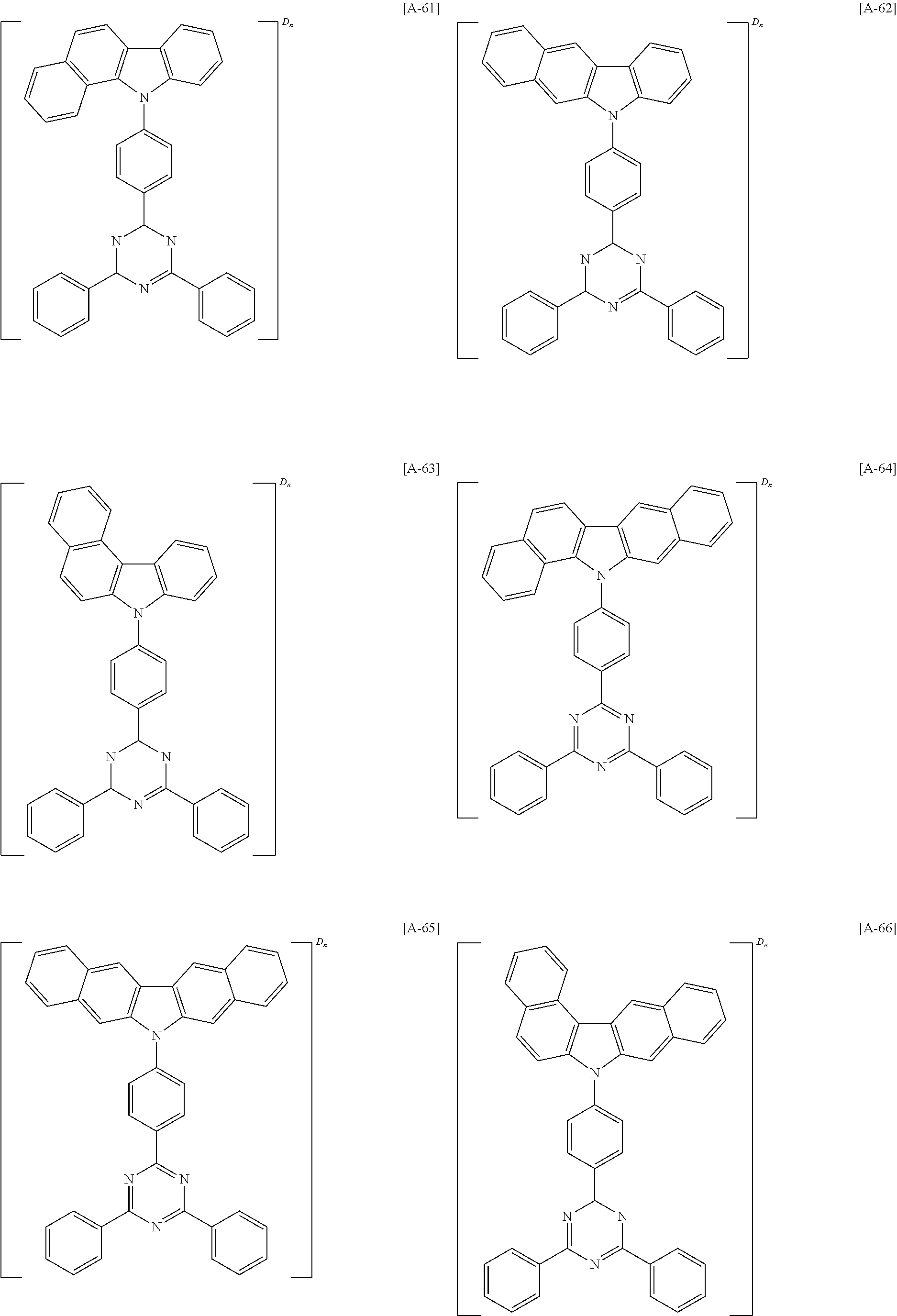

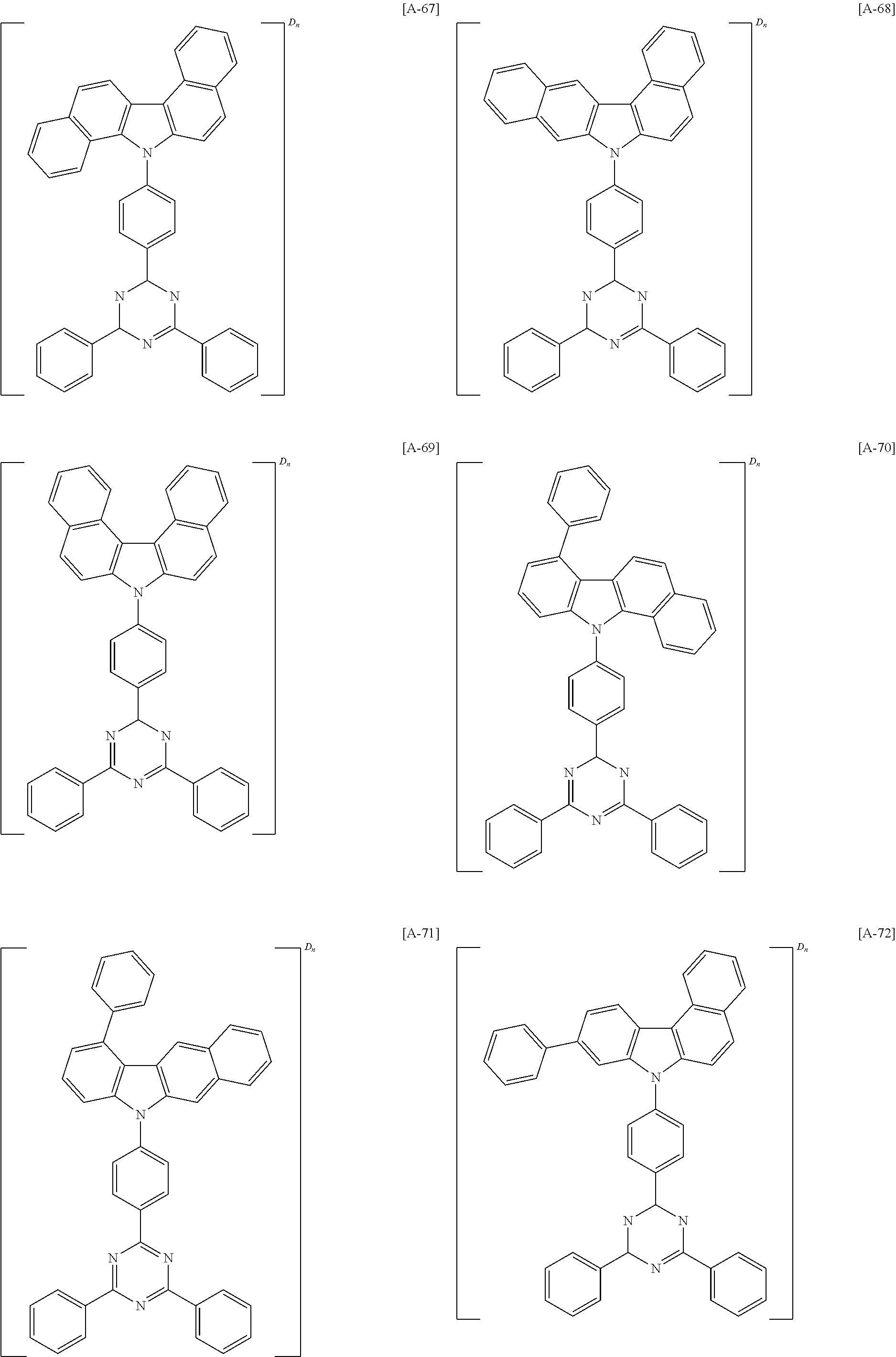

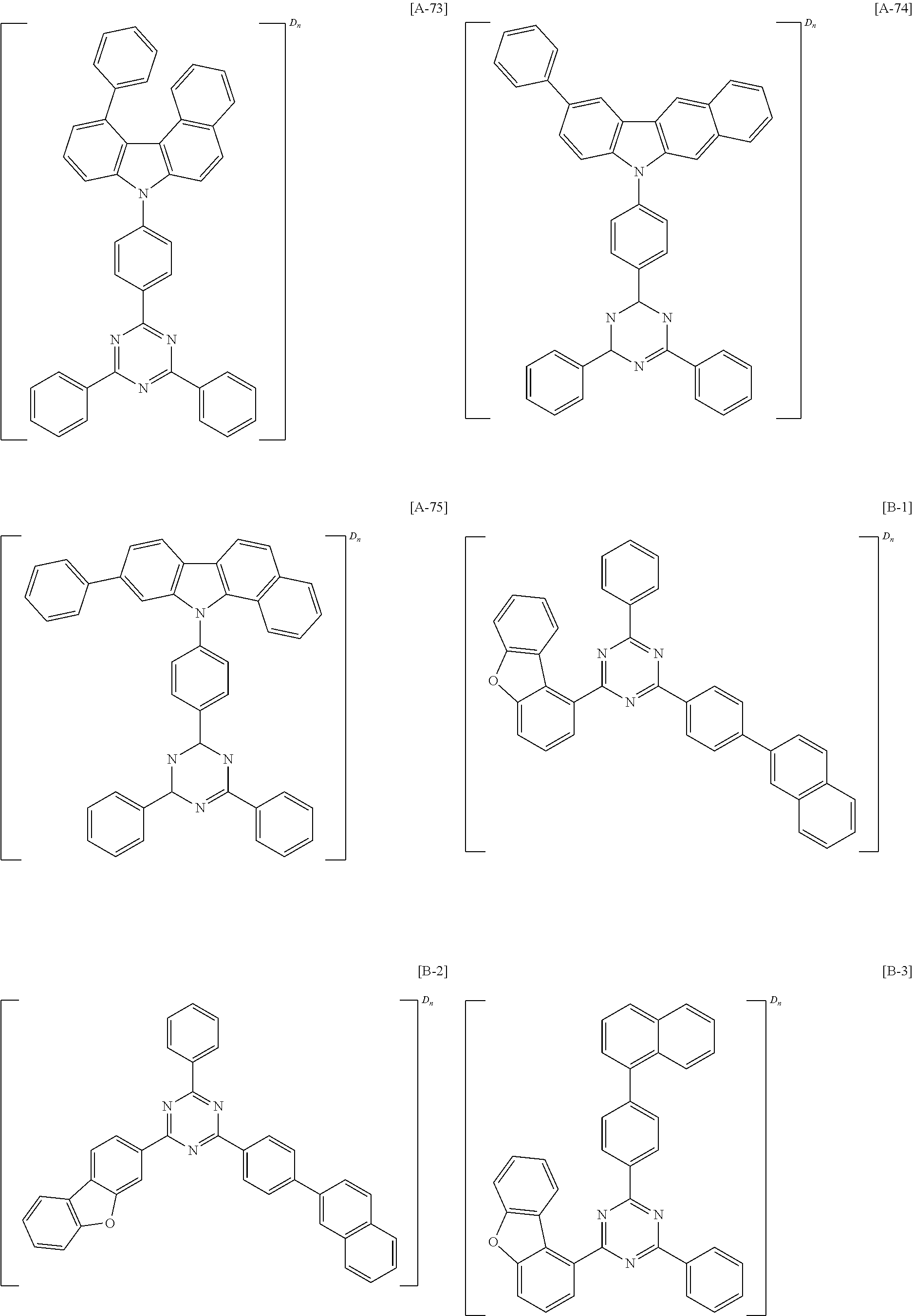

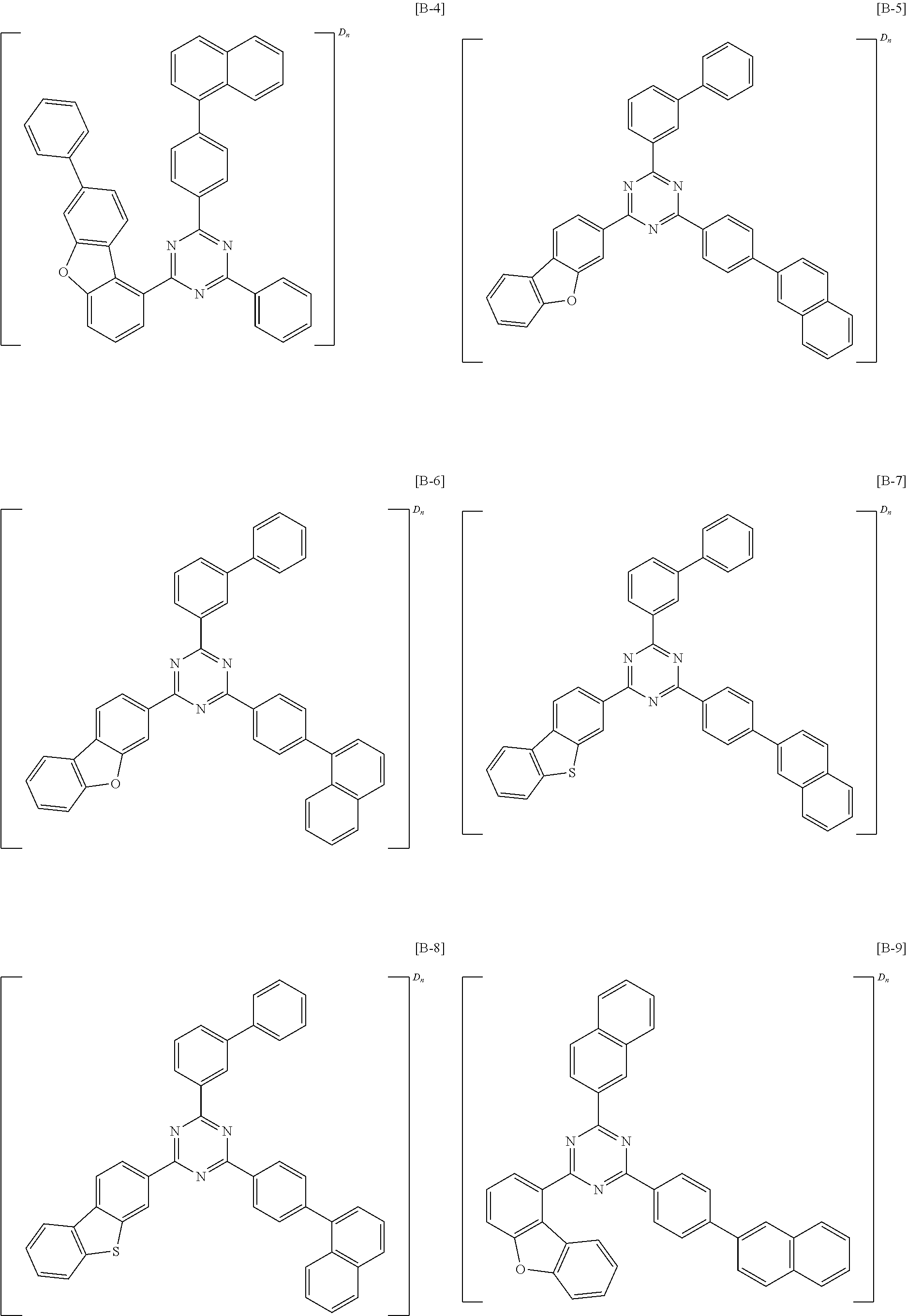

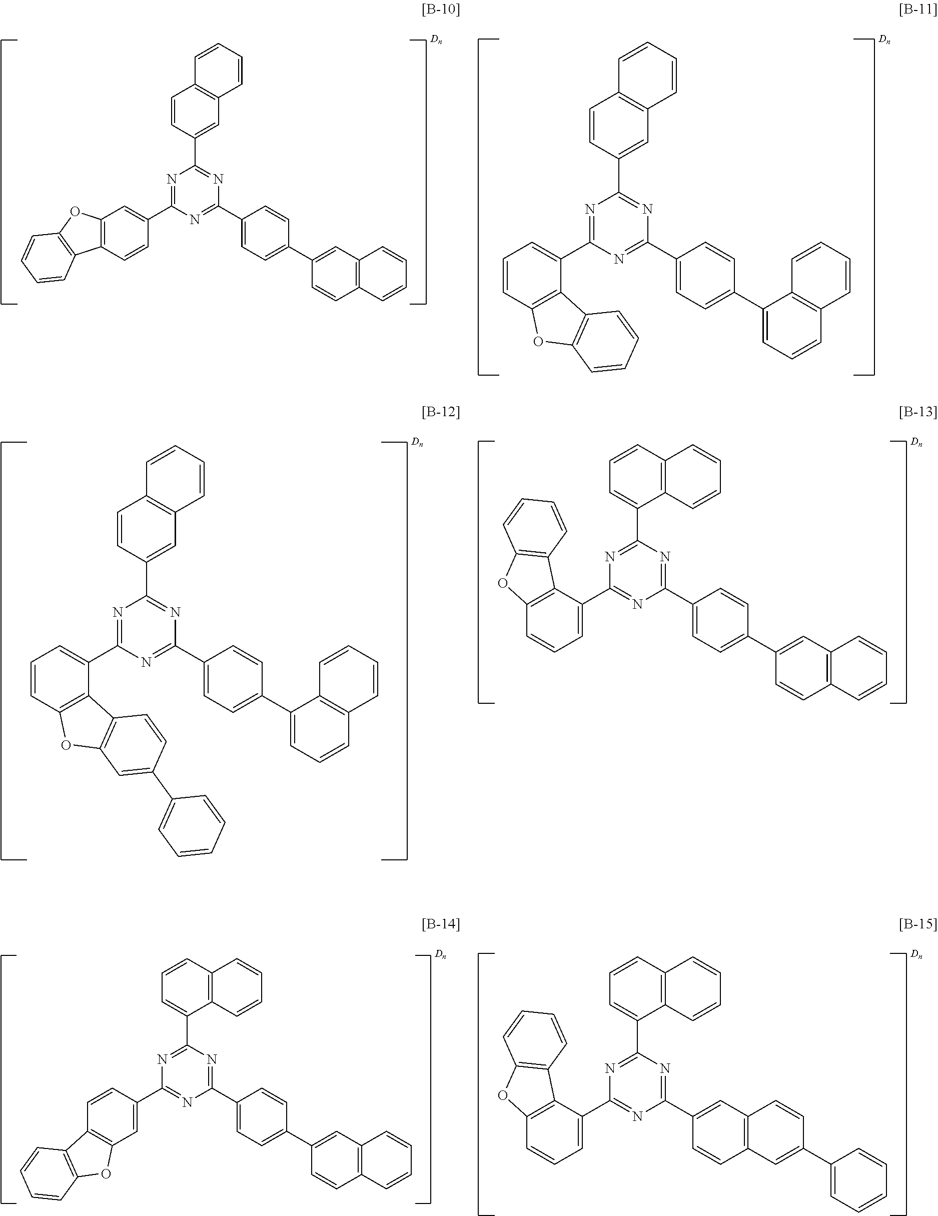

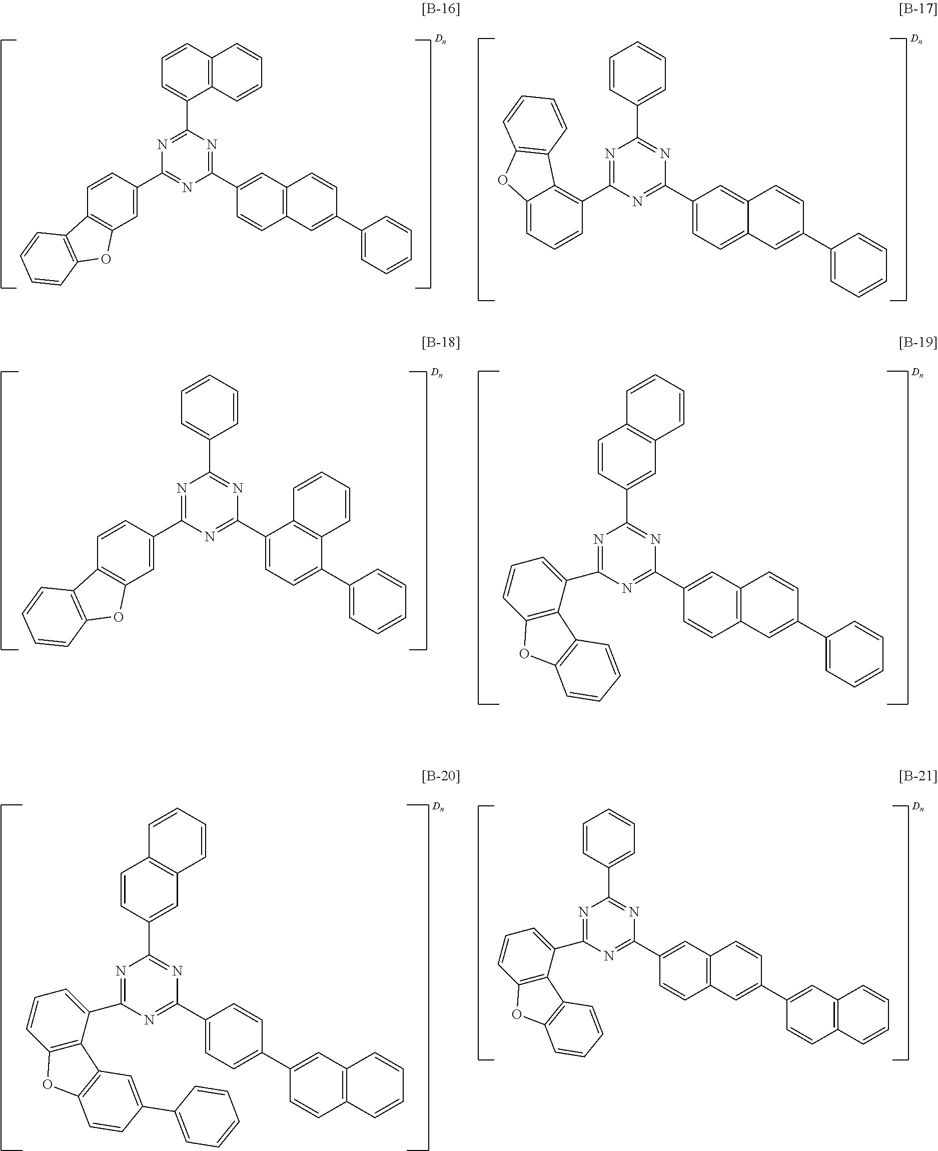

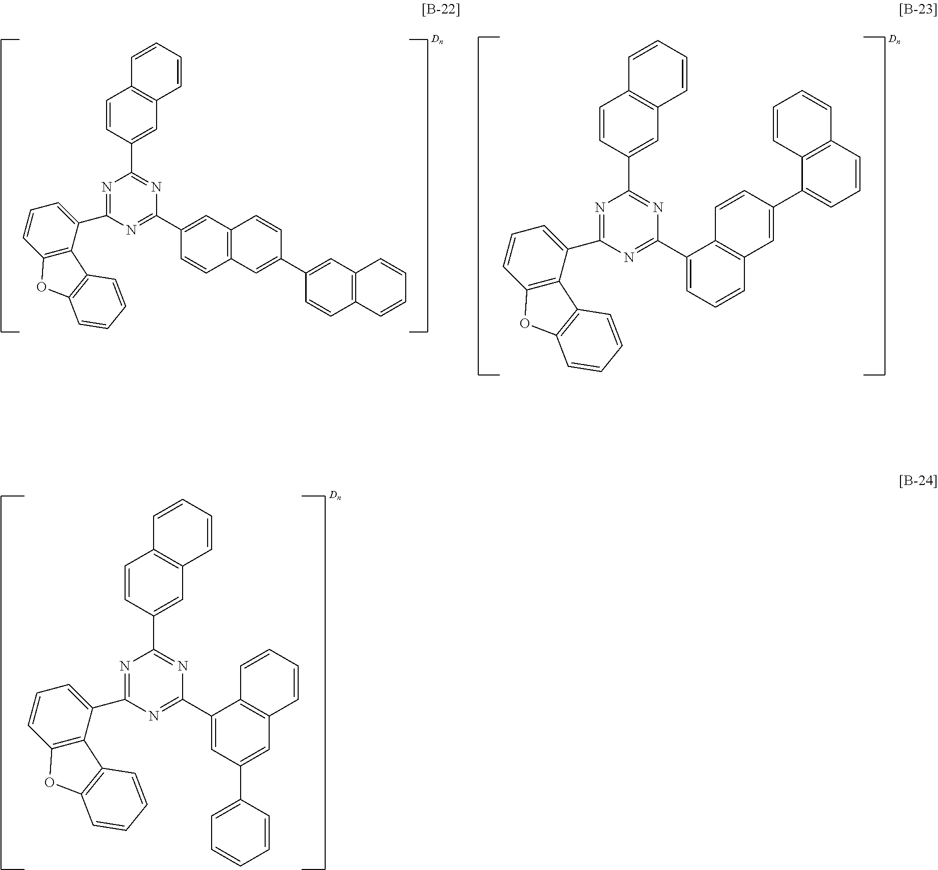

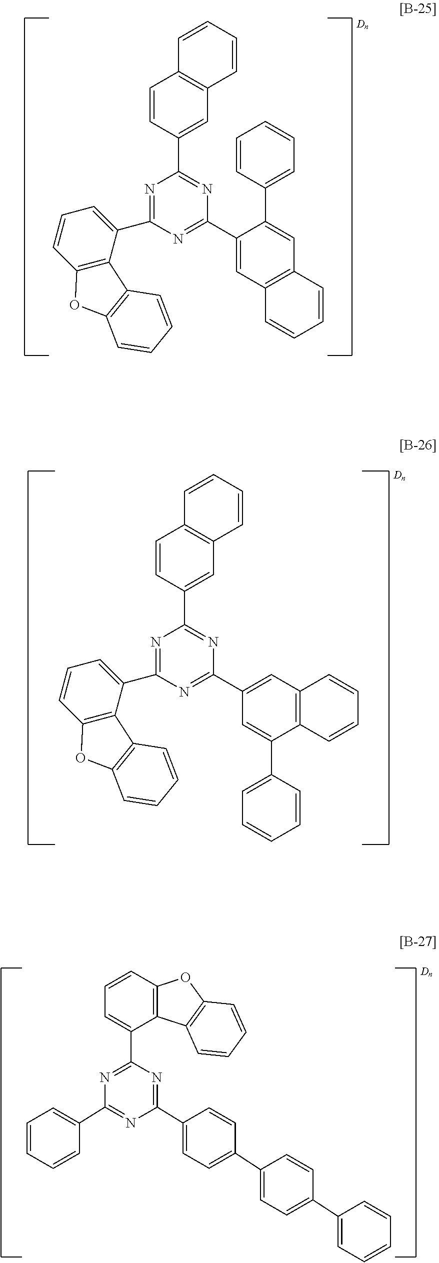

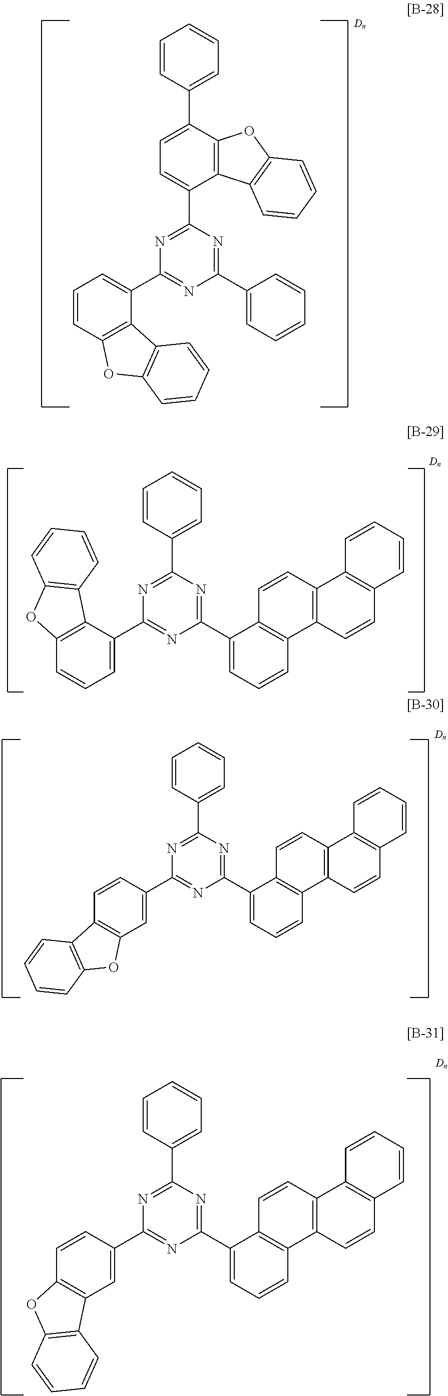

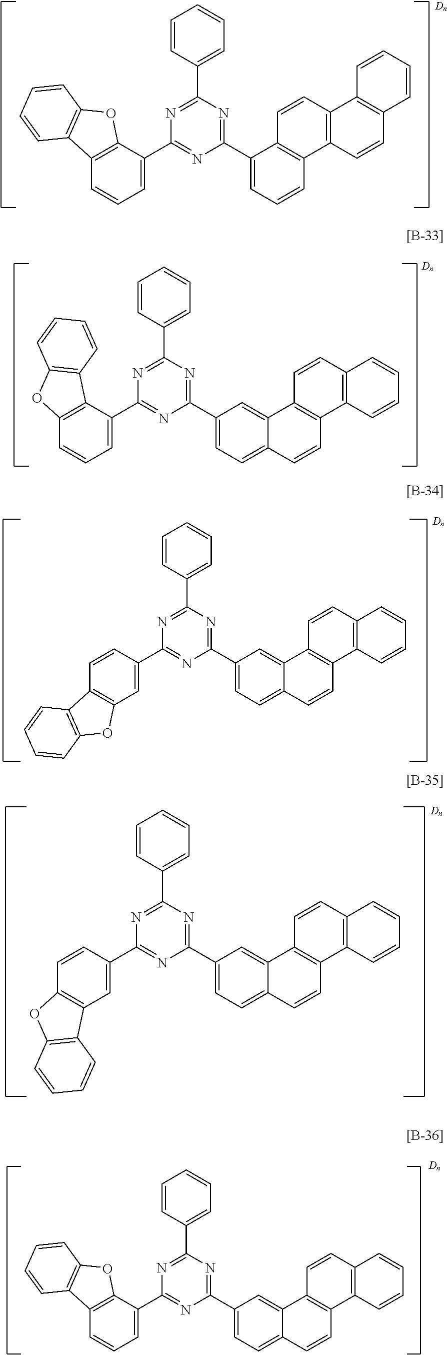

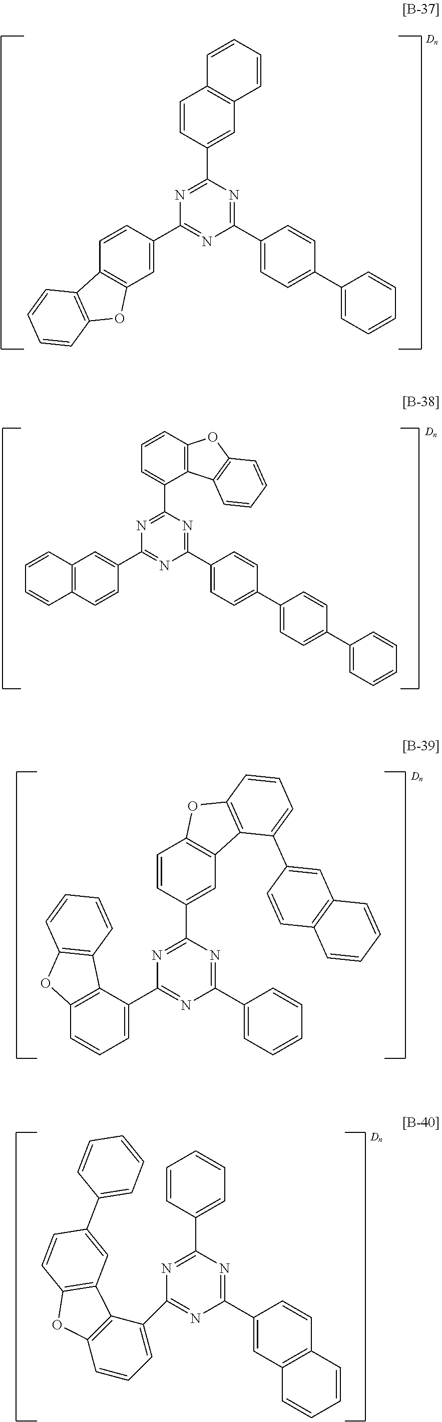

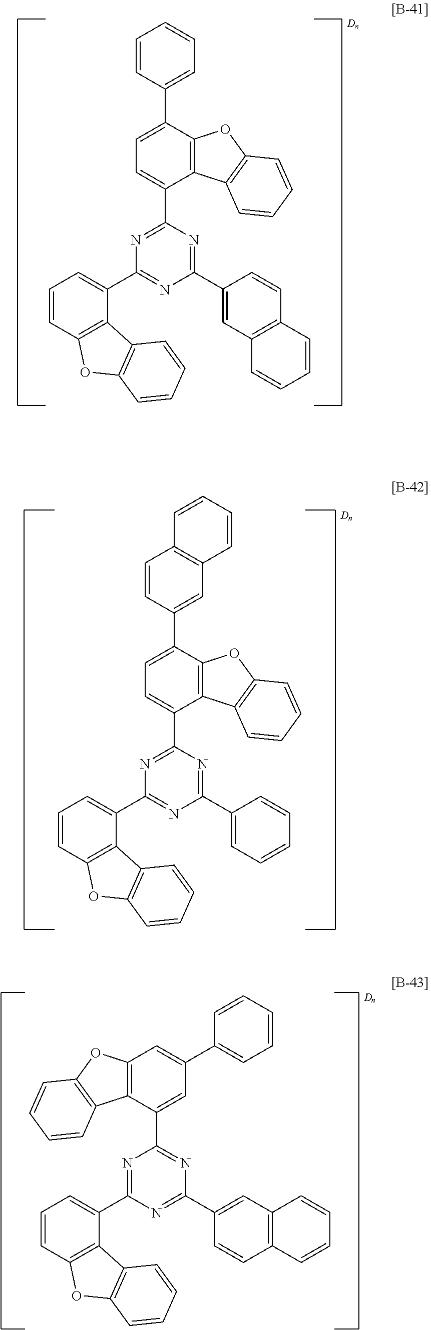

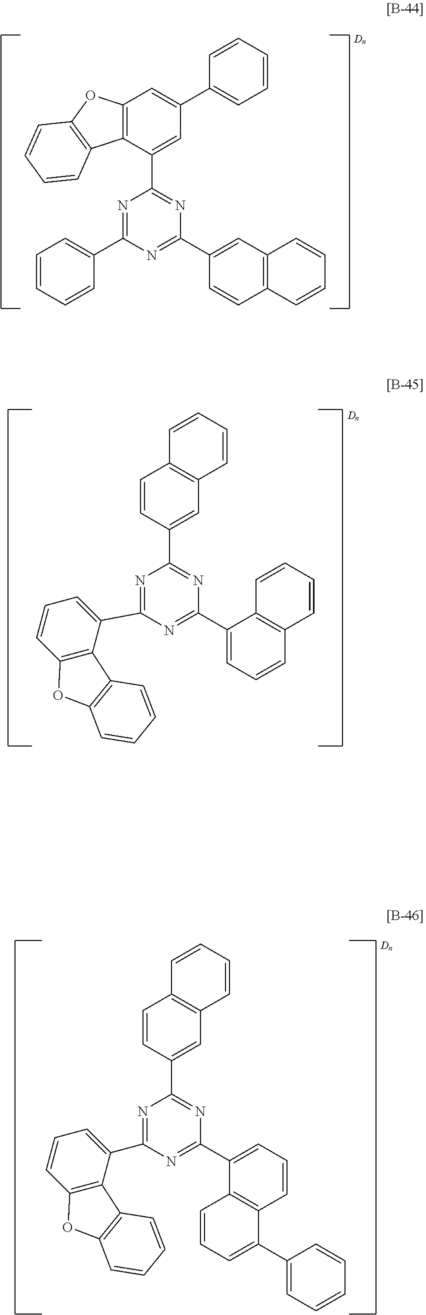

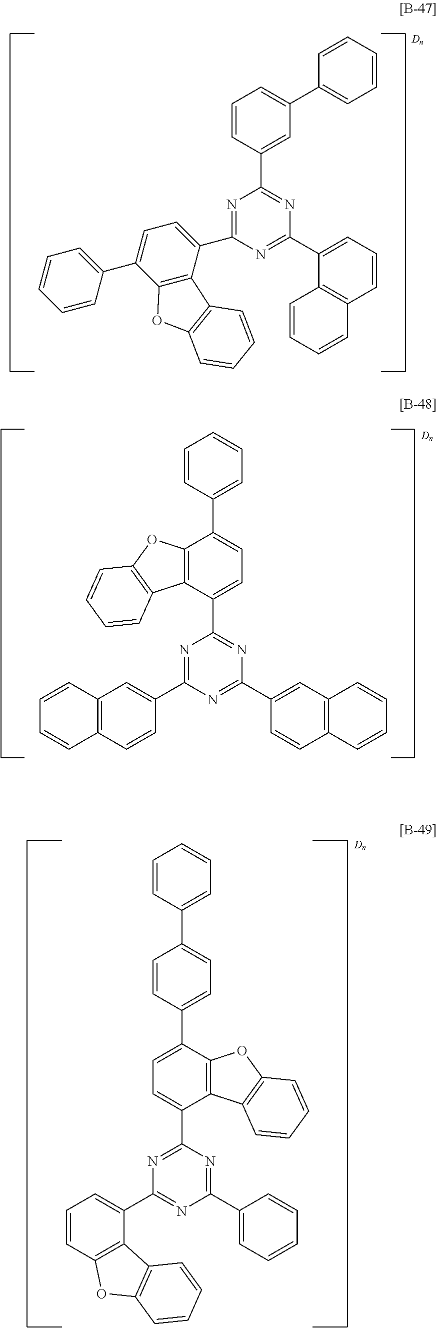

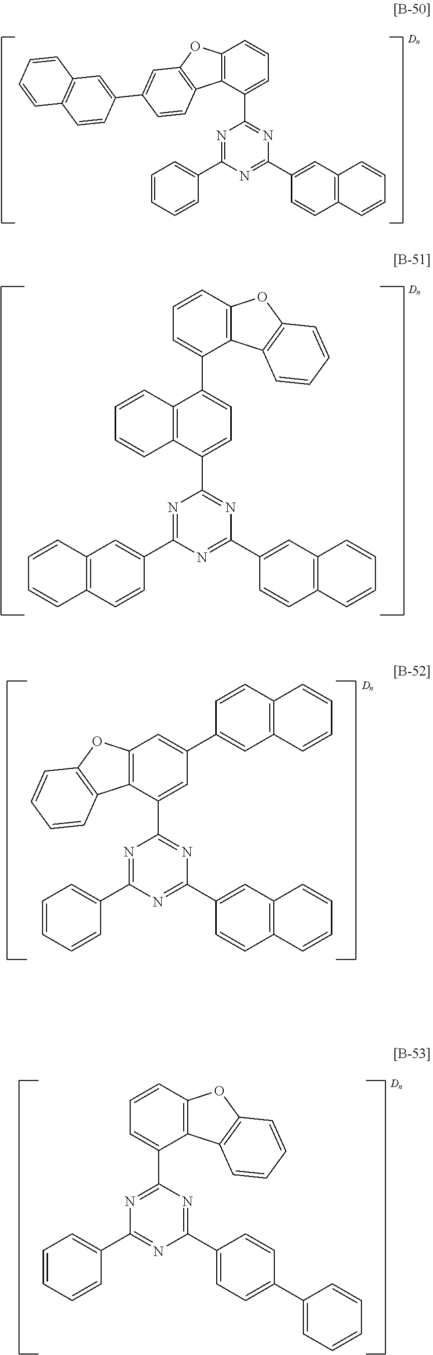

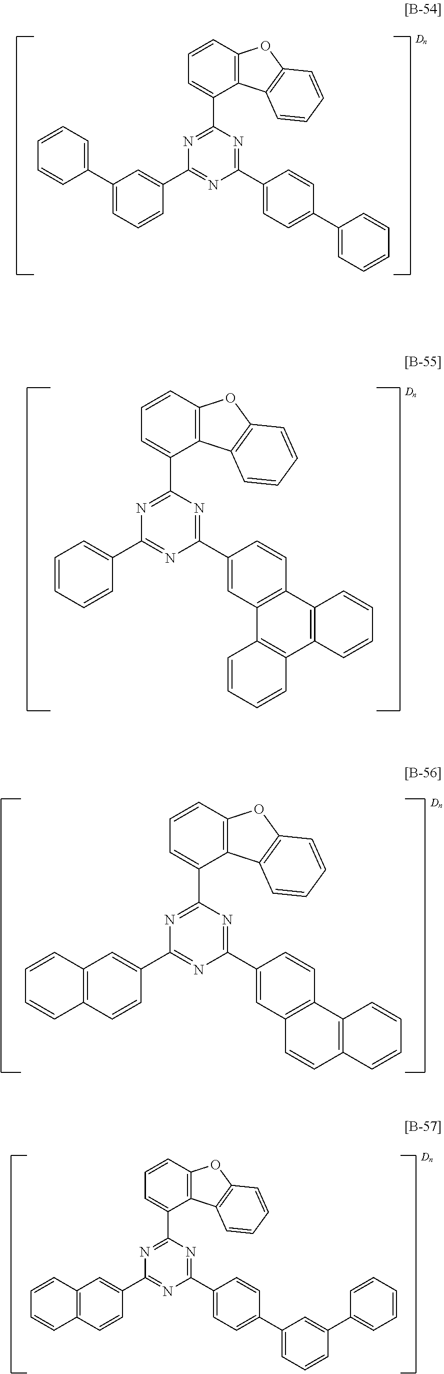

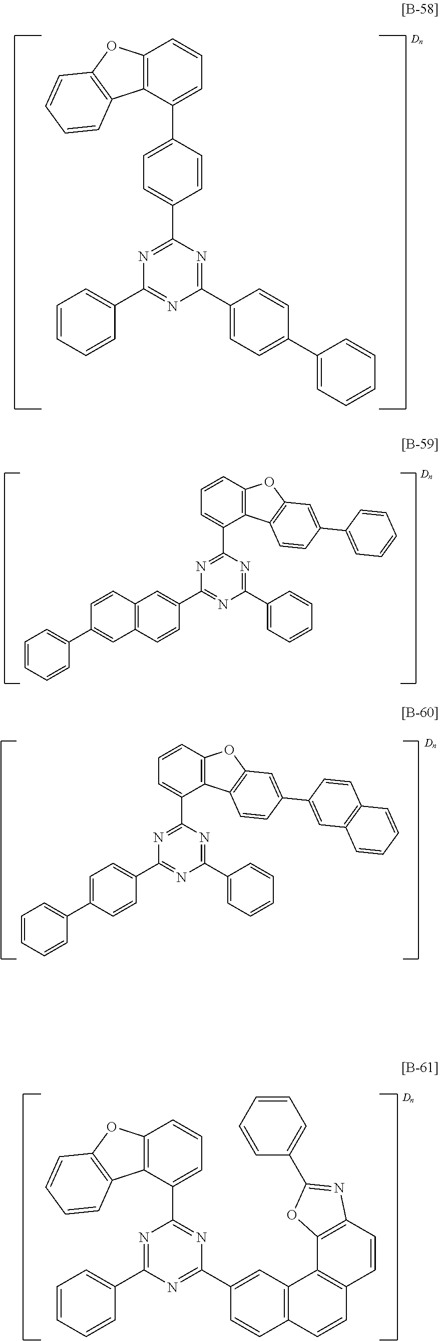

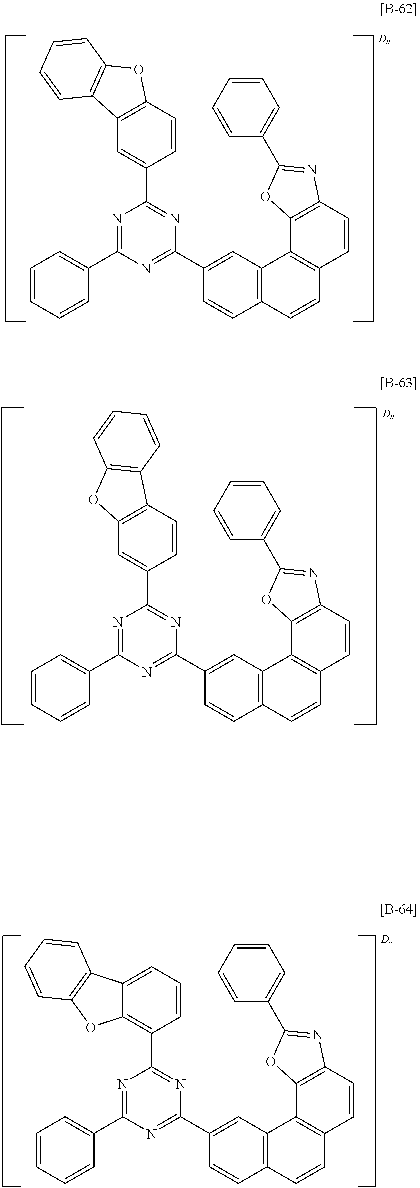

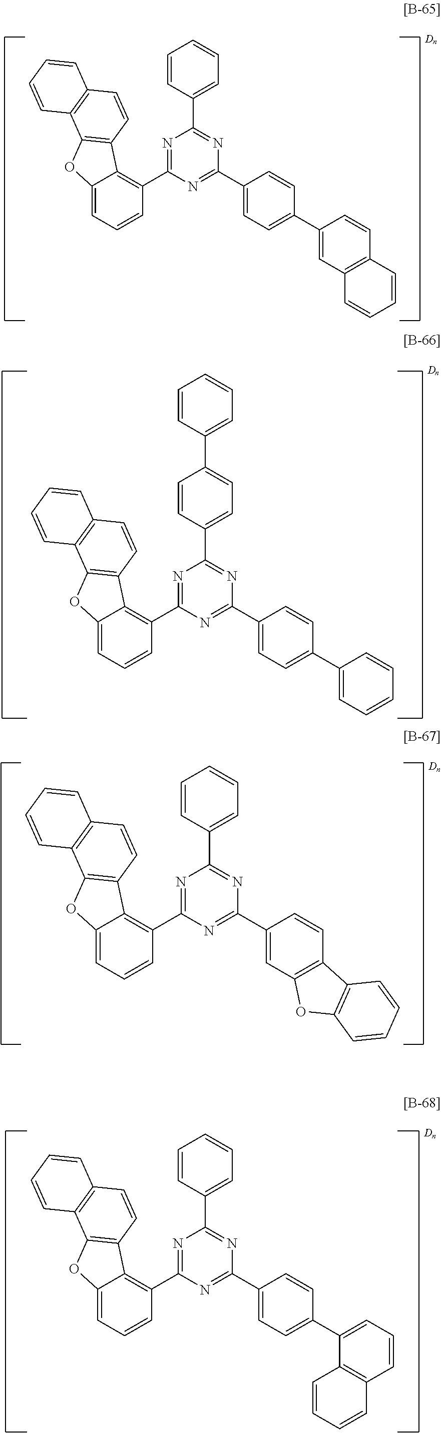

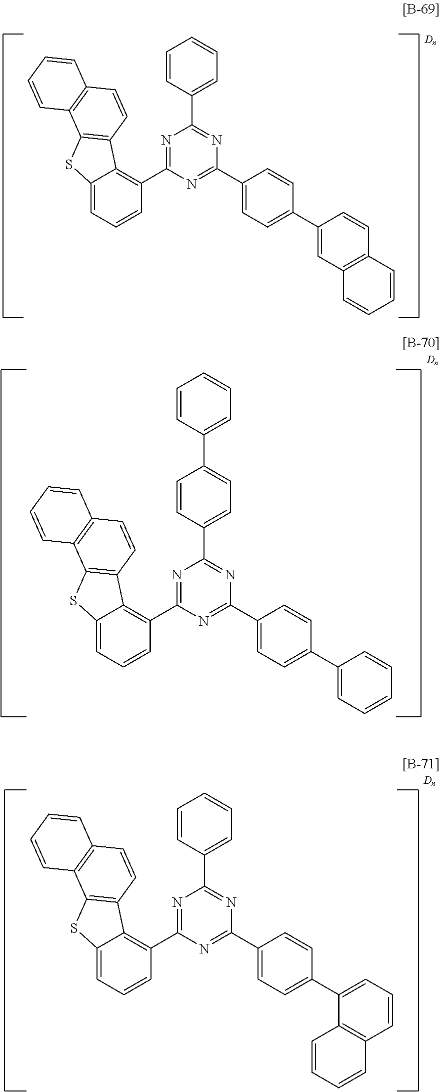

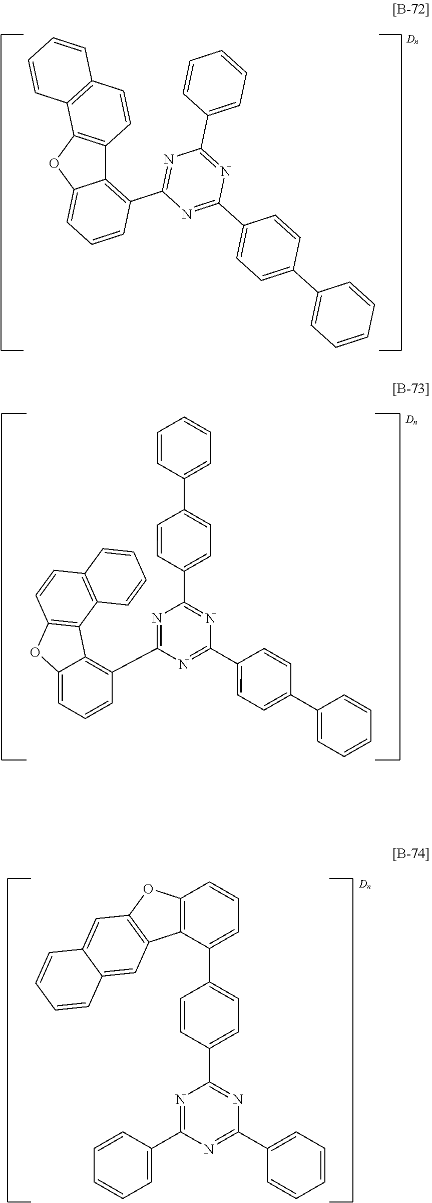

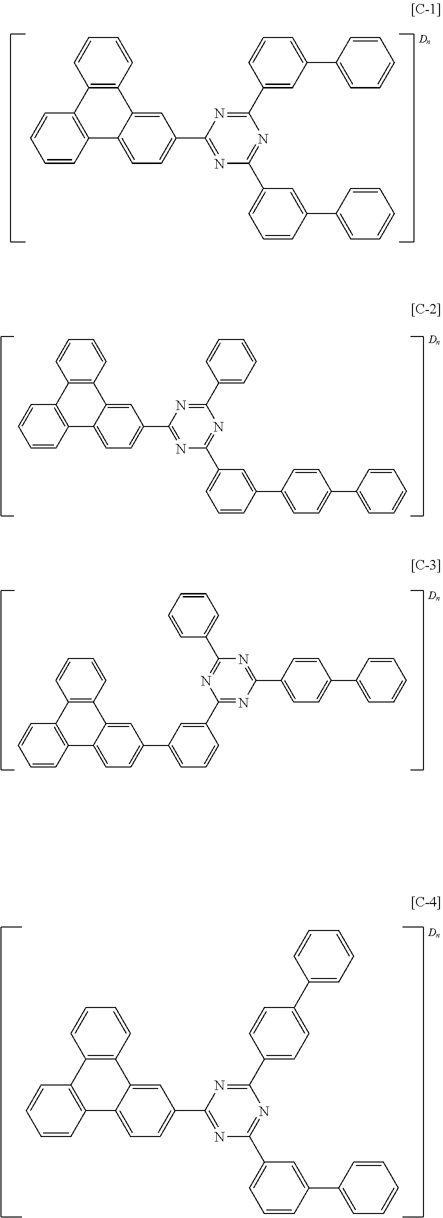

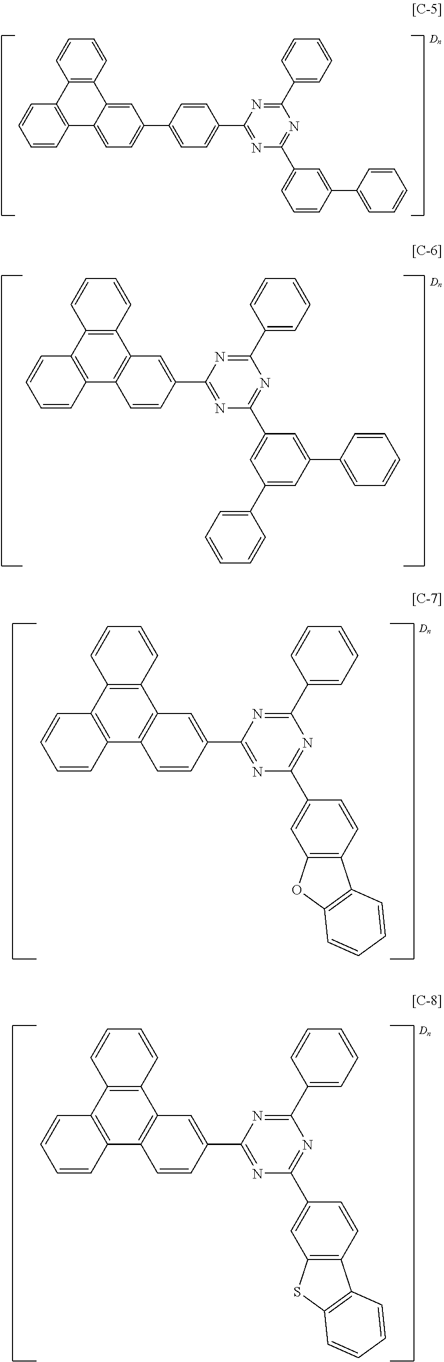

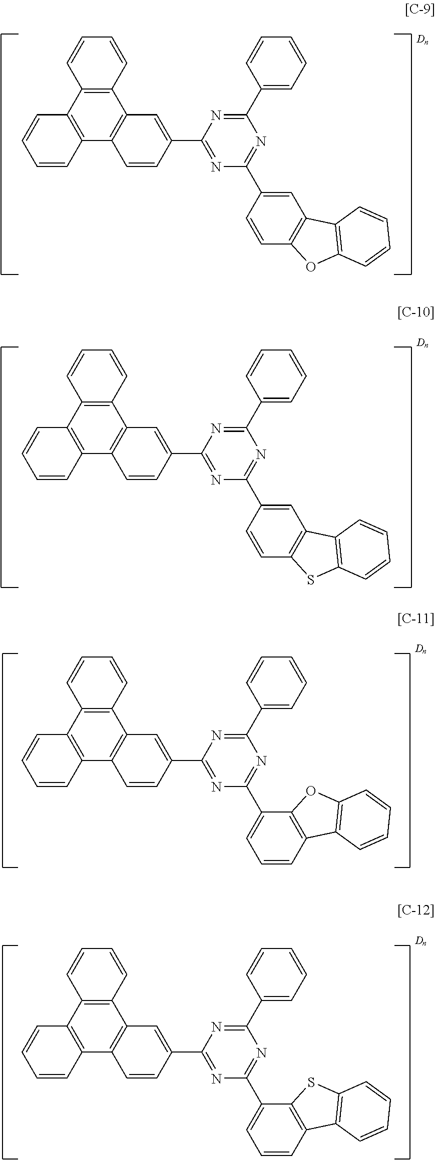

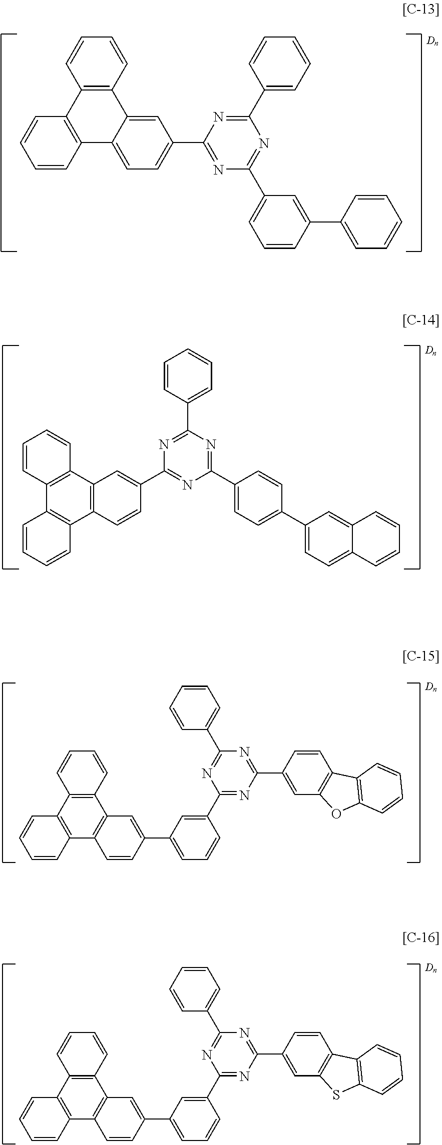

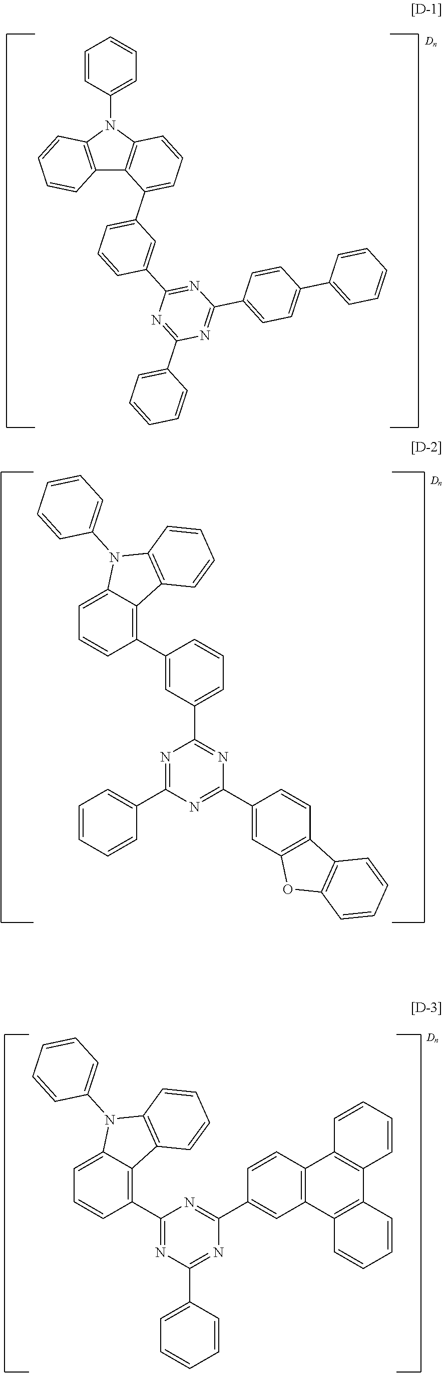

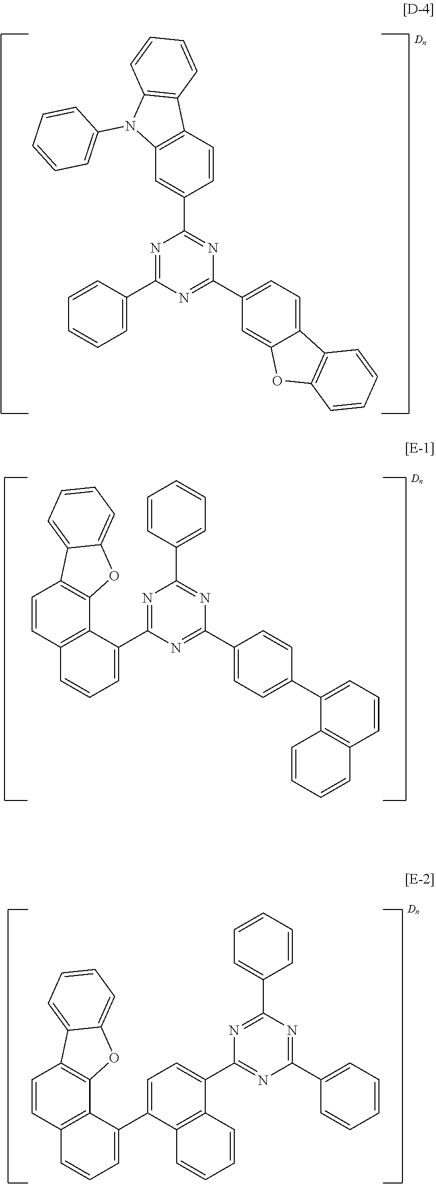

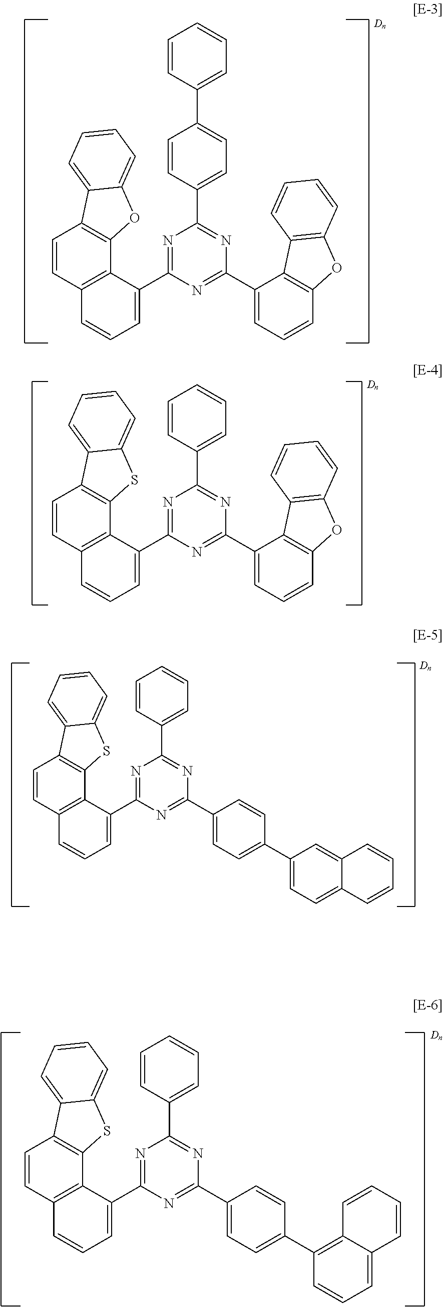

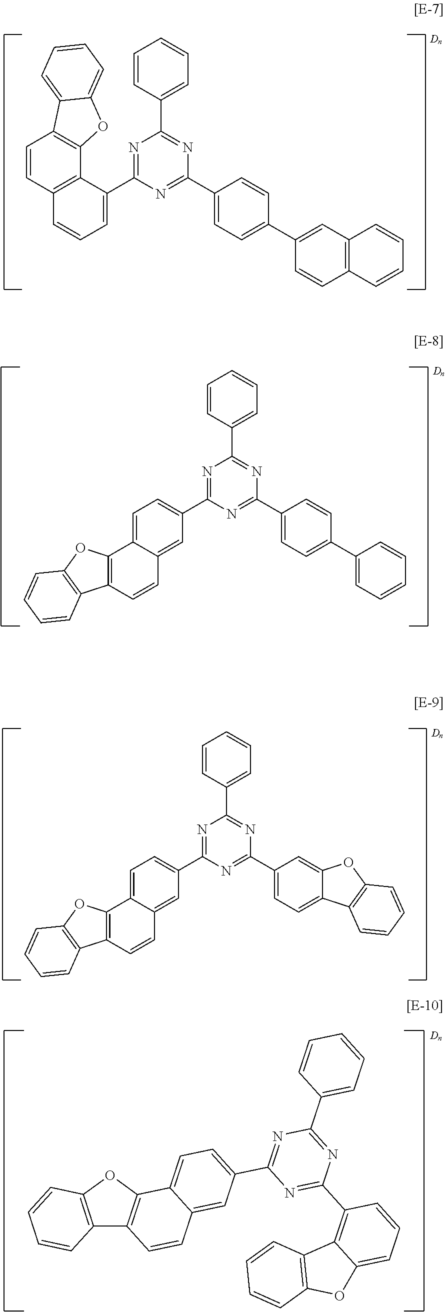

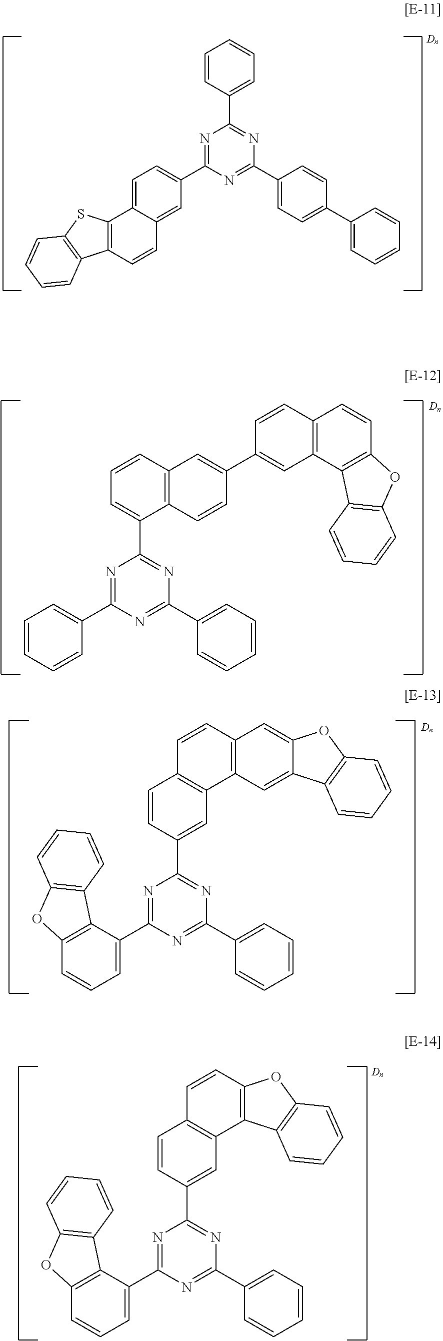

(Dn means the number of deuterium atoms substituted, n is an integer greater than or equal to 0, and the maximum number of n corresponds to the number of substitutable hydrogen positions)

In the light emitting layer 32, the first compound and the second compound may be included as a host, and may be included in a weight ratio of, e.g., about 1:99 to 99:1. By being included in the above range, the hole transport ability of the first compound and the electron transport ability of the second compound may be used to achieve a proper weight ratio to implement bipolar characteristics, thereby improving efficiency and life-span. Within the above range, they may be included in a weight ratio of, e.g., about 90:10 to 10:90, about 80:20 to 20:80, and, e.g., about 80:20 to about 30:70, about 80:20 to about 40:60, and about 80:20 to about 50:50. In an implementation, they may be included in a weight ratio of about 80:20, about 70:30, or about 60:40.

In an implementation, by introducing fused-ring polycyclic functional groups such as naphthalene, phenanthrene, benzophenanthrene, chrysene, or triphenylene, the Tl energy level may be lowered, helping facilitate exciton transfer to the red emitting dopant, thereby helping improve the efficiency of the device.

The light emitting layer 32 may further include, e.g., one or more compounds other than the aforementioned first compound and second compound as a host.

The light emitting layer 32 may further include, e.g., a dopant.

The dopant may be, e.g., a phosphorescent dopant, e.g., a red, green, or blue phosphorescent dopant, and may be, e.g., a red or green phosphorescent dopant.

The dopant is a material mixed with the compound for an organic optoelectronic device in a small amount to cause light emission, and may be generally a material such as a metal complex that emits light by multiple excitation into a triplet or more. The dopant may be, e.g., an inorganic, organic, or organic/inorganic compound, and one or more types thereof may be used.

Examples of the dopant may be or include a phosphorescent dopant and examples of the phosphorescent dopant may be or include an organometal compound including Ir, Pt, Os, Ti, Zr, Hf, Eu, Tb, Tm, Fe, Co, Ni, Ru, Rh, Pd, or a combination thereof. The phosphorescent dopant may be, e.g., a compound represented by Chemical Formula Z.

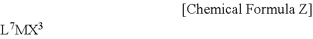

In Chemical Formula Z, M may be, e.g., a metal and L⁷ and X³ may be the same or different and may be, e.g., a ligand forming a complex compound with M.

The M may be, e.g., Ir, Pt, Os, Ti, Zr, Hf, Eu, Tb, Tm, Fe, Co, Ni, Ru, Rh, Pd, or a combination thereof, and L⁷ and X³ may be, e.g., a bidentate ligand.

The ligands represented by L⁷ and X³ may be, e.g., one of Chemical Formula Z-1 to Chemical Formula Z-8.

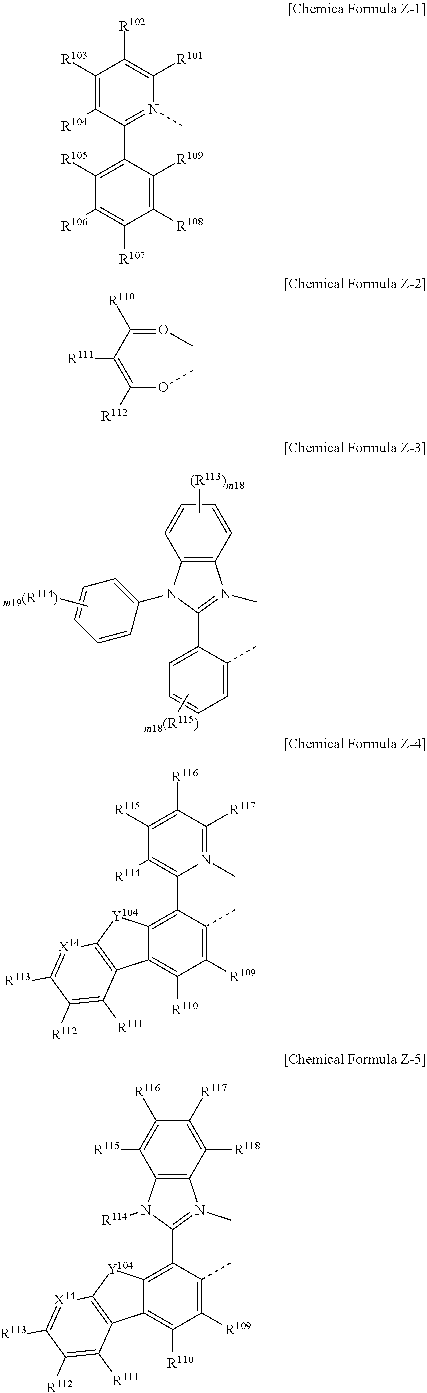

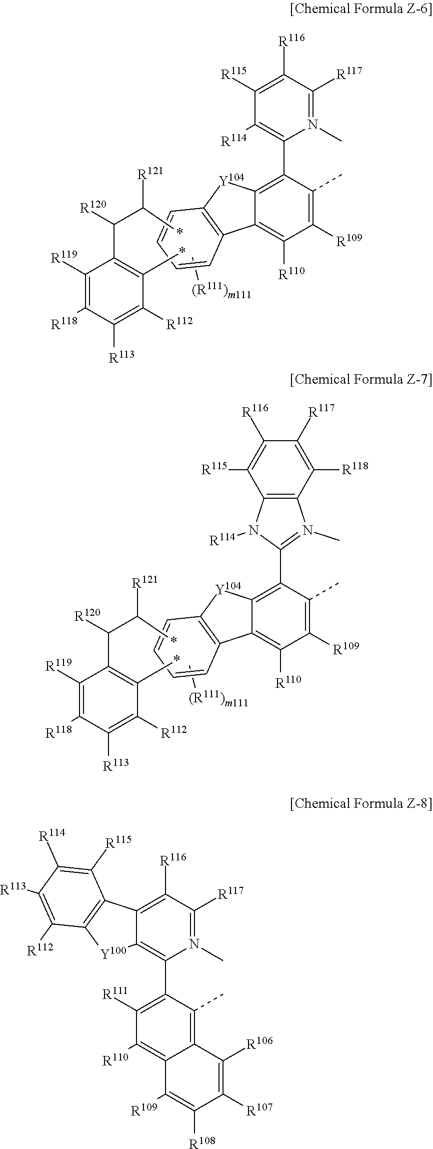

In Chemical Formula Z-1 to Chemical Formula Z-8, X¹⁴ may be, e.g., carbon or nitrogen.

Y¹⁰⁰ may be, e.g., O or S.

R¹⁰¹ to R¹²² may each independently be, e.g., hydrogen, deuterium, a halogen, a substituted or unsubstituted C1 to C30 alkyl group, a substituted or unsubstituted C3 to C30 cycloalkyl group, a substituted or unsubstituted C6 to C20 aryl group, —SiR¹³³R¹³⁴R¹³⁵, or —GeR¹³³R¹³⁴R¹³⁵; or may be linked to adjacent substituents to form a substituted or unsubstituted ring, and, e.g., together with pyridine may form a substituted or unsubstituted quinoline, a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline.

R¹³³ to R¹³⁵ may each independently be, e.g., a substituted or unsubstituted C1 to C6 alkyl group.

m18 may be, e.g., an integer of 1 to 4.

m19 may be, e.g., an integer of 1 to 5.

m111 may be, e.g., an integer of 1 or 2.

Examples of ligands represented by L⁷ and X³ may be, e.g., a chemical formula of Group A.

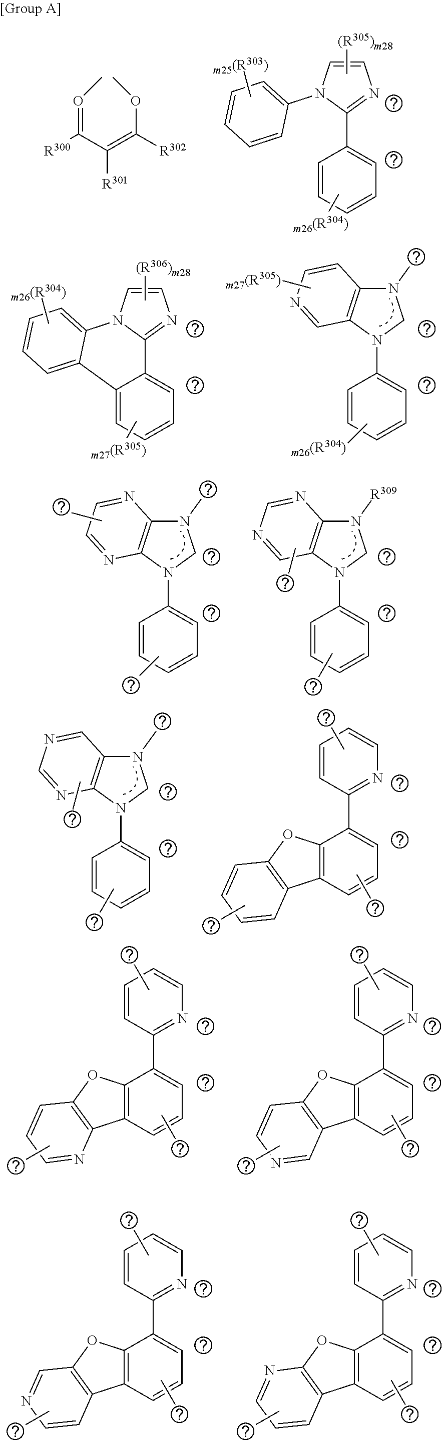

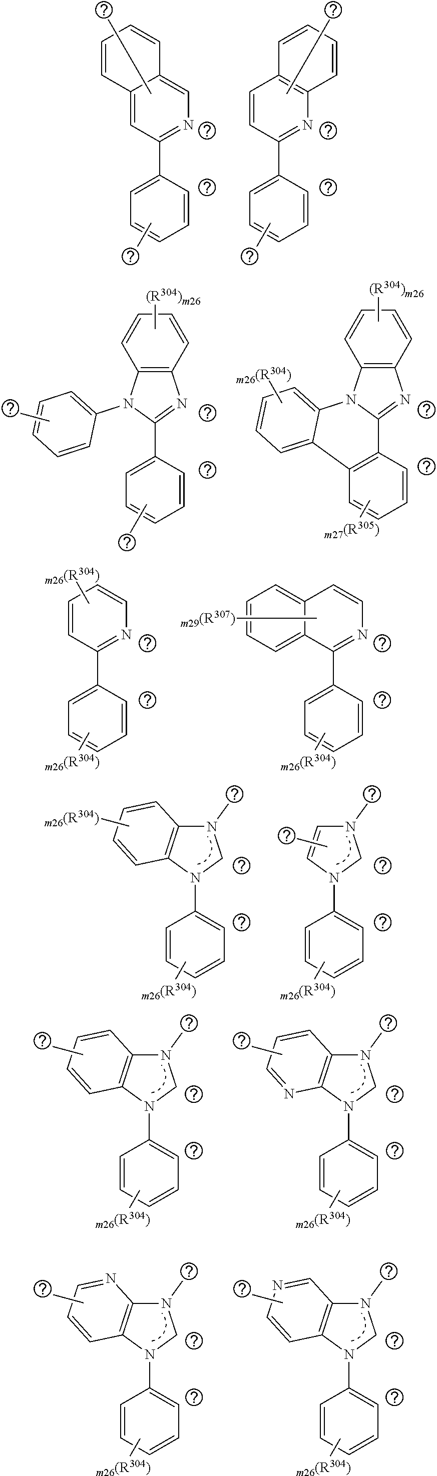

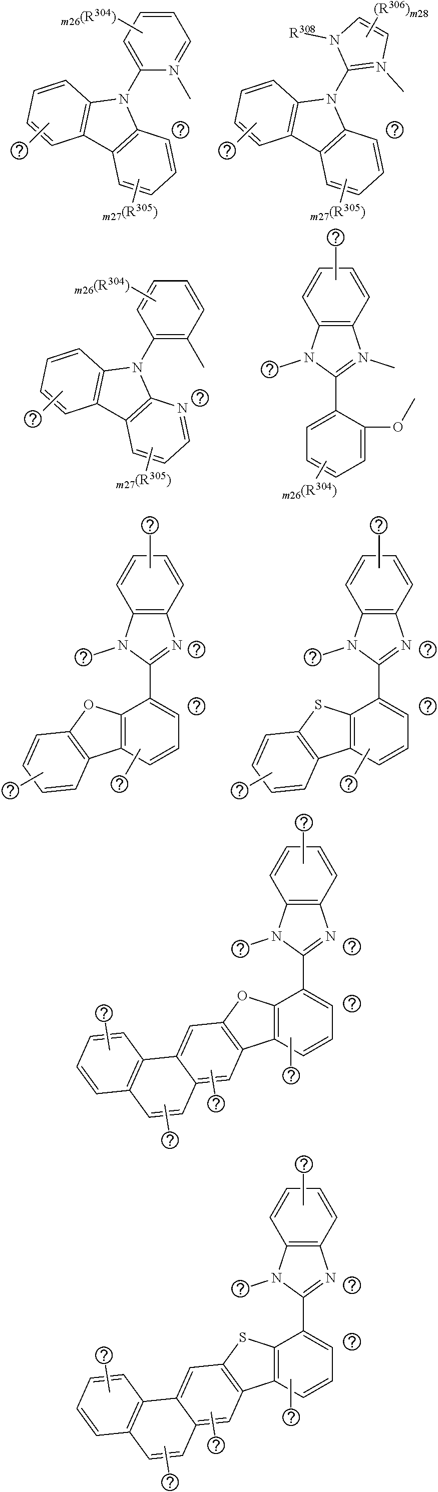

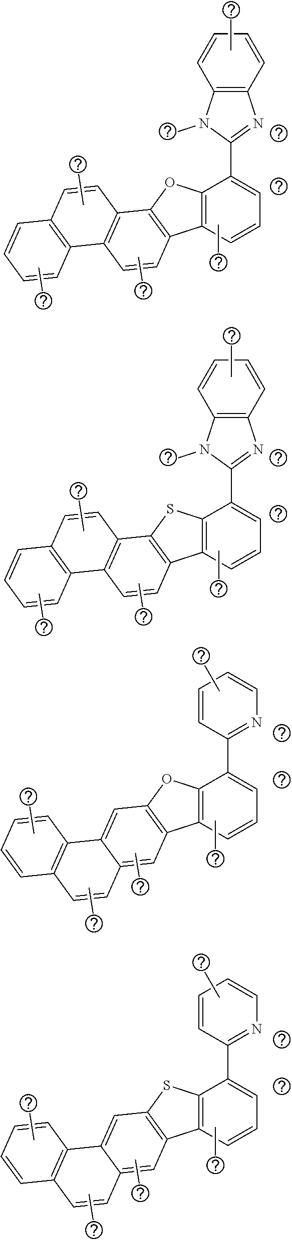

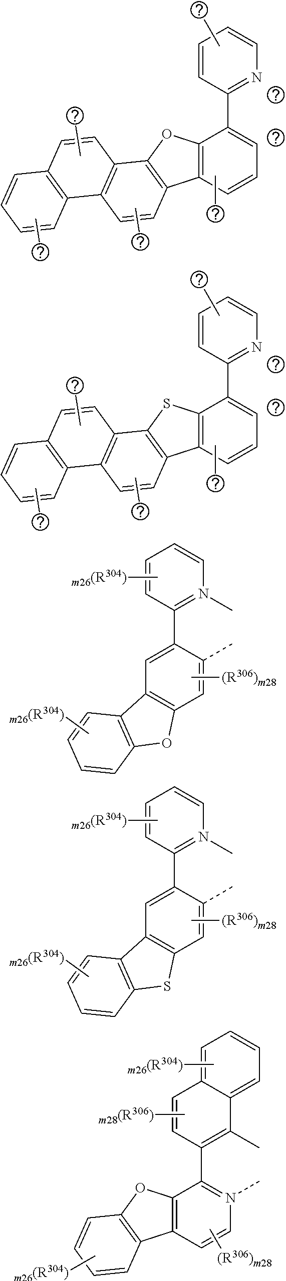

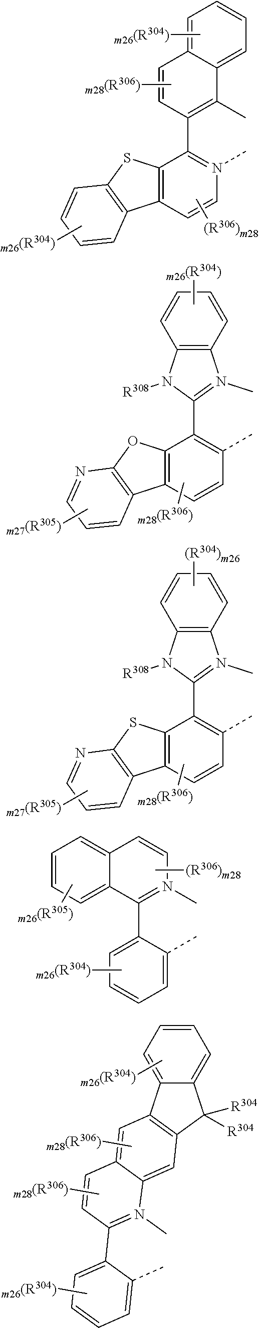

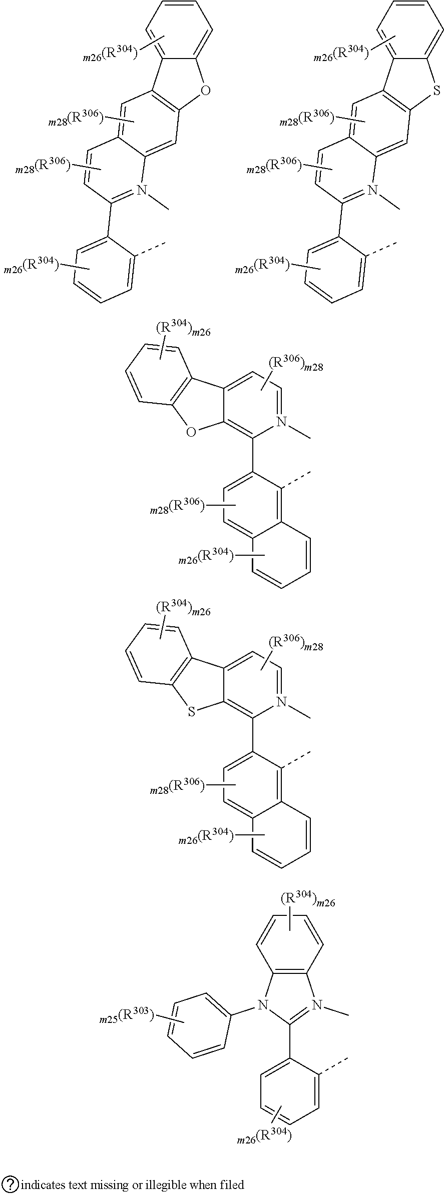

In Group A, R³⁰⁰ to R³⁰² may each independently be, e.g., hydrogen, deuterium, a C1 to C30 alkyl group substituted or unsubstituted with a halogen, a C6 to C30 aryl group substituted or unsubstituted with a C1 to C30 alkyl, or a halogen.

R³⁰³ to R³⁰⁸ may each independently be, e.g., hydrogen, deuterium, a halogen, a substituted or unsubstituted C1 to C30 alkyl group, a substituted or unsubstituted C1 to C30 alkoxy group, a substituted or unsubstituted C3 to C30 cycloalkyl group, a substituted or unsubstituted C2 to C30 alkenyl group, a substituted or unsubstituted C6 to C30 aryl group, a substituted or unsubstituted C1 to C30 heteroaryl group, a substituted or unsubstituted C1 to C30 amino group, a substituted or unsubstituted C6 to C30 arylamino group, SF₅, a trialkylsilyl group having a substituted or unsubstituted C1 to C30 alkyl group, a dialkylarylsilyl group having a substituted or unsubstituted C1 to C30 alkyl group or a C6 to C30 aryl group, or a triarylsilyl group having a substituted or unsubstituted C6 to C30 aryl group.

m25 may be, e.g., an integer of 1 to 5.

m26 may be, e.g., an integer of 1 to 4.

m27 may be, e.g., an integer of 1 to 3.

m28 may be, e.g., an integer of 1 or 2.

m29 may be, e.g., an integer of 1 to 6.

In an implementation, one of m25 to m29 may be an integer of 2 or more, and the respective ones of R³⁰³ to R³⁰⁷ may be the same or different from each other.

In some example embodiments, the phosphorescent dopant may be an iridium complex, and may be, e.g., represented by one of Chemical Formula 6 to Chemical Formula 8.

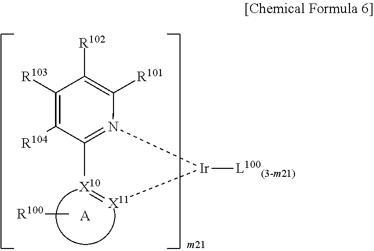

In Chemical Formula 6, ring A may be, e.g., a monocyclic ring or a polycyclic fused ring, wherein each ring of the monocyclic ring and polycyclic fused ring may be, e.g., a 5- or 6-membered carbocyclic or heterocyclic ring.

R¹⁰⁰ may represent, e.g., one to a maximum number of monovalent substituents.

In an implementation, there may be two or more R¹⁰⁰ groups, and each R¹⁰⁰ may be the same or different from each other.

R¹⁰¹ to R¹⁰⁴ may each independently be, e.g., hydrogen, deuterium, a halogen, a substituted or unsubstituted C1 to C10 alkyl group, a substituted or unsubstituted C6 to C20 aryl group, —SiR¹¹⁴R¹¹⁵R¹¹⁶, —GeR¹¹⁴R¹¹⁵R¹¹⁶, or a combination thereof.

R¹¹⁴ to R¹¹⁶ may each independently be, e.g., a substituted or unsubstituted C1 to C6 alkyl group.

X¹⁰ and X¹¹ may each independently be, e.g., carbon or nitrogen.

L¹⁰⁰ may be, e.g., a ligand of a monovalent anion or a bidentate ligand, which coordinates to iridium through the unshared electron pair of carbon or a heteroatom.

m21 may be, e.g., an integer of 0 to 3.

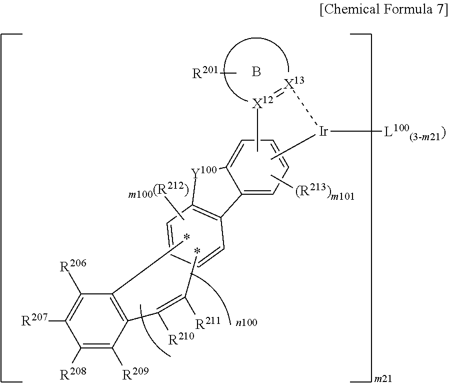

In Chemical Formula 7, ring B may be, e.g., a monocyclic ring or a polycyclic fused ring, wherein each ring of the monocyclic ring and polycyclic fused ring may be, e.g., a 5- or 6-membered carbocyclic or heterocyclic ring.

Y¹⁰⁰ may be, e.g., O or S.

R²⁰¹ may represent, e.g., one to a maximum number of monovalent substituents.

In an implementation, there may be two or more R²⁰¹ groups, and each R²⁰¹ may be the same or different from each other.

R²⁰⁶ to R²¹³ may each independently be, e.g., hydrogen, deuterium, a halogen, a substituted or unsubstituted C1 to C10 alkyl group, a substituted or unsubstituted C6 to C20 aryl group, —SiR¹¹⁴R¹¹⁵R¹¹⁶, —GeR¹¹⁴R¹¹⁵R¹¹⁶, or a combination thereof.

R¹¹⁴ to R¹¹⁶ may each independently be, e.g., a substituted or unsubstituted C1 to C6 alkyl group.

X¹² and X¹³ may each independently be, e.g., carbon or nitrogen.

L 100 may be, e.g., a ligand of a monovalent anion or a bidentate ligand, which coordinates to iridium through the unshared electron pair of carbon or a heteroatom.

m21 may be, e.g., an integer of 0 to 3.

m100 may be, e.g., an integer of 1 to 3.

m101 may be, e.g., an integer of 1 or 2.

n100 may be, e.g., an integer of 0 or 1, wherein the absence of a connection bond when n100 is 0.

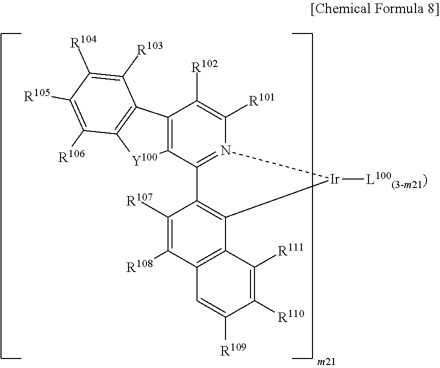

In Chemical Formula 8, Y¹⁰⁰ may be, e.g., O or S.

R¹⁰¹ to R¹¹¹ may each independently be, e.g., hydrogen, deuterium, a halogen, a substituted or unsubstituted C1 to C10 alkyl group, a substituted or unsubstituted C6 to C20 aryl group, —SiR¹¹⁴R¹¹⁵R¹¹⁶, —GeR¹¹⁴R¹¹⁵R¹¹⁶, or a combination thereof.

R¹¹⁴ to R¹¹⁶ may each independently be, e.g., a substituted or unsubstituted C1 to C6 alkyl group.

L¹⁰⁰ may be, e.g., a ligand of a monovalent anion or a bidentate ligand, which coordinates to iridium through the unshared electron pair of carbon or a heteroatom.

m21 may be, e.g., an integer of 0 to 3.

In an implementation, the iridium complex may be, e.g., represented by one of Chemical Formula 6-1 to Chemical Formula 6-6.

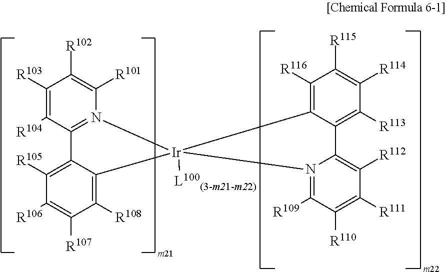

In Chemical Formula 6-1, R¹⁰¹ to R¹¹⁶ may each independently be, e.g., hydrogen, deuterium, a halogen, a substituted or unsubstituted C1 to C10 alkyl group, a substituted or unsubstituted C6 to C20 aryl group, —SiR¹³²R¹³³R¹³⁴, or —GeR¹³²R¹³³R¹³⁴.

R¹³² to R¹³⁴ may each independently be, e.g., a substituted or unsubstituted C1 to C6 alkyl group.

At least one of R¹⁰¹ to R¹¹⁶ may be, e.g., a functional group represented by Chemical Formula V-1.

L¹⁰⁰ may be, e.g., a bidentate ligand of a monovalent anion and may be, e.g., a ligand that coordinates to iridium through a lone pair of carbons or heteroatoms.

m21 and m22 may each independently be, e.g., an integer of 0 to 3 and m21+m22 may be, e.g., an integer of 1 to 3.

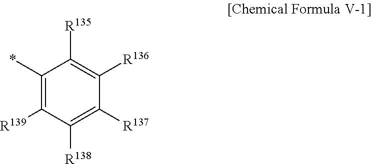

In Chemical Formula V-1, R¹³⁵ to R¹³⁹ may each independently be, e.g., hydrogen, deuterium, a substituted or unsubstituted C1 to C10 alkyl group, a substituted or unsubstituted C6 to C20 aryl group, or —SiR¹³²R¹³³R¹³⁴.

R¹³² to R¹³⁴ may each independently be, e.g., a substituted or unsubstituted C1 to C6 alkyl group.

* refers to a portion linked to a carbon atom.

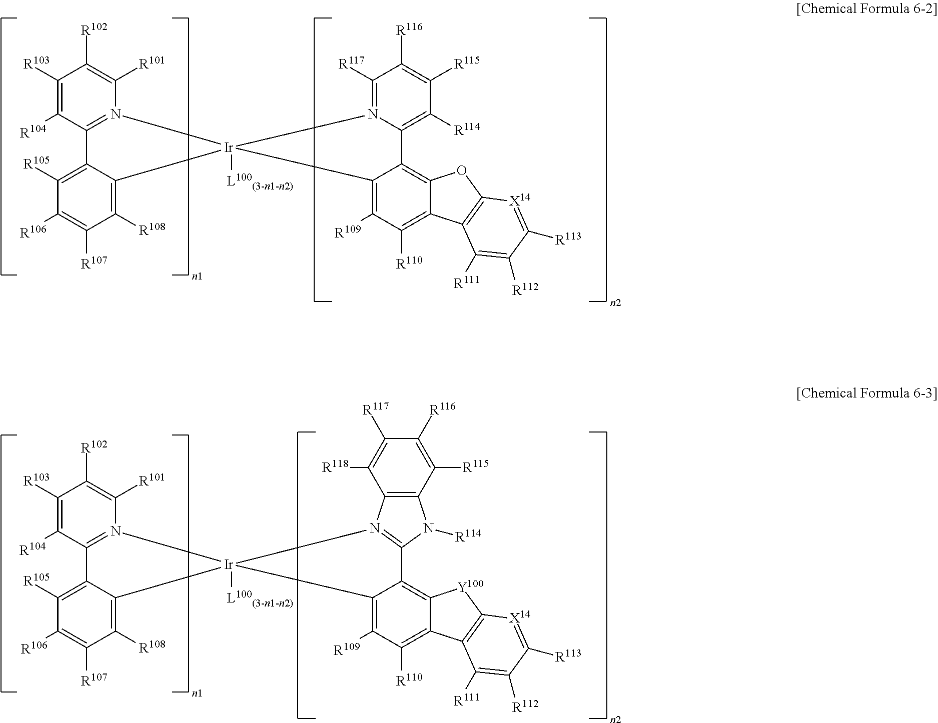

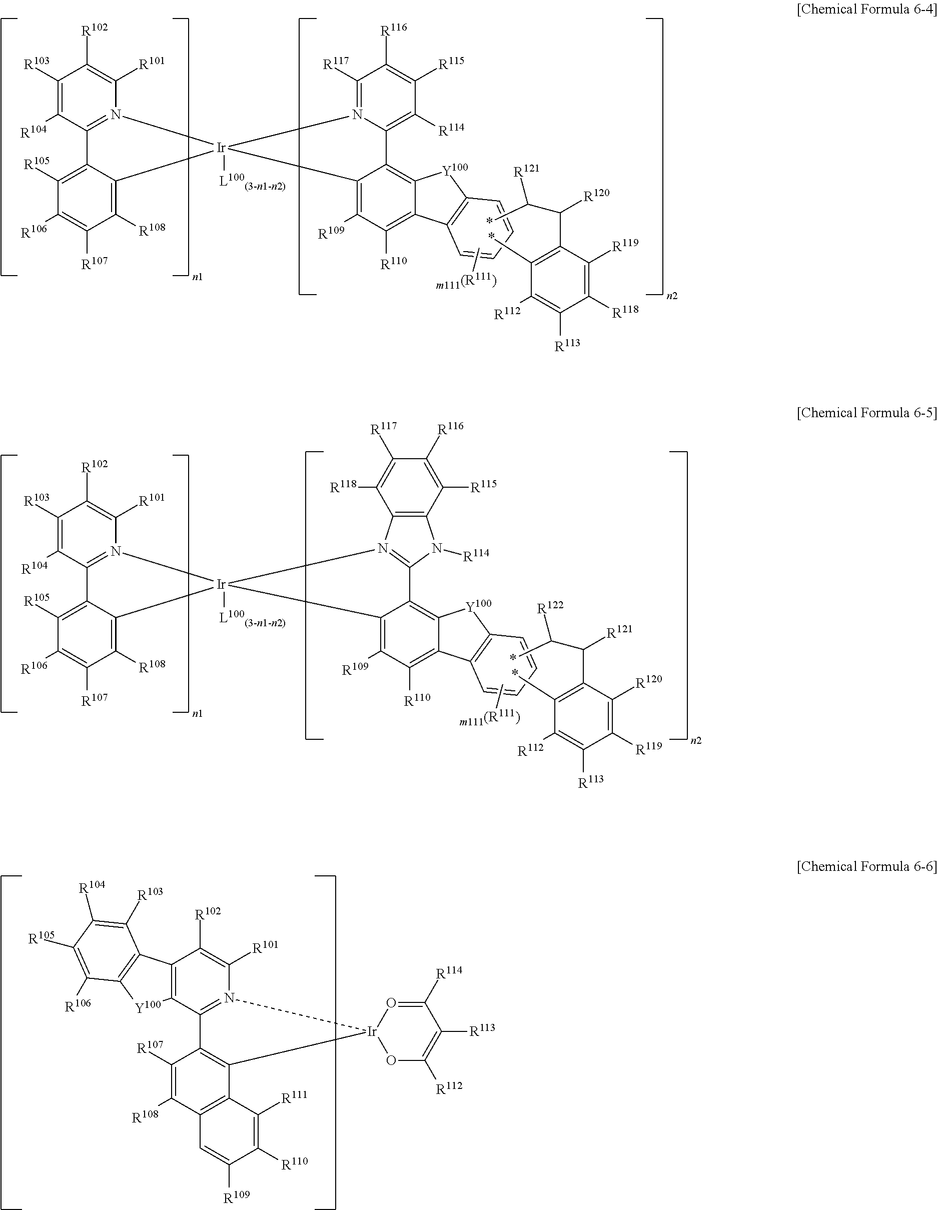

In Chemical Formula 6-2 to Chemical Formula 6-6, X¹⁴ may be, e.g., carbon or nitrogen.

Y¹⁰⁰ may be, e.g., O or S.

R¹⁰¹ to R¹²² may each independently be, e.g., hydrogen, deuterium, a halogen, a substituted or unsubstituted C1 to C10 alkyl group, a substituted or unsubstituted C6 to C20 aryl group, —SiR¹³³R¹³⁴R¹³⁵, or —GeR¹³³R¹³⁴R¹³⁵.

R¹³³ to R¹³⁵ may each independently be, e.g., a substituted or unsubstituted C1 to C6 alkyl group.

L¹⁰⁰ may be, e.g., a bidentate ligand of a monovalent anion and may be, e.g., a ligand that coordinates to iridium through a lone pair of carbons or heteroatoms.

m111 may be, e.g., an integer of 1 to 2.

n1 and n2 may each independently be, e.g., an integer of 0 to 3 and n1+n2 may be, e.g., an integer of 1 to 3.

The hole transport auxiliary layer 33 may include a third compound having bipolar characteristics and having relatively strong hole characteristics.

As described above, the light emitting layer 32 may help significantly improve the luminous efficiency by increasing the mobility of electrons and holes compared to when used alone by including a first compound having relatively strong hole characteristics and a second compound having relatively strong electron characteristics together.

When a material having biased electron or hole characteristics is used to form a light emitting layer, relatively more excitons in a device including the light emitting layer are generated due to recombination of carriers on the interface between the light emitting layer and the electron or hole transport layer. As a result, the molecular excitons in the light emitting layer interact with charges on the interface of the hole transport layer and thus, cause a roll-off of sharply deteriorating efficiency and also, sharply deteriorate light emitting life-span characteristics.

In order to solve the problems, the first and second compounds may be simultaneously included in the light emitting layer to make a light emitting region not be biased to either of the electron transport layer or the hole transport layer, and additionally, the hole transport auxiliary layer including the third compound having relatively strong hole characteristics may be between the hole transport layer and the light emitting layer, and thereby charges may be prevented from being accumulated at the interface between the hole transport layer and the light emitting layer and a device capable of adjusting carrier balance in the light emitting layer may be provided. Accordingly, roll-off characteristics of an organic optoelectronic device may be improved and simultaneously life-span characteristics may be remarkably improved.

The third compound may be represented by Chemical Formula 3.

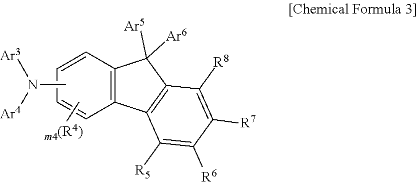

In Chemical Formula 3, Ar³ and Ar⁴ may each independently be, e.g., a substituted or unsubstituted C6 to C30 aryl group or a substituted or unsubstituted C2 to C30 heterocyclic group.

Ar⁵ and Ar⁶ may each independently be, e.g., a substituted or unsubstituted C1 to C30 alkyl group or a substituted or unsubstituted C6 to C30 aryl group.

R⁴ to R⁸ may each independently be, e.g., hydrogen, deuterium, a cyano group, a halogen, a substituted or unsubstituted C1 to C30 alkyl group, a substituted or unsubstituted C6 to C30 aryl group, or a substituted or unsubstituted C2 to C30 heterocyclic group.

m4 may be, e.g., an integer of 1 to 3.

In an implementation, m4 may be 2 or 3, and each R⁴ may be the same or different from each other.

The third compound has a structure in which at least one fluorene group may be substituted on the amine core.

Because at least one fluorene group may be substituted in the amine core, the steric hindrance may help minimize degradation by reducing the deposition temperature, thereby helping further improve the life-span characteristics.

In an implementation, the third compound may be, e.g., represented by one of Chemical Formula 3-1 to Chemical Formula 3-4, depending on the substitution position of fluorene.

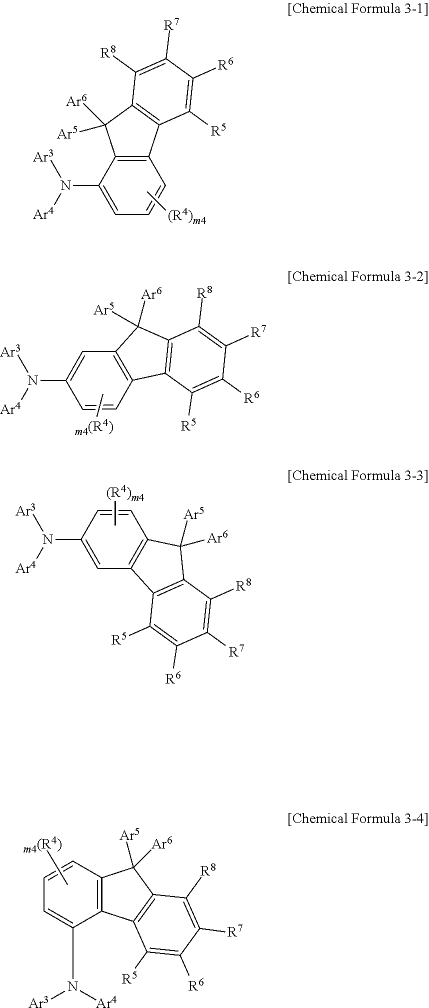

In Chemical Formula 3-1 to Chemical Formula 3-4, Ar³ to Ar⁶, R⁴ to R⁸, and m4 may be defined the same as those described above.

In an implementation, the third compound may be, e.g., represented by Chemical Formula 3-4.

In Chemical Formula 3, Ar³ and Ar⁴ may each independently be, e.g., a substituted or unsubstituted phenyl group, a substituted or unsubstituted biphenyl group, a substituted or unsubstituted terphenyl group, a substituted or unsubstituted fluorenyl group, a substituted or unsubstituted spirobifluorenyl group, a substituted or unsubstituted triphenylene group, a substituted or unsubstituted dibenzofuranyl group, or a substituted or unsubstituted dibenzothiophenyl group.

In an implementation, Ar³ and Ar⁴ may each independently be, e.g., a substituted or unsubstituted phenyl group, a substituted or unsubstituted biphenyl group, or a substituted or unsubstituted fluorenyl group.

In Chemical Formula 3, Ar⁵ and Ar⁶ may each independently be, e.g., a substituted or unsubstituted C1 to C5 alkyl group or a substituted or unsubstituted C6 to C12 aryl group.

In an implementation, Ar⁵ and Ar⁶ may each independently be, e.g., a substituted or unsubstituted C1 to C5 alkyl group, a substituted or unsubstituted phenyl group, or a substituted or unsubstituted biphenyl group.

In Chemical Formula 3, R⁴ to R⁸ may each independently be, e.g., hydrogen, deuterium, or a substituted or unsubstituted C1 to C5 alkyl group.

In an implementation, R⁴ to R⁸ may each independently be, e.g., hydrogen, deuterium, or a substituted or unsubstituted tert-butyl group.

In an implementation, at least one of Ar³ and Ar⁴ may be, e.g., a substituted or unsubstituted fluorenyl group and the third compound may be, e.g., represented by Chemical Formula 3-4-1.

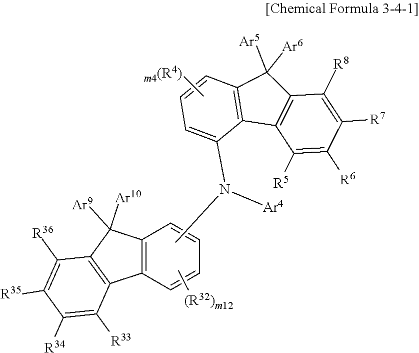

In Chemical Formula 3-4-1, Ar⁴ to Ar⁶, R⁴ to R⁸, and m4 may be defined the same as those described above.

Ar⁹ and Ar¹⁰ are each independently a substituted or unsubstituted C1 to C30 alkyl group or a substituted or unsubstituted C6 to C30 aryl group.

R³² to R³⁶ may each independently be, e.g., hydrogen, deuterium, a cyano group, a halogen, a substituted or unsubstituted C1 to C30 alkyl group, a substituted or unsubstituted C6 to C30 aryl group, or a substituted or unsubstituted C2 to C30 heterocyclic group.

m12 may be, e.g., an integer of 1 to 3.

In an implementation, m4 may be 2 or 3, and each R⁴ may be the same or different from each other.

In an implementation, m12 may be 2 or 3, and each of R³² may be the same or different from each other.

In Chemical Formula 3-4-1, Ar⁹ and Ar¹⁰ may each independently be, e.g., a substituted or unsubstituted C1 to C5 alkyl group or a substituted or unsubstituted C6 to C12 aryl group.

In an implementation, Ar⁹ and Ar¹⁰ may each independently be, e.g., a substituted or unsubstituted C1 to C5 alkyl group, a substituted or unsubstituted phenyl group, or a substituted or unsubstituted naphthyl group.

In Chemical Formula 3-4-1, R⁴ to R⁸ may each independently be, e.g., hydrogen, deuterium, or a substituted or unsubstituted C1 to C5 alkyl group.

In an implementation, R⁴ to R⁸ may each independently be, e.g., hydrogen, deuterium, or a tert-butyl group.

In an implementation, Chemical Formula 3-4-1 may be, e.g., Chemical Formula 3-4-1a, Chemical Formula 3-4-1b, Chemical Formula 3-4-1c, and Chemical Formula 3-4-1d.

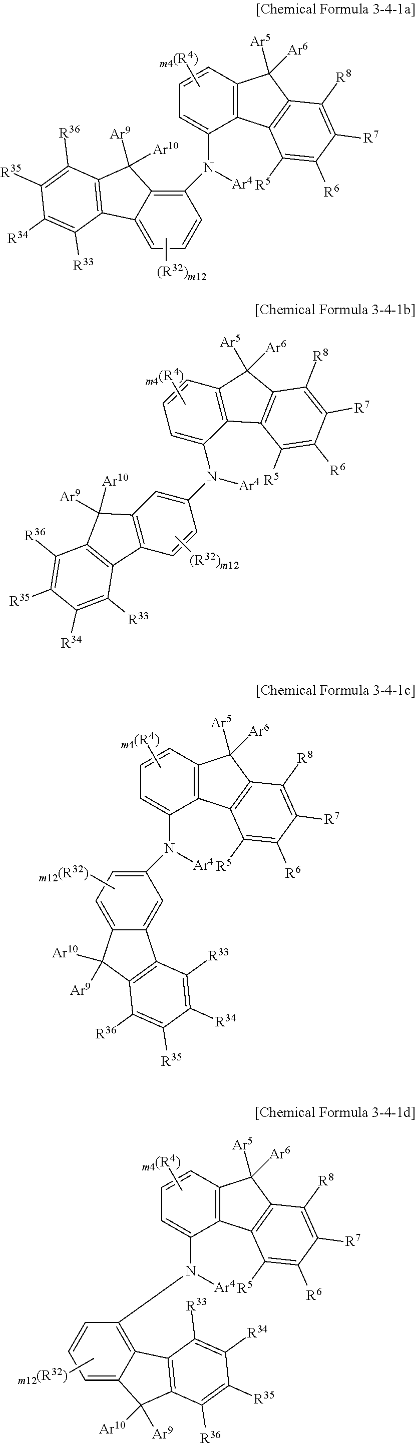

In Chemical Formula 3-4-1a, Chemical Formula 3-4-1b, Chemical Formula 3-4-1c, and Chemical Formula 3-4-1d, Art to Ar⁶, Ar⁹, Ar¹⁰, R⁴ to R⁸, R³² to R³⁶, m4, and m12 may be defined the same as those described above.

In an implementation, the third compound may be, e.g., represented by Chemical Formula 3-4-1b.

In an implementation, at least two of R⁴ to R⁸ in Chemical Formula 3 may be, e.g., a substituted or unsubstituted tert-butyl group.

Heat resistance may be improved by introducing an alkyl group that may help improve a glass transition temperature.

In an implementation, by lowering the refractive index of the material, improvement in the efficiency of the device may be expected.

In an implementation, by applying a third compound having a high LUMO energy level together with the aforementioned host composition as a hole transport auxiliary layer, electron movement may be restricted so that electrons remain within the light emitting layer, and thus excitons may be efficiently formed, so that improvement in device efficiency may also be expected.

In an implementation, at least two of R⁴ to R⁸ or at least two of R³³ to R³⁶ in Chemical Formula 3-4-1 may be, e.g., a substituted or unsubstituted tert-butyl group.

In an implementation, in Chemical Formula 3, R⁶ and R⁸ may each be, e.g., a substituted or unsubstituted tert-butyl group.

In an implementation, in Chemical Formula 3-4-1, R⁶, R⁸, R³⁴, and R³⁶ may each be, e.g., a substituted or unsubstituted tert-butyl group.

In an implementation, the third compound may be, e.g., a compound of Group 3.

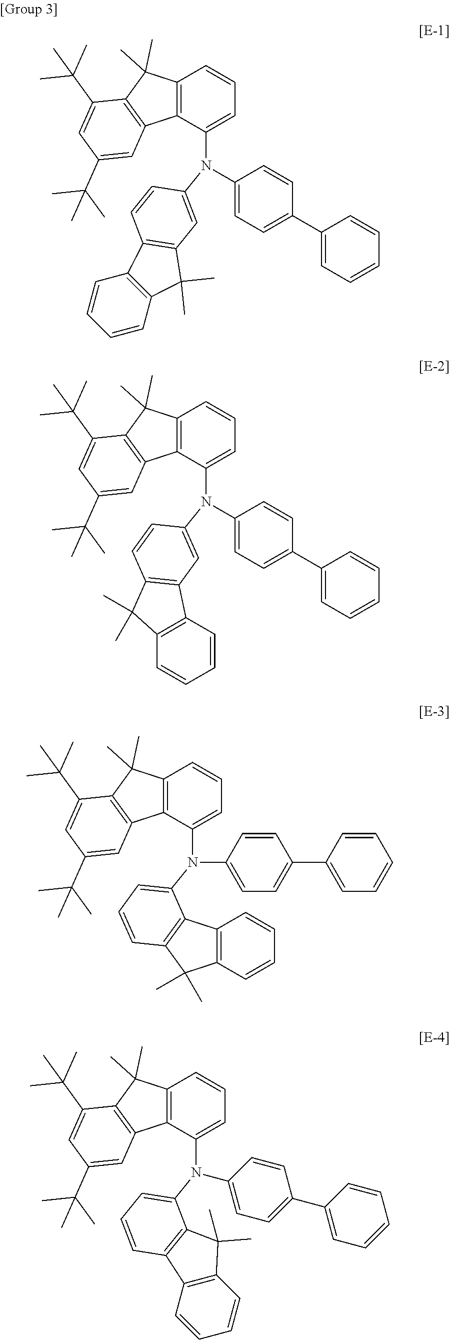 [SMILES: CC(C)(C)c1cc2c(c(C(C)(C)C)c1)C(C)(C)c1cccc(N(c3ccc(-c4ccccc4)cc3)c3ccc4c(c3)C(C)(C)c3ccccc3-4)c1-2 ; CC(C)(C)c1cc2c(c(C(C)(C)C)c1)C(C)(C)c1cccc(N(c3ccc(-c4ccccc4)cc3)c3ccc4c(c3)-c3ccccc3C4(C)C)c1-2 ; CC(C)(C)c1cc2c(c(C(C)(C)C)c1)C(C)(C)c1cccc(N(c3ccc(-c4ccccc4)cc3)c3cccc4c3-c3ccccc3C4(C)C)c1-2 ; CC(C)(C)c1cc2c(c(C(C)(C)C)c1)C(C)(C)c1cccc(N(c3ccc(-c4ccccc4)cc3)c3cccc4c3C(C)(C)c3ccccc3-4)c1-2]

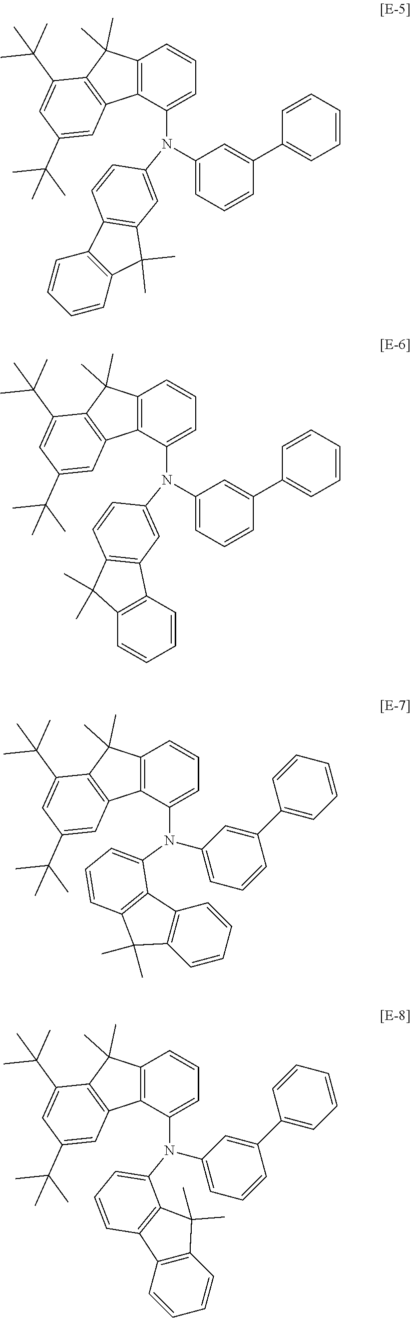 [SMILES: CC(C)(C)c1cc2c(c(C(C)(C)C)c1)C(C)(C)c1cccc(N(c3cccc(-c4ccccc4)c3)c3ccc4c(c3)C(C)(C)c3ccccc3-4)c1-2 ; CC(C)(C)c1cc2c(c(C(C)(C)C)c1)C(C)(C)c1cccc(N(c3cccc(-c4ccccc4)c3)c3ccc4c(c3)-c3ccccc3C4(C)C)c1-2 ; CC(C)(C)c1cc2c(c(C(C)(C)C)c1)C(C)(C)c1cccc(N(c3cccc(-c4ccccc4)c3)c3cccc4c3-c3ccccc3C4(C)C)c1-2 ; CC(C)(C)c1cc2c(c(C(C)(C)C)c1)C(C)(C)c1cccc(N(c3cccc(-c4ccccc4)c3)c3cccc4c3C(C)(C)c3ccccc3-4)c1-2]

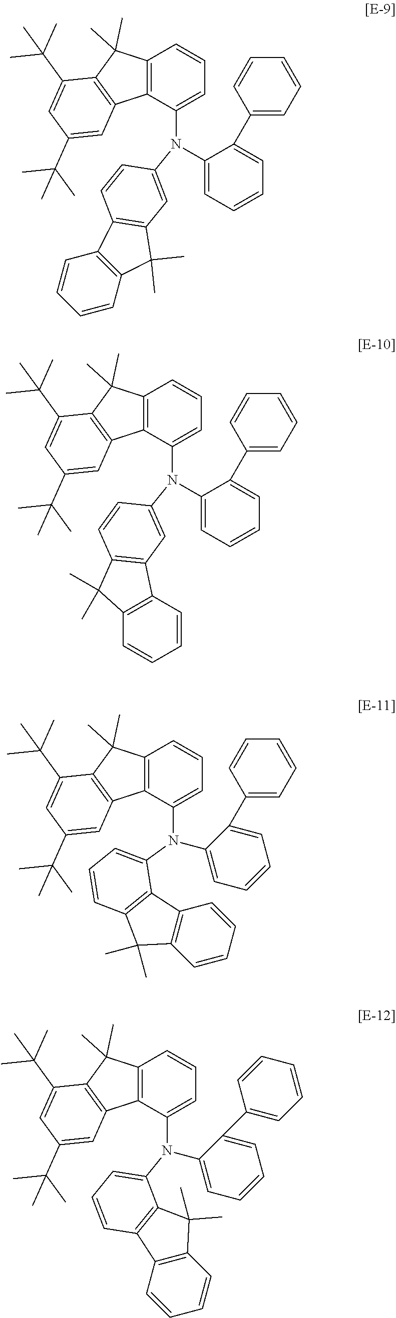 [SMILES: CC(C)(C)c1cc2c(c(C(C)(C)C)c1)C(C)(C)c1cccc(N(c3ccc4c(c3)C(C)(C)c3ccccc3-4)c3ccccc3-c3ccccc3)c1-2 ; CC(C)(C)c1cc2c(c(C(C)(C)C)c1)C(C)(C)c1cccc(N(c3ccc4c(c3)-c3ccccc3C4(C)C)c3ccccc3-c3ccccc3)c1-2 ; CC(C)(C)c1cc2c(c(C(C)(C)C)c1)C(C)(C)c1cccc(N(c3ccccc3-c3ccccc3)c3cccc4c3-c3ccccc3C4(C)C)c1-2 ; CC(C)(C)c1cc2c(c(C(C)(C)C)c1)C(C)(C)c1cccc(N(c3ccccc3-c3ccccc3)c3cccc4c3C(C)(C)c3ccccc3-4)c1-2]

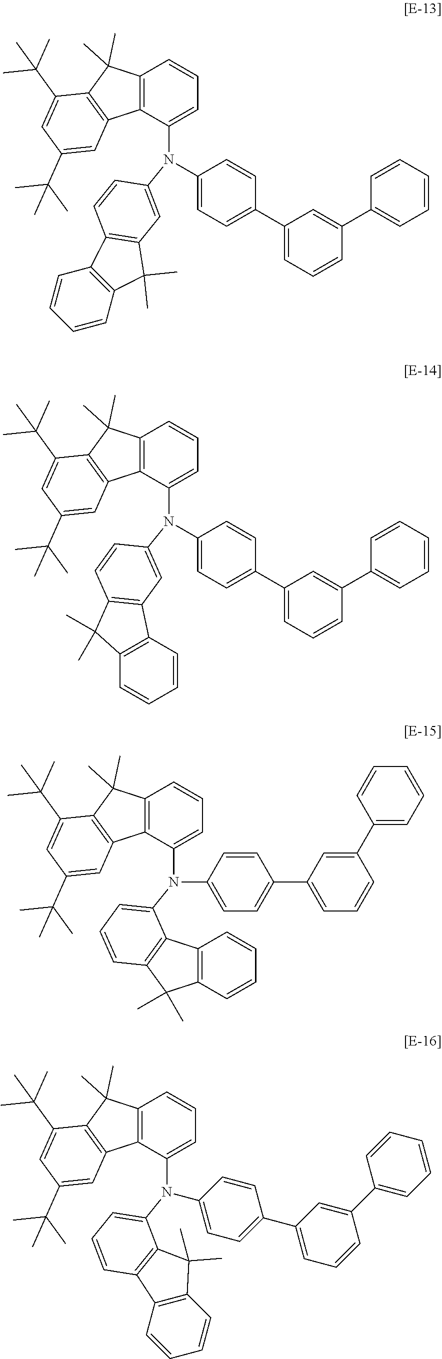 [SMILES: CC(C)(C)c1cc2c(c(C(C)(C)C)c1)C(C)(C)c1cccc(N(c3ccc(-c4cccc(-c5ccccc5)c4)cc3)c3ccc4c(c3)C(C)(C)c3ccccc3-4)c1-2 ; CC(C)(C)c1cc2c(c(C(C)(C)C)c1)C(C)(C)c1cccc(N(c3ccc(-c4cccc(-c5ccccc5)c4)cc3)c3ccc4c(c3)-c3ccccc3C4(C)C)c1-2 ; CC(C)(C)c1cc2c(c(C(C)(C)C)c1)C(C)(C)c1cccc(N(c3ccc(-c4cccc(-c5ccccc5)c4)cc3)c3cccc4c3-c3ccccc3C4(C)C)c1-2 ; CC(C)(C)c1cc2c(c(C(C)(C)C)c1)C(C)(C)c1cccc(N(c3ccc(-c4cccc(-c5ccccc5)c4)cc3)c3cccc4c3C(C)(C)c3ccccc3-4)c1-2]

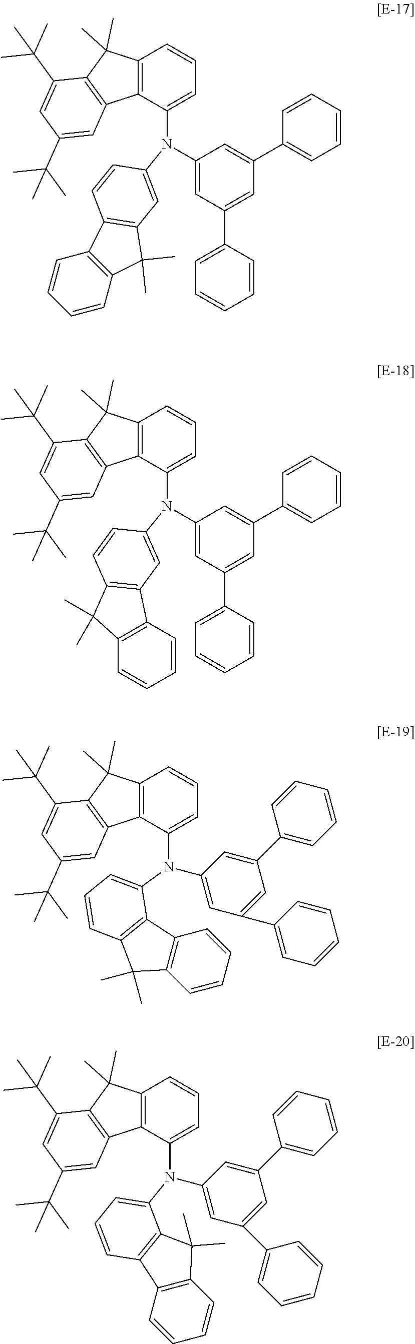 [SMILES: CC(C)(C)c1cc2c(c(C(C)(C)C)c1)C(C)(C)c1cccc(N(c3cc(-c4ccccc4)cc(-c4ccccc4)c3)c3ccc4c(c3)C(C)(C)c3ccccc3-4)c1-2 ; CC(C)(C)c1cc2c(c(C(C)(C)C)c1)C(C)(C)c1cccc(N(c3cc(-c4ccccc4)cc(-c4ccccc4)c3)c3ccc4c(c3)-c3ccccc3C4(C)C)c1-2 ; CC(C)(C)c1cc2c(c(C(C)(C)C)c1)C(C)(C)c1cccc(N(c3cc(-c4ccccc4)cc(-c4ccccc4)c3)c3cccc4c3-c3ccccc3C4(C)C)c1-2 ; CC(C)(C)c1cc2c(c(C(C)(C)C)c1)C(C)(C)c1cccc(N(c3cc(-c4ccccc4)cc(-c4ccccc4)c3)c3cccc4c3C(C)(C)c3ccccc3-4)c1-2]

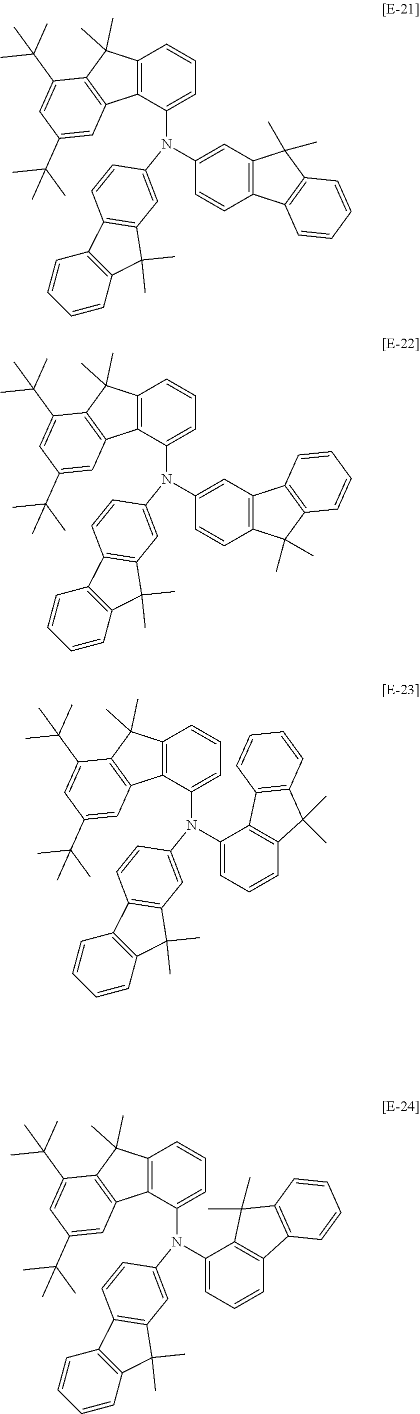

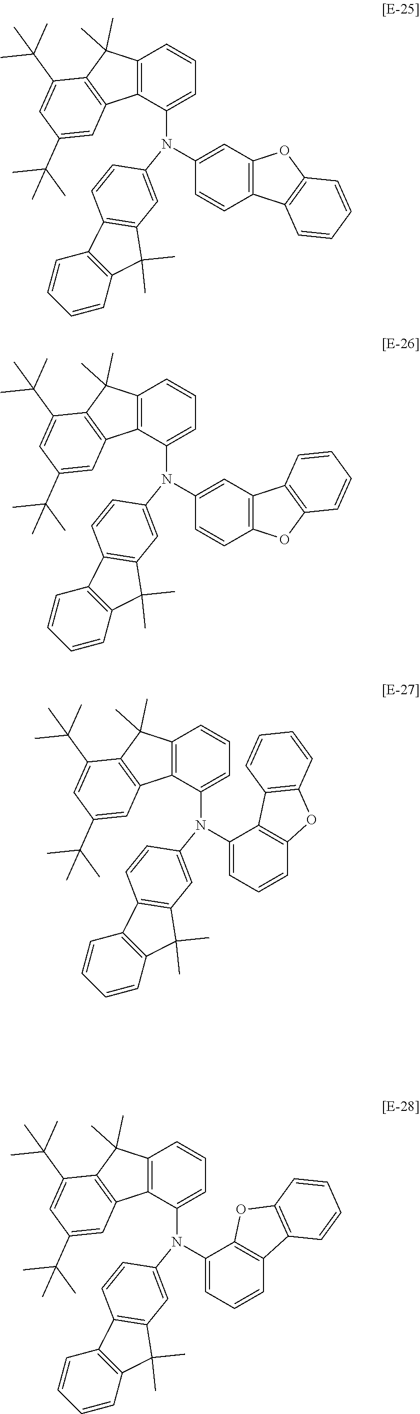

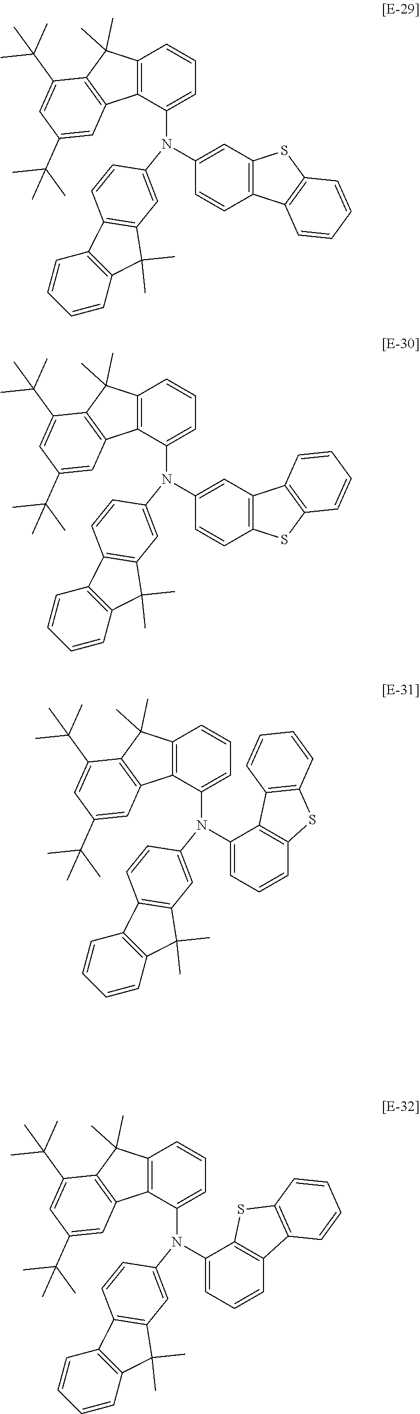

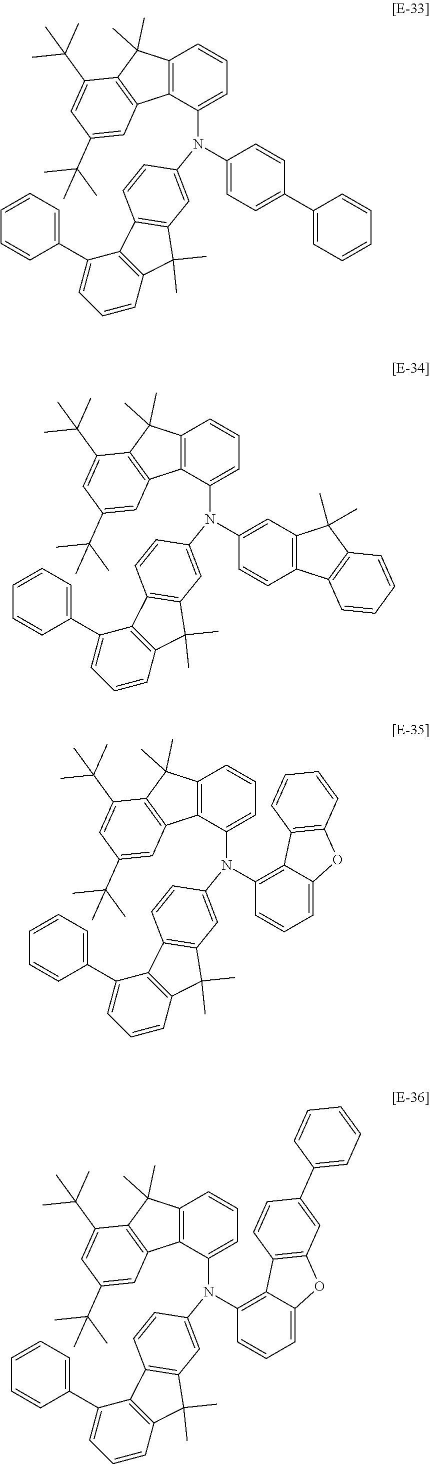 [SMILES: CC(C)(C)c1cc2c(c(C(C)(C)C)c1)C(C)(C)c1cccc(N(c3ccc(-c4ccccc4)cc3)c3ccc4c(c3)C(C)(C)c3cccc(-c5ccccc5)c3-4)c1-2 ; CC(C)(C)c1cc2c(c(C(C)(C)C)c1)C(C)(C)c1cccc(N(c3ccc4c(c3)C(C)(C)c3ccccc3-4)c3ccc4c(c3)C(C)(C)c3cccc(-c5ccccc5)c3-4)c1-2 ; CC(C)(C)c1cc2c(c(C(C)(C)C)c1)C(C)(C)c1cccc(N(c3ccc4c(c3)C(C)(C)c3cccc(-c5ccccc5)c3-4)c3cccc4oc5ccccc5c34)c1-2 ; CC(C)(C)c1cc2c(c(C(C)(C)C)c1)C(C)(C)c1cccc(N(c3ccc4c(c3)C(C)(C)c3cccc(-c5ccccc5)c3-4)c3cccc4oc5cc(-c6ccccc6)ccc5c34)c1-2]

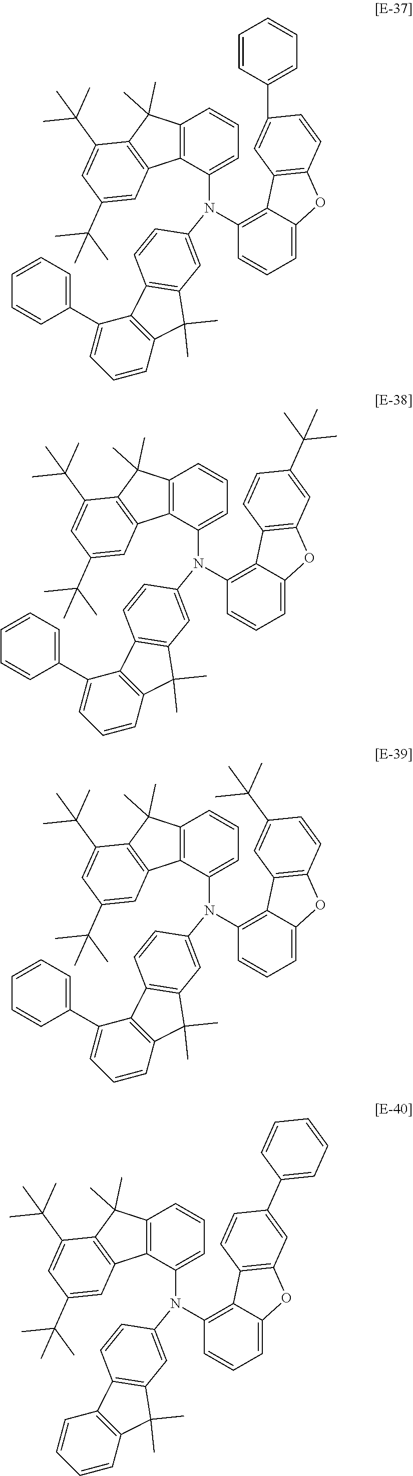

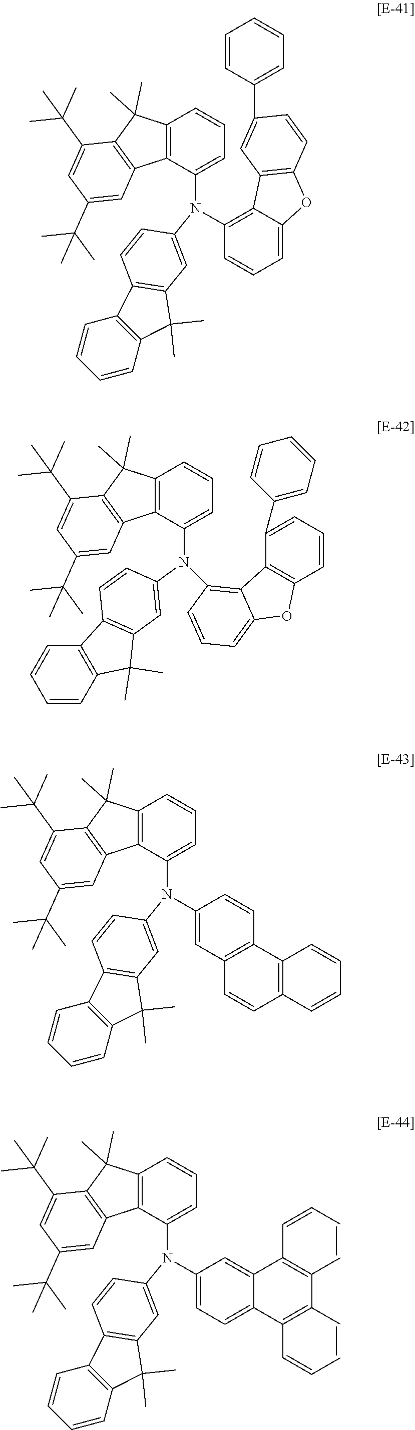

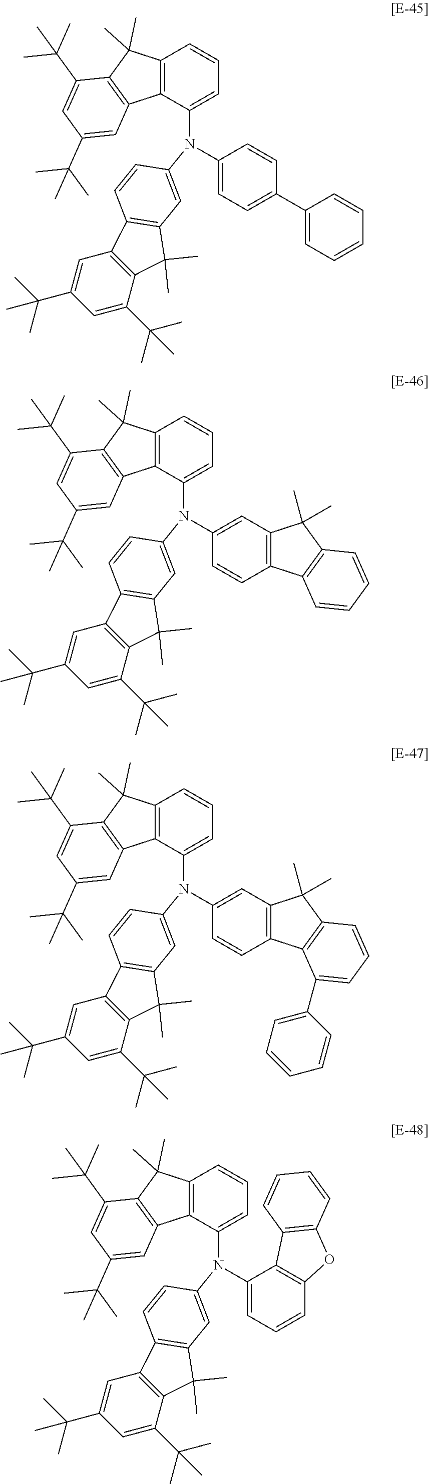

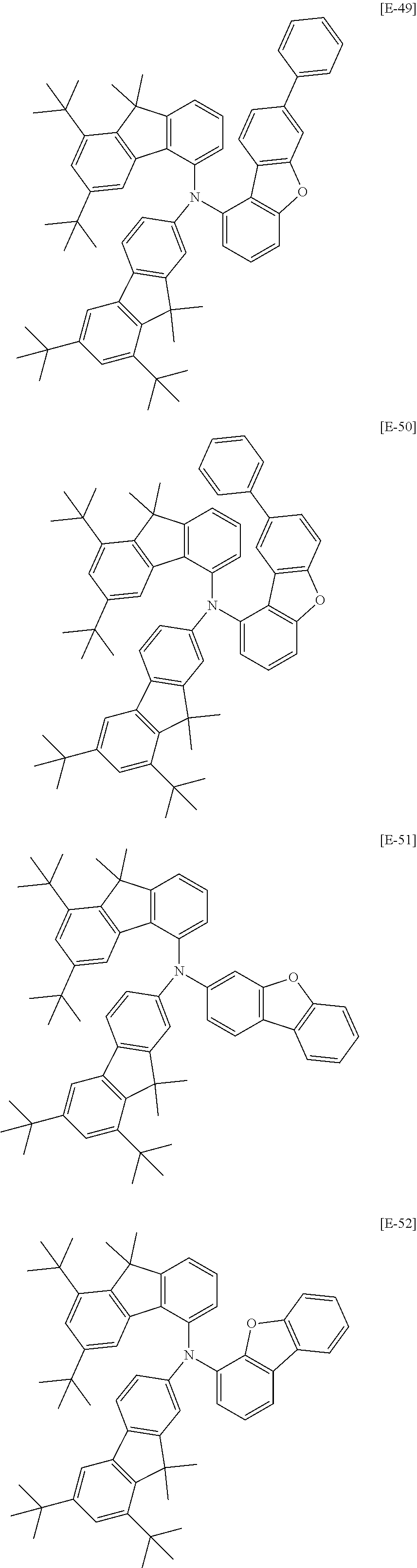 [SMILES: CC(C)(C)c1cc2c(c(C(C)(C)C)c1)C(C)(C)c1cc(N(c3cccc4c3-c3cc(C(C)(C)C)cc(C(C)(C)C)c3C4(C)C)c3cccc4oc5cc(-c6ccccc6)ccc5c34)ccc1-2 ; CC(C)(C)c1cc2c(c(C(C)(C)C)c1)C(C)(C)c1cc(N(c3cccc4c3-c3cc(C(C)(C)C)cc(C(C)(C)C)c3C4(C)C)c3cccc4oc5ccc(-c6ccccc6)cc5c34)ccc1-2 ; CC(C)(C)c1cc2c(c(C(C)(C)C)c1)C(C)(C)c1cc(N(c3ccc4c(c3)oc3ccccc34)c3cccc4c3-c3cc(C(C)(C)C)cc(C(C)(C)C)c3C4(C)C)ccc1-2 ; CC(C)(C)c1cc2c(c(C(C)(C)C)c1)C(C)(C)c1cc(N(c3cccc4c3-c3cc(C(C)(C)C)cc(C(C)(C)C)c3C4(C)C)c3cccc4c3oc3ccccc34)ccc1-2]

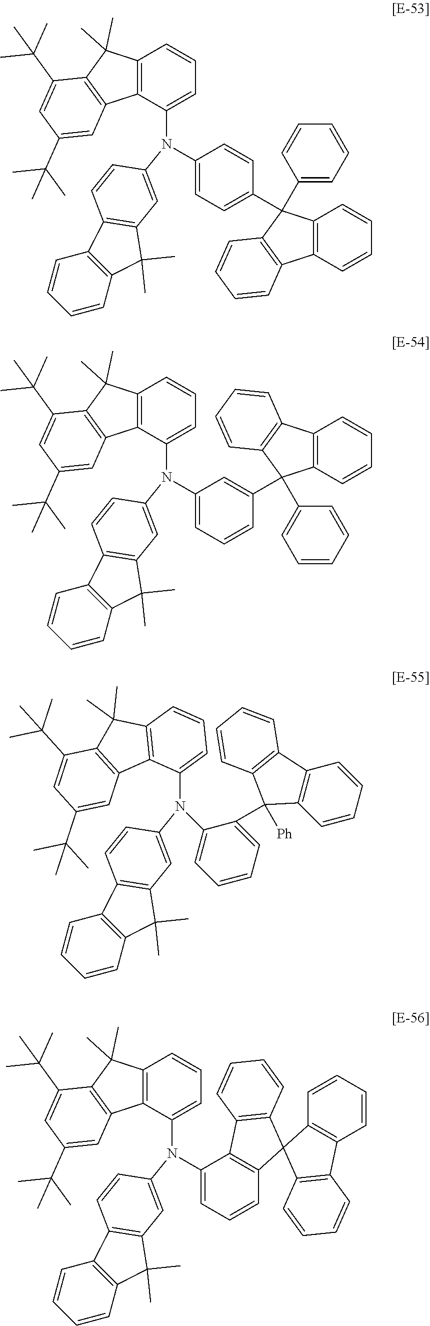

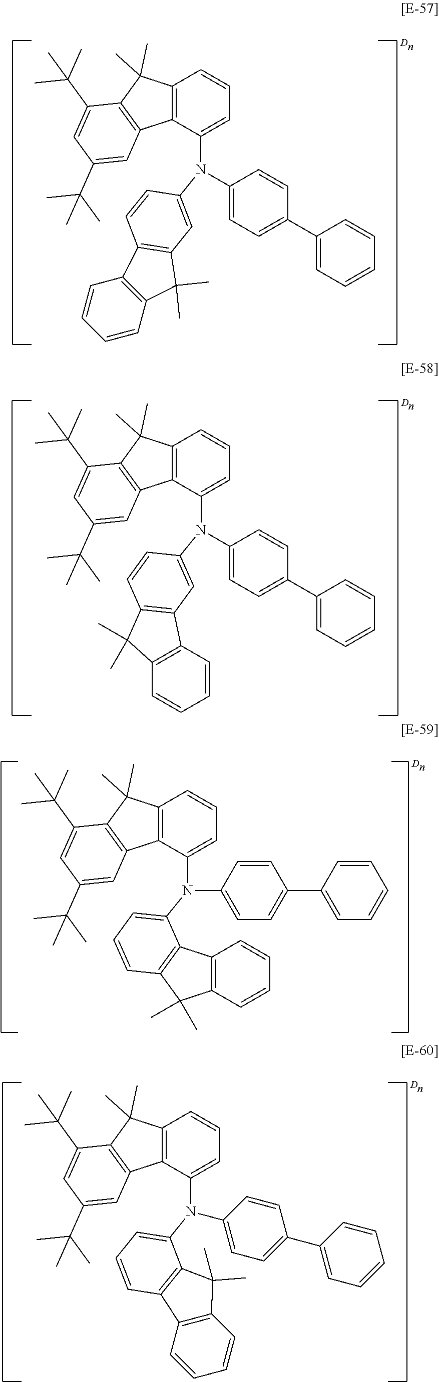

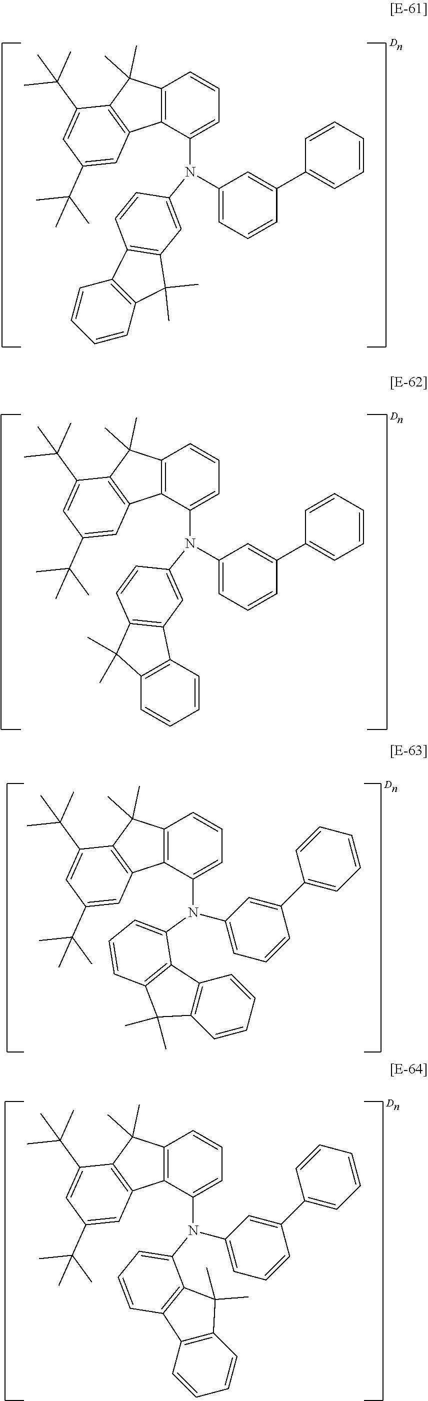

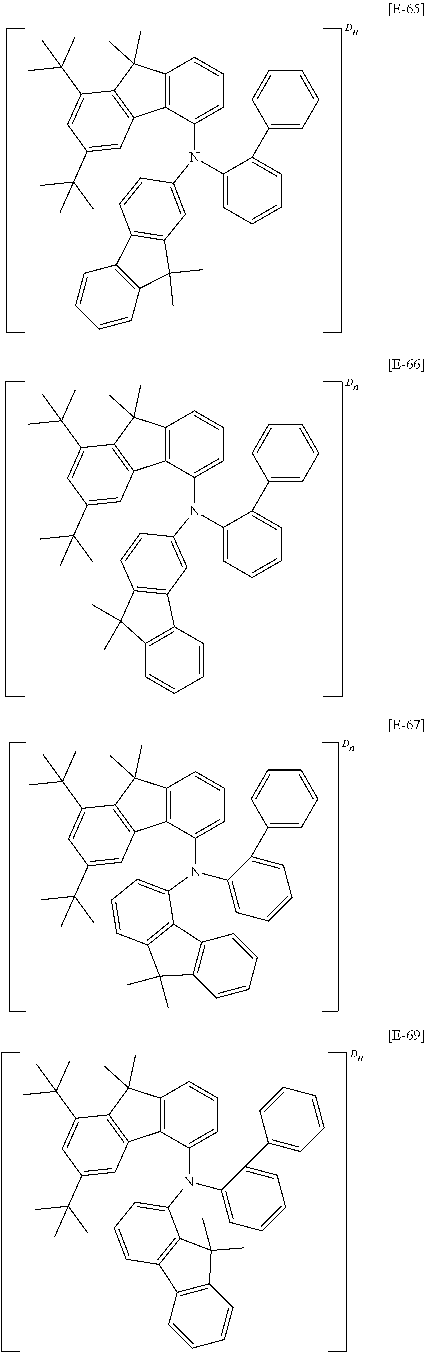

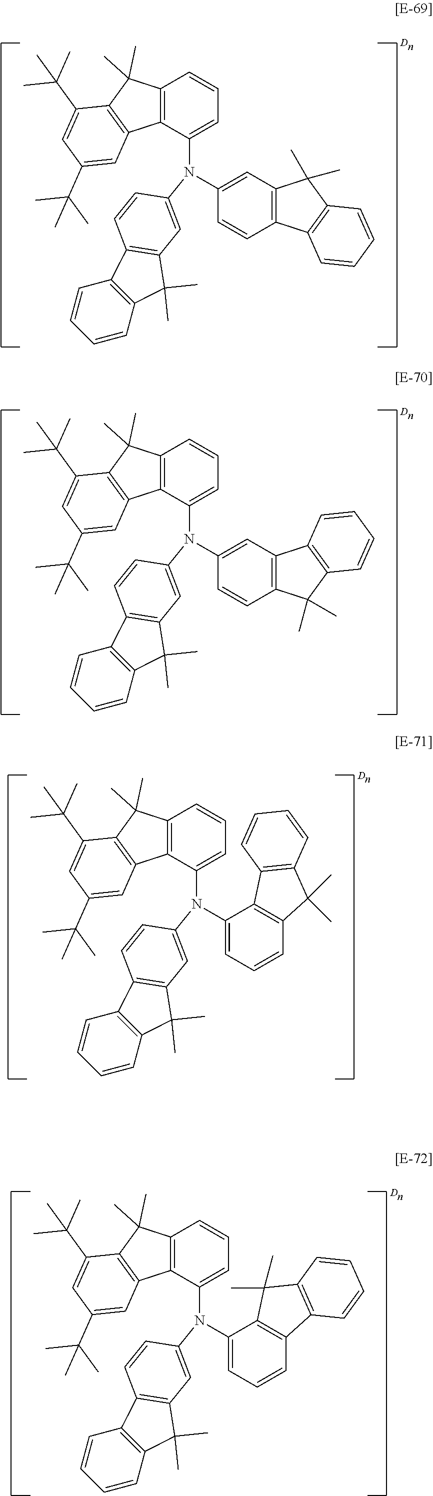

(Dn means the number of deuterium atoms substituted, n is an integer greater than or equal to 0, and the maximum number of n corresponds to the number of substitutable hydrogen positions).

In an implementation, the first compound may be, e.g., represented by Chemical Formula 1A or Chemical Formula 1B, the second compound may be, e.g., represented by Chemical Formula 2B-IV, and the third compound may be, e.g., represented by Chemical Formula 3-4-1b.

In an implementation, the organic layer 30 may further include, e.g., an electron transport region.

The electron transport region may help further increase electron injection or electron mobility and help block holes between the cathode 20 and the light emitting layer 32.

In an implementation, the electron transport region may include an electron transport layer 34 between the cathode 20 and the light emitting layer 32, and an electron transport auxiliary layer between the light emitting layer 32 and the electron transport layer 34, and at least one of the compounds listed in Group B may be included in at least either one layer of the electron transport layer and the electron transport auxiliary layer.

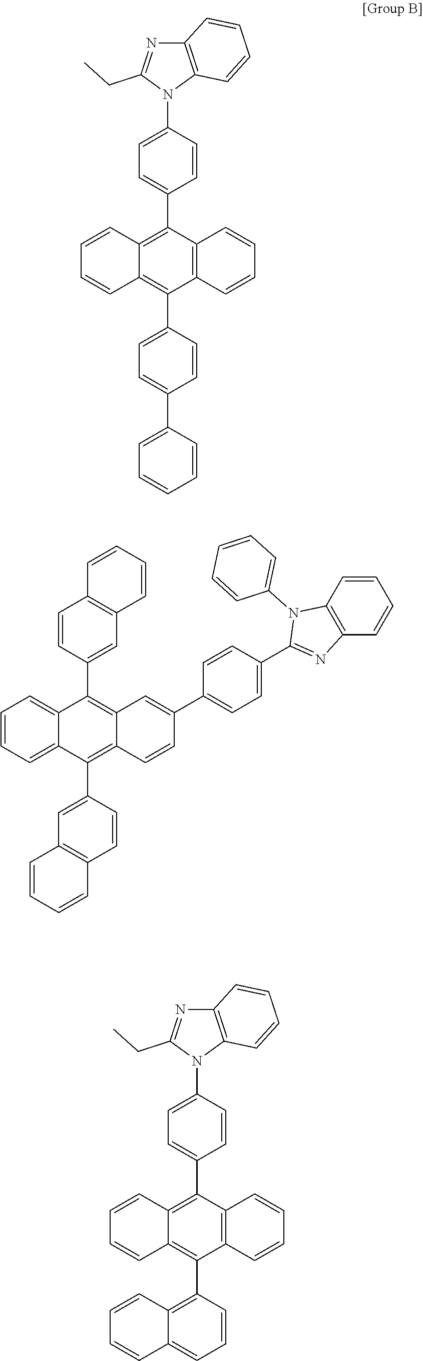 [SMILES: CCc1nc2ccccc2n1-c1ccc(-c2c3ccccc3c(-c3ccc(-c4ccccc4)cc3)c3ccccc23)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; CCc1nc2ccccc2n1-c1ccc(-c2c3ccccc3c(-c3cccc4ccccc34)c3ccccc23)cc1]

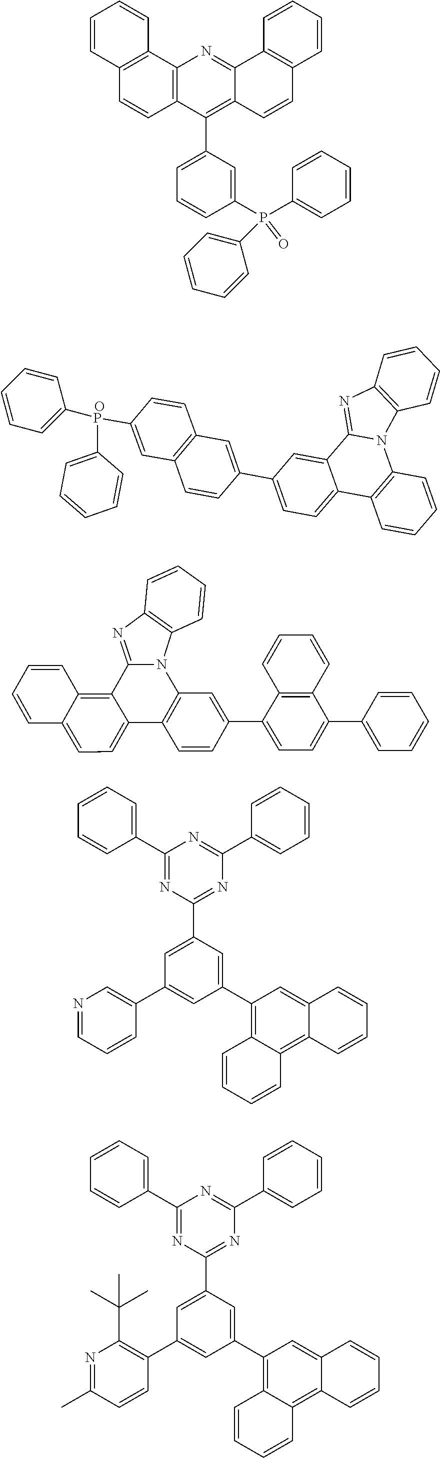

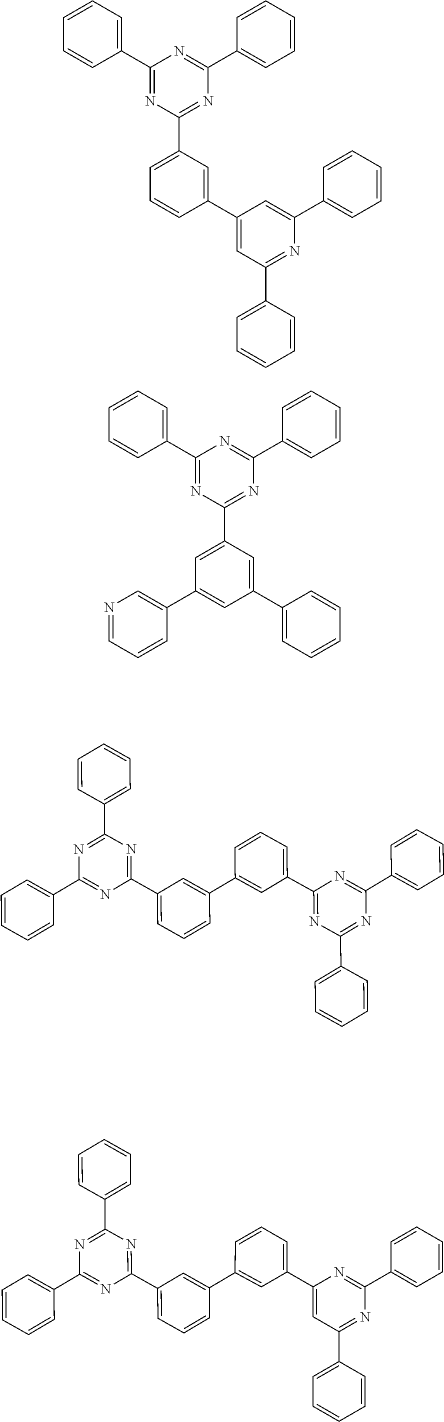 [SMILES: c1ccc(-c2cc(-c3cccc(-c4nc(-c5ccccc5)nc(-c5ccccc5)n4)c3)cc(-c3ccccc3)n2)cc1 ; c1ccc(-c2cc(-c3cccnc3)cc(-c3nc(-c4ccccc4)nc(-c4ccccc4)n3)c2)cc1 ; c1ccc(-c2nc(-c3ccccc3)nc(-c3cccc(-c4cccc(-c5nc(-c6ccccc6)nc(-c6ccccc6)n5)c4)c3)n2)cc1 ; c1ccc(-c2cc(-c3cccc(-c4cccc(-c5nc(-c6ccccc6)nc(-c6ccccc6)n5)c4)c3)nc(-c3ccccc3)n2)cc1]

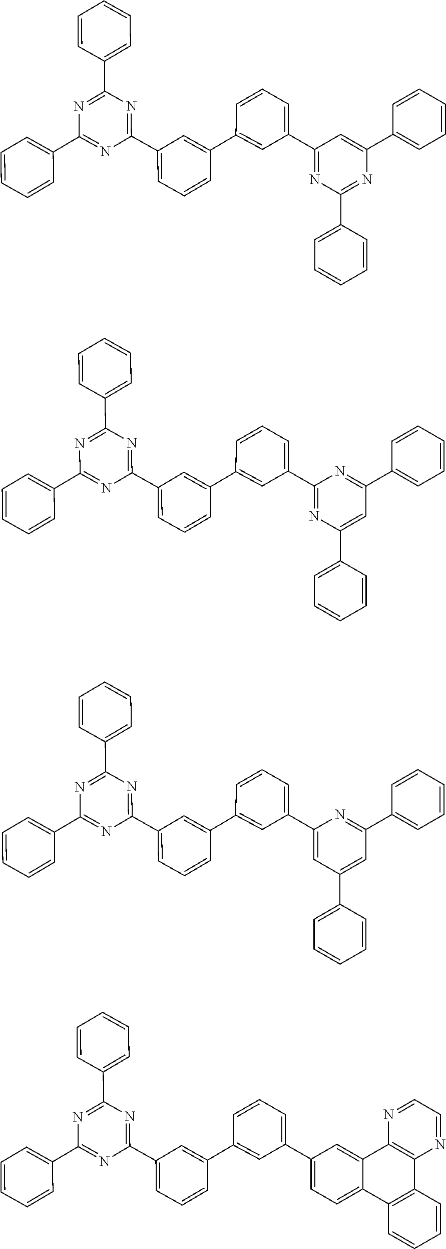 [SMILES: c1ccc(-c2cc(-c3cccc(-c4cccc(-c5nc(-c6ccccc6)nc(-c6ccccc6)n5)c4)c3)nc(-c3ccccc3)n2)cc1 ; c1ccc(-c2cc(-c3ccccc3)nc(-c3cccc(-c4cccc(-c5nc(-c6ccccc6)nc(-c6ccccc6)n5)c4)c3)n2)cc1 ; c1ccc(-c2cc(-c3ccccc3)nc(-c3cccc(-c4cccc(-c5nc(-c6ccccc6)nc(-c6ccccc6)n5)c4)c3)c2)cc1 ; c1ccc(-c2nc(-c3ccccc3)nc(-c3cccc(-c4cccc(-c5ccc6c7ccccc7c7nccnc7c6c5)c4)c3)n2)cc1]

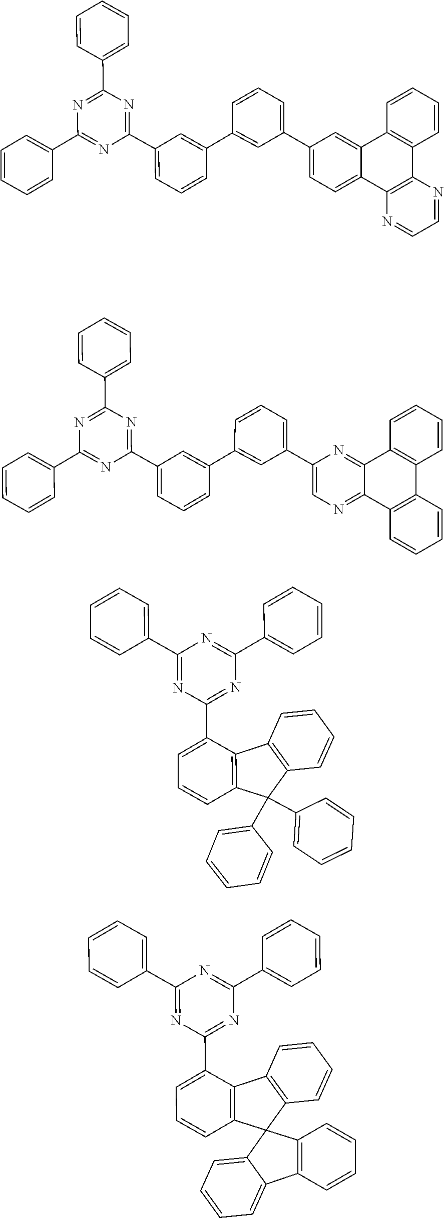 [SMILES: c1ccc(-c2nc(-c3ccccc3)nc(-c3cccc(-c4cccc(-c5ccc6c(c5)c5ccccc5c5nccnc65)c4)c3)n2)cc1 ; c1ccc(-c2nc(-c3ccccc3)nc(-c3cccc(-c4cccc(-c5cnc6c7ccccc7c7ccccc7c6n5)c4)c3)n2)cc1 ; c1ccc(-c2nc(-c3ccccc3)nc(-c3cccc4c3-c3ccccc3C4(c3ccccc3)c3ccccc3)n2)cc1 ; c1ccc(-c2nc(-c3ccccc3)nc(-c3cccc4c3-c3ccccc3C43c4ccccc4-c4ccccc43)n2)cc1]

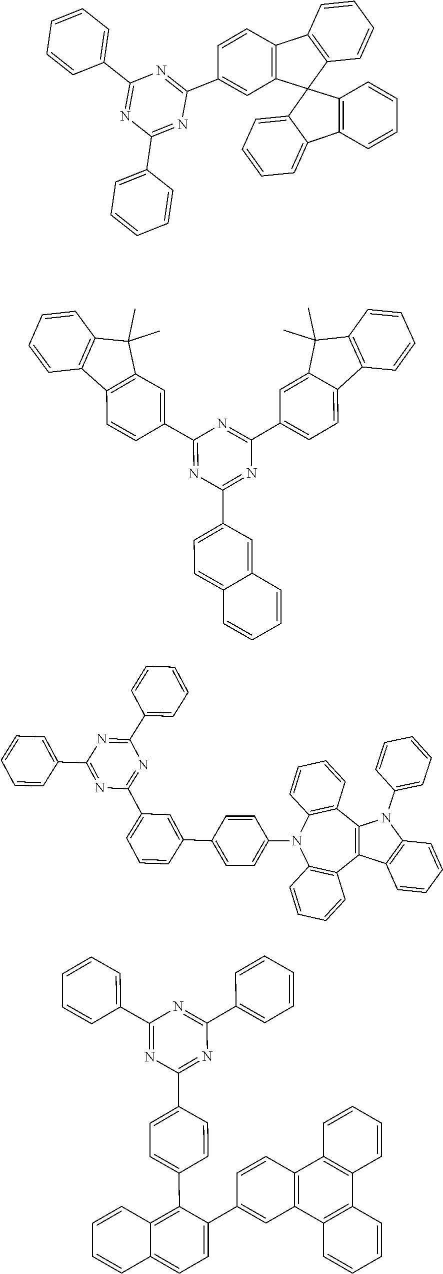 [SMILES: c1ccc(-c2nc(-c3ccccc3)nc(-c3ccc4c(c3)C3(c5ccccc5-c5ccccc53)c3ccccc3-4)n2)cc1 ; CC1(C)c2ccccc2-c2ccc(-c3nc(-c4ccc5c(c4)C(C)(C)c4ccccc4-5)nc(-c4ccc5ccccc5c4)n3)cc21 ; c1ccc(-c2nc(-c3ccccc3)nc(-c3cccc(-c4ccc(N5c6ccccc6-c6c(n(-c7ccccc7)c7ccccc67)-c6ccccc65)cc4)c3)n2)cc1 ; c1ccc(-c2nc(-c3ccccc3)nc(-c3ccc(-c4c(-c5ccc6c7ccccc7c7ccccc7c6c5)ccc5ccccc45)cc3)n2)cc1]

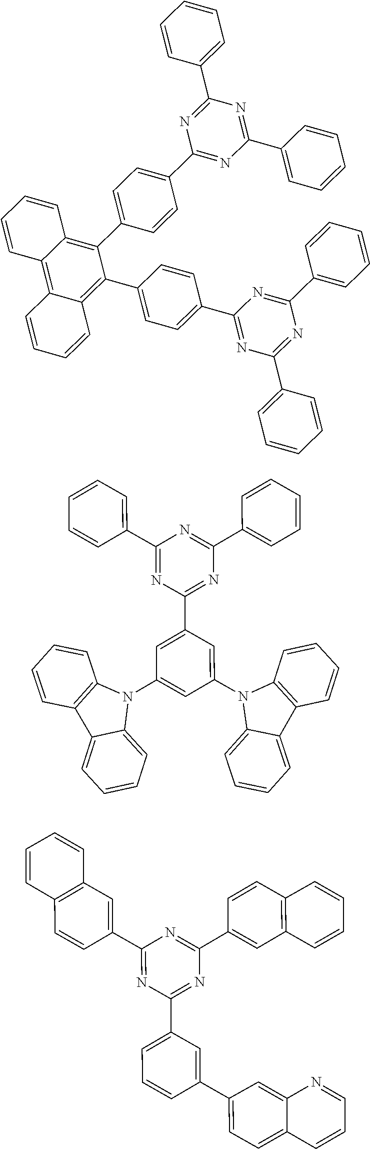

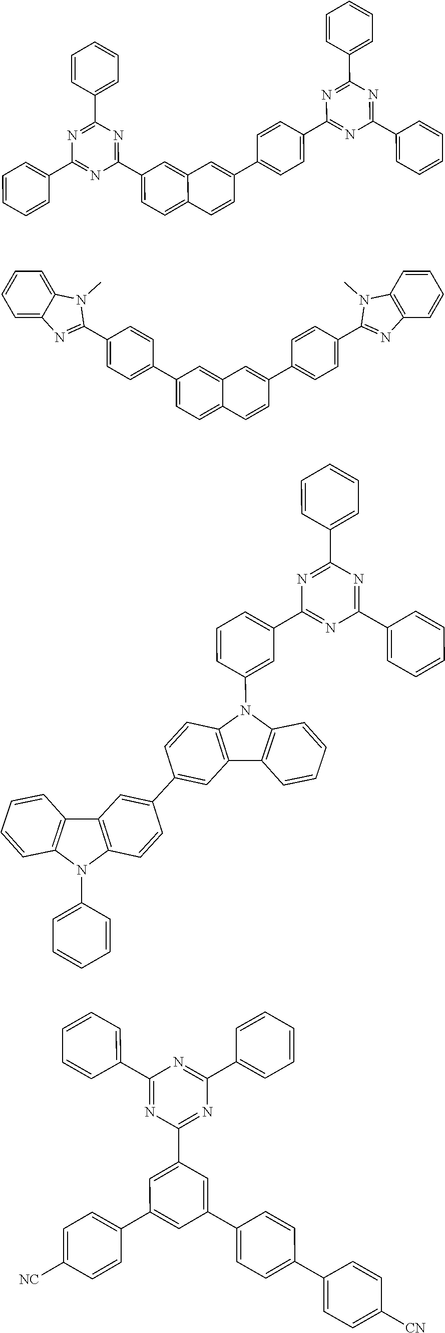

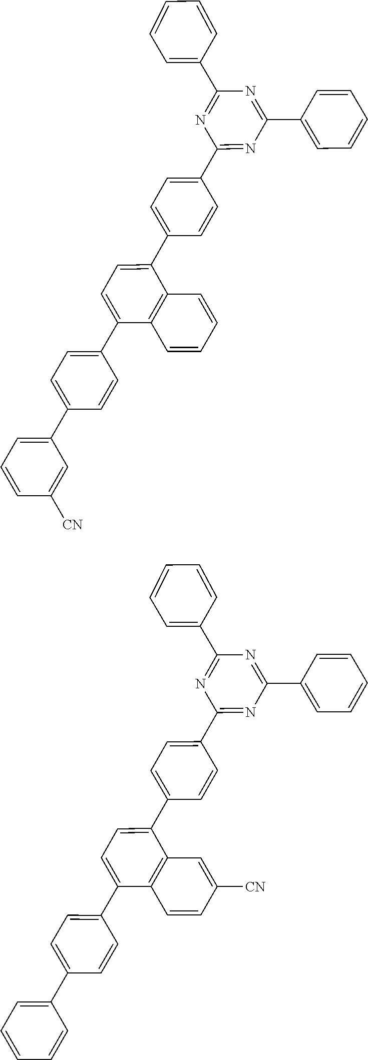 [SMILES: N#Cc1cccc(-c2ccc(-c3ccc(-c4ccc(-c5nc(-c6ccccc6)nc(-c6ccccc6)n5)cc4)c4ccccc34)cc2)c1 ; N#Cc1ccc2c(-c3ccc(-c4ccccc4)cc3)ccc(-c3ccc(-c4nc(-c5ccccc5)nc(-c5ccccc5)n4)cc3)c2c1]

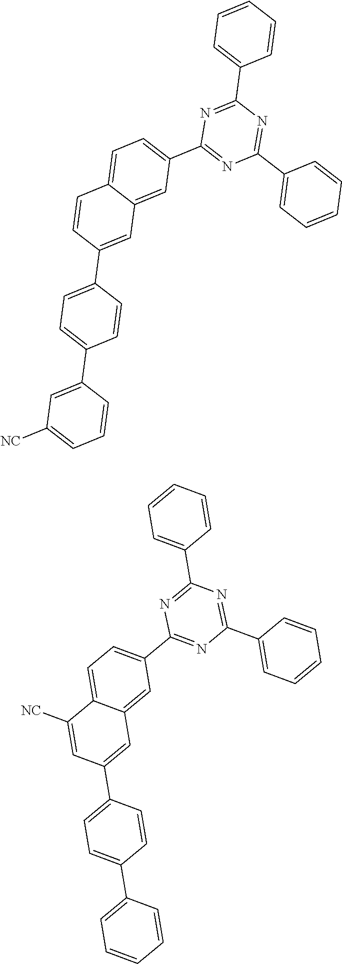 [SMILES: N#Cc1cccc(-c2ccc(-c3ccc4ccc(-c5nc(-c6ccccc6)nc(-c6ccccc6)n5)cc4c3)cc2)c1 ; N#Cc1cc(-c2ccc(-c3ccccc3)cc2)cc2cc(-c3nc(-c4ccccc4)nc(-c4ccccc4)n3)ccc12]

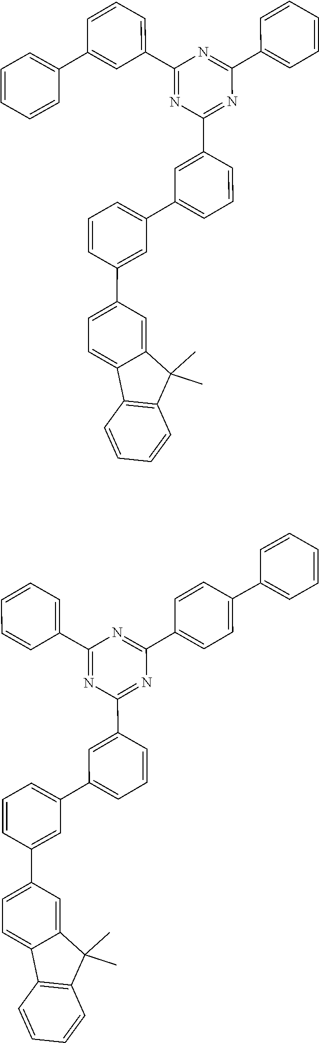 [SMILES: CC1(C)c2ccccc2-c2ccc(-c3cccc(-c4cccc(-c5nc(-c6ccccc6)nc(-c6cccc(-c7ccccc7)c6)n5)c4)c3)cc21 ; CC1(C)c2ccccc2-c2ccc(-c3cccc(-c4cccc(-c5nc(-c6ccccc6)nc(-c6ccc(-c7ccccc7)cc6)n5)c4)c3)cc21]

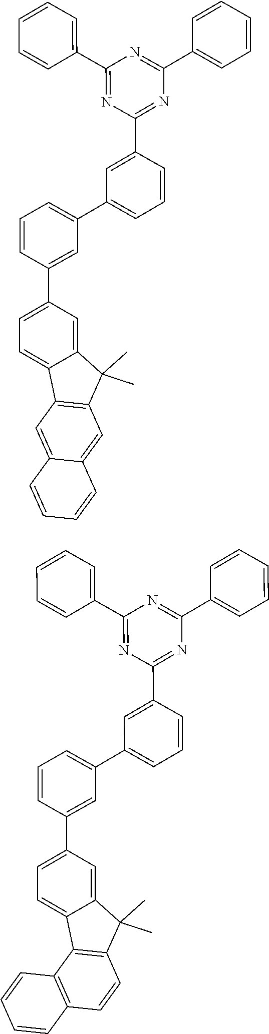

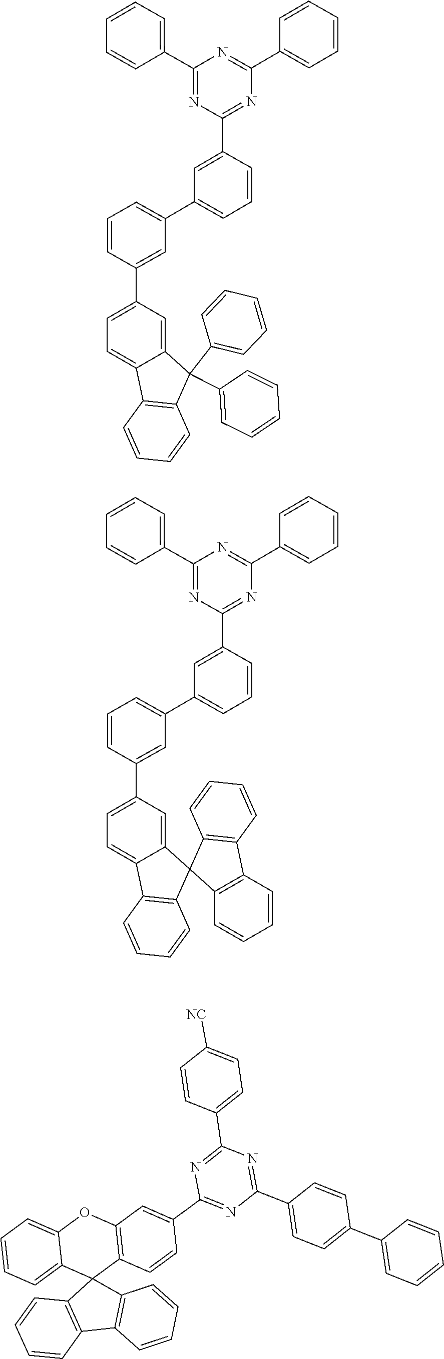

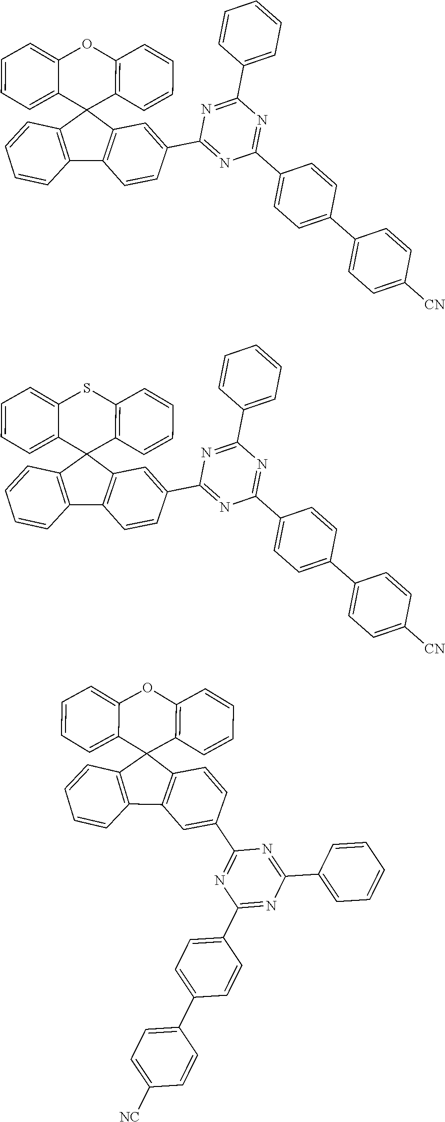 [SMILES: N#Cc1ccc(-c2ccc(-c3nc(-c4ccccc4)nc(-c4ccc5c(c4)C4(c6ccccc6Oc6ccccc64)c4ccccc4-5)n3)cc2)cc1 ; N#Cc1ccc(-c2ccc(-c3nc(-c4ccccc4)nc(-c4ccc5c(c4)C4(c6ccccc6Sc6ccccc64)c4ccccc4-5)n3)cc2)cc1 ; N#Cc1ccc(-c2ccc(-c3nc(-c4ccccc4)nc(-c4ccc5c(c4)-c4ccccc4C54c5ccccc5Oc5ccccc54)n3)cc2)cc1]

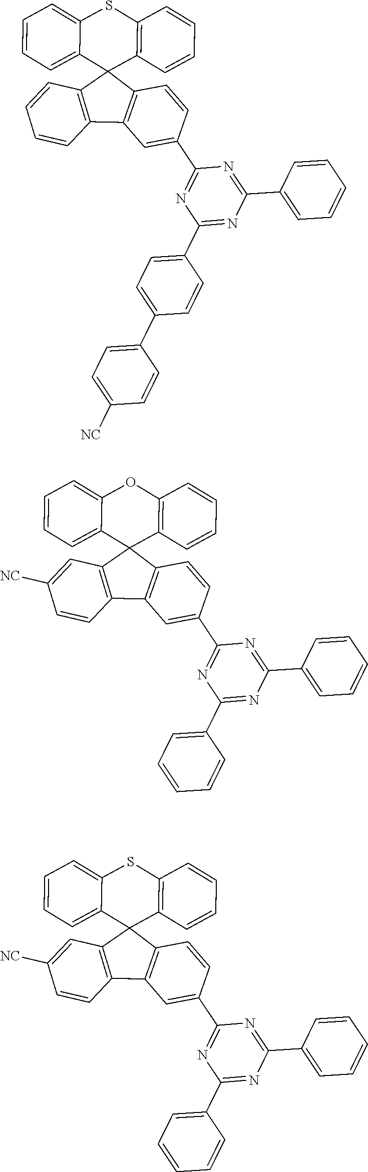 [SMILES: N#Cc1ccc(-c2ccc(-c3nc(-c4ccccc4)nc(-c4ccc5c(c4)-c4ccccc4C54c5ccccc5Sc5ccccc54)n3)cc2)cc1 ; N#Cc1ccc2c(c1)C1(c3ccccc3Oc3ccccc31)c1ccc(-c3nc(-c4ccccc4)nc(-c4ccccc4)n3)cc1-2 ; N#Cc1ccc2c(c1)C1(c3ccccc3Sc3ccccc31)c1ccc(-c3nc(-c4ccccc4)nc(-c4ccccc4)n3)cc1-2]

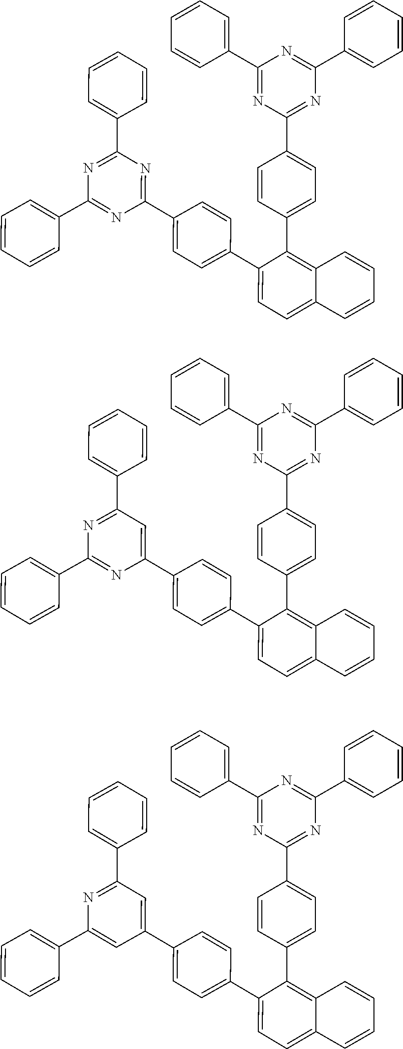 [SMILES: c1ccc(-c2nc(-c3ccccc3)nc(-c3ccc(-c4ccc5ccccc5c4-c4ccc(-c5nc(-c6ccccc6)nc(-c6ccccc6)n5)cc4)cc3)n2)cc1 ; c1ccc(-c2cc(-c3ccc(-c4ccc5ccccc5c4-c4ccc(-c5nc(-c6ccccc6)nc(-c6ccccc6)n5)cc4)cc3)nc(-c3ccccc3)n2)cc1 ; c1ccc(-c2cc(-c3ccc(-c4ccc5ccccc5c4-c4ccc(-c5nc(-c6ccccc6)nc(-c6ccccc6)n5)cc4)cc3)cc(-c3ccccc3)n2)cc1]

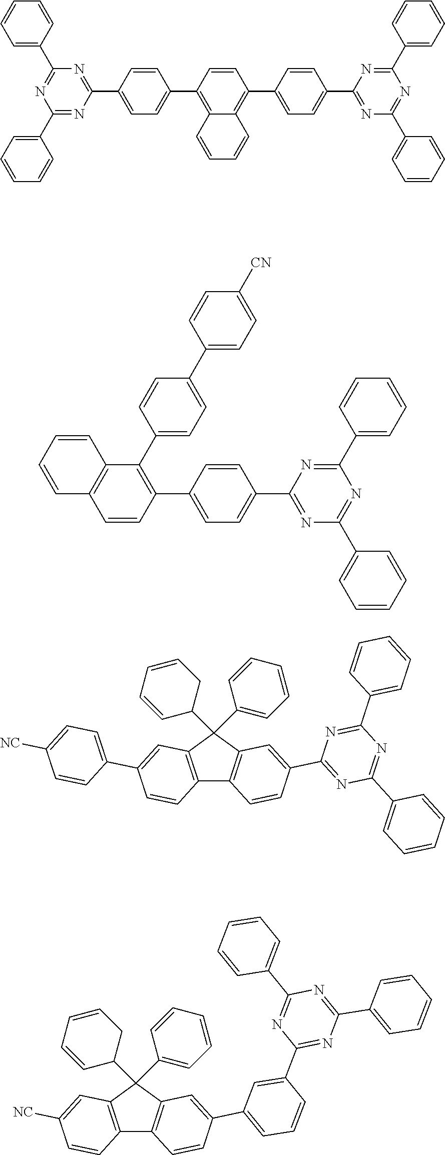

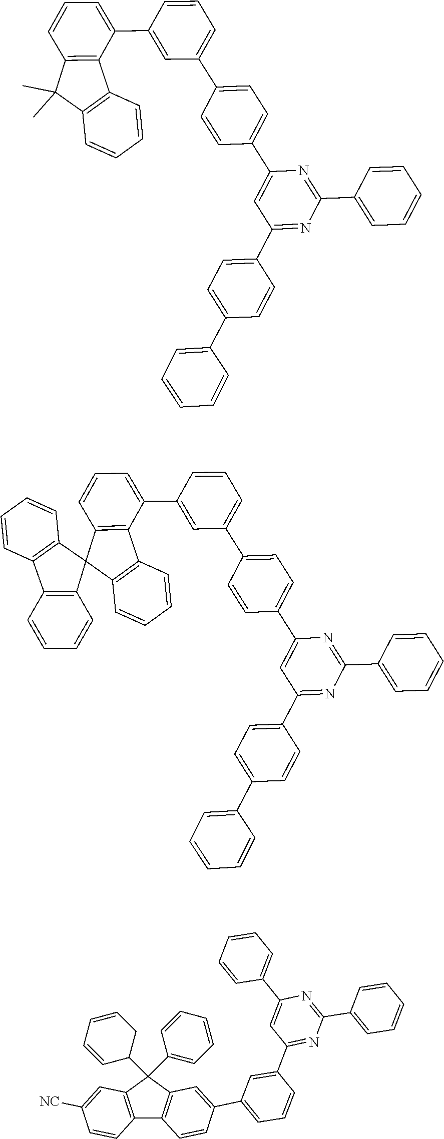 [SMILES: CC1(C)c2ccccc2-c2c(-c3cccc(-c4ccc(-c5cc(-c6ccc(-c7ccccc7)cc6)nc(-c6ccccc6)n5)cc4)c3)cccc21 ; c1ccc(-c2ccc(-c3cc(-c4ccc(-c5cccc(-c6cccc7c6-c6ccccc6C76c7ccccc7-c7ccccc76)c5)cc4)nc(-c4ccccc4)n3)cc2)cc1 ; N#Cc1ccc2c(c1)C(c1ccccc1)(C1C=CC=CC1)c1cc(-c3cccc(-c4cc(-c5ccccc5)nc(-c5ccccc5)n4)c3)ccc1-2]

In an implementation, an organic light emitting diode may further include an electron injection layer a hole injection layer, or the like, in addition to the light emitting layer as the organic layer.

An organic light emitting diode may be, e.g., manufactured by forming an anode or cathode on a substrate, forming an organic layer using a dry film method such as evaporation, sputtering, plasma plating, and ion plating, and then forming a cathode or anode thereon.

The aforementioned organic light emitting diode may be applied to an organic light emitting display device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Hereinafter, starting materials and reactants used in Examples and Synthesis Examples were purchased from Sigma-Aldrich Co. Ltd., TCI Inc., Tokyo chemical industry, or P&H tech as far as there is no particular comment or were synthesized by suitable methods.

### Synthesis of First Compound

### Synthesis Example 1: Synthesis of Compound 1-16

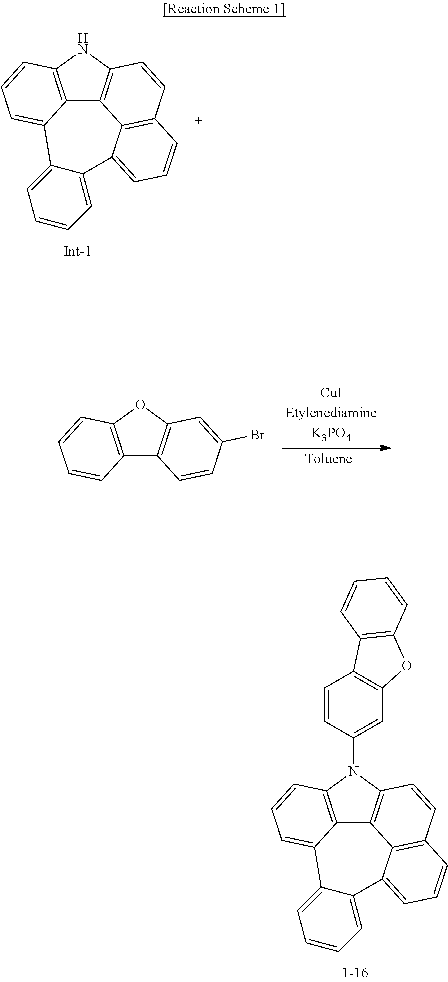 [SMILES: c1ccc2c(c1)-c1cccc3ccc4[nH]c5cccc-2c5c4c13 ; Brc1ccc2c(c1)oc1ccccc12 ; c1ccc2c(c1)-c1cccc3ccc4c(c13)c1c-2cccc1n4-c1ccc2c(c1)oc1ccccc12]

Compound 1-16 (Dn=0) was synthesized by using Int-1 (CAS No. 2408302-78-1) and 3-bromodibenzofuran (CAS No. 26608-06-0) with reference to the synthetic method disclosed in Korean Patent Laid-Open Publication No. 10-2020-0011884.

### Synthesis Example 2: Synthesis of Compound 1-27

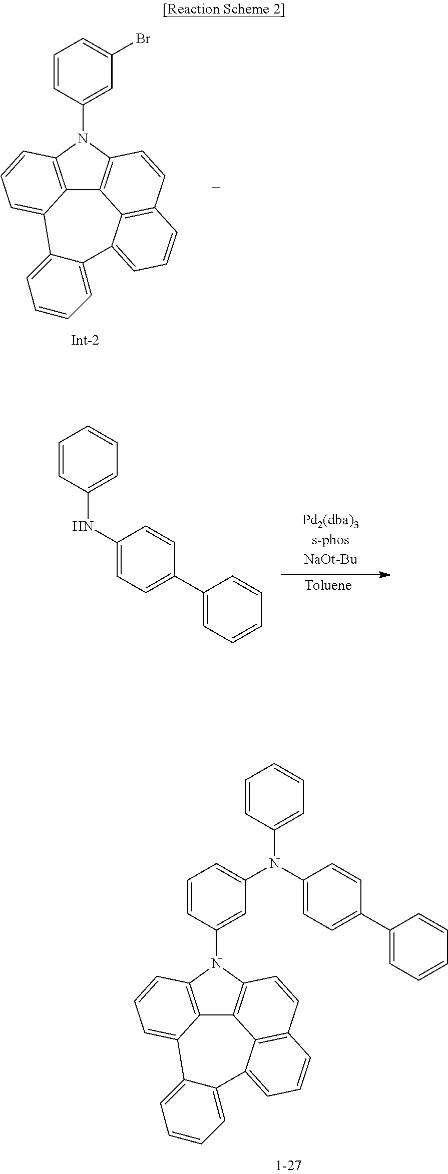 [SMILES: Brc1cccc(-n2c3cccc4c3c3c5c(cccc5ccc32)-c2ccccc2-4)c1 ; c1ccc(Nc2ccc(-c3ccccc3)cc2)cc1 ; c1ccc(-c2ccc(N(c3ccccc3)c3cccc(-n4c5cccc6c5c5c7c(cccc7ccc54)-c4ccccc4-6)c3)cc2)cc1]

Compound 1-27 (Dn=0) was synthesized by using Int-2 (CAS No. 2408617-74-1) and N-phenyl [1,1′-biphenyl]-4-amine (CAS No. 32228-99-2) with reference to the synthetic method disclosed in Korean Patent Laid-Open Publication No. 10-2020-0011884.

### Synthesis Example 3: Synthesis of Compound 1-40

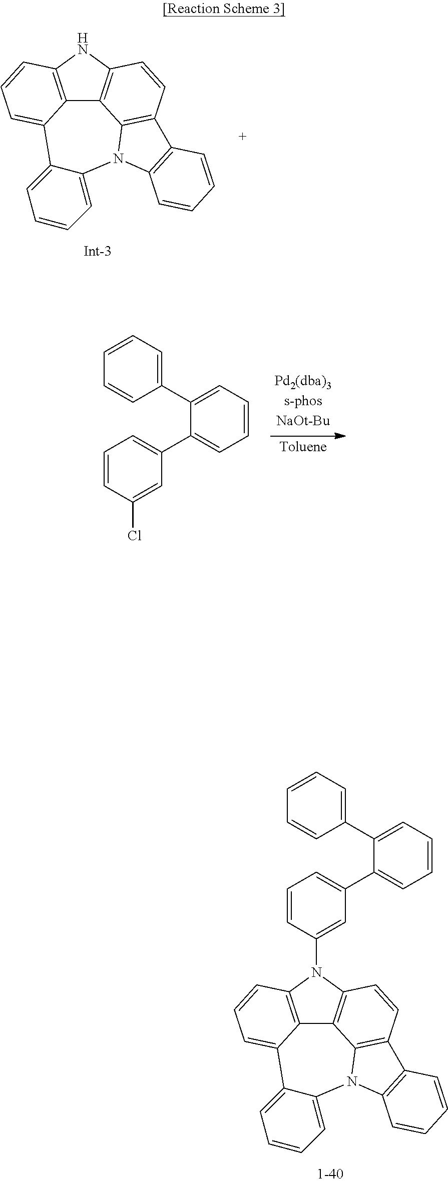 [SMILES: c1cc2[nH]c3ccc4c5ccccc5n5c6ccccc6c(c1)c2c3c45 ; Clc1cccc(-c2ccccc2-c2ccccc2)c1 ; c1ccc(-c2ccccc2-c2cccc(-n3c4cccc5c6ccccc6n6c7ccccc7c7ccc3c(c54)c76)c2)cc1]

Compound 1-40 (Dn=0) was synthesized by using Int-3 (CAS No. 2176462-87-4) and 3-chloro-1,1′: 2′,1″-terphenyl (CAS No. 2179148-28-6) with reference to the synthetic method disclosed in Korean Patent Laid-Open Publication No. 10-2020-0011884.

### Synthesis Example 4: Synthesis of Compound 1-32

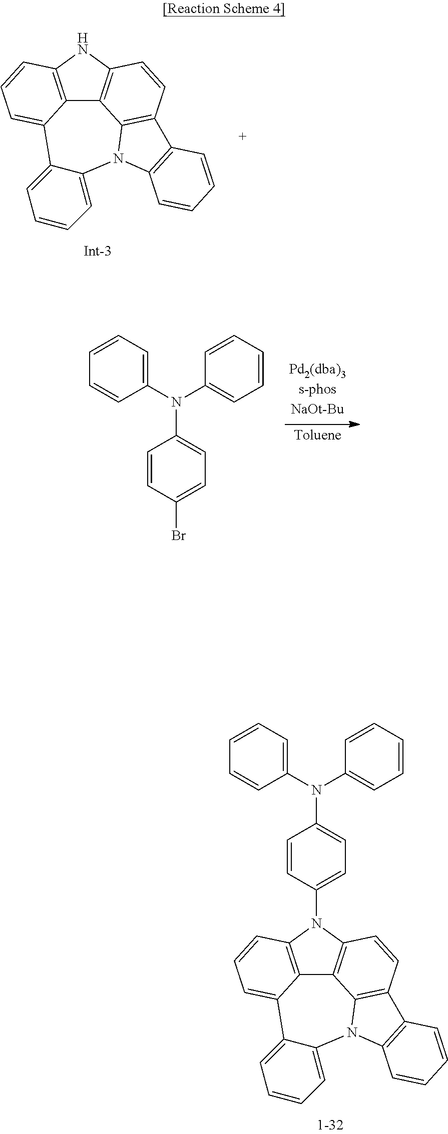 [SMILES: c1cc2[nH]c3ccc4c5ccccc5n5c6ccccc6c(c1)c2c3c45 ; Brc1ccc(N(c2ccccc2)c2ccccc2)cc1 ; c1ccc(N(c2ccccc2)c2ccc(-n3c4cccc5c6ccccc6n6c7ccccc7c7ccc3c(c54)c76)cc2)cc1]

Compound 1-32 (Dn=0) was synthesized by using Int-3 (CAS No. 2176462-87-4) and 4-bromotriphenylamine (CAS No. 36809-26-4) with reference to the synthetic method disclosed in Korean Patent Laid-Open Publication No. 10-2020-0011884.

### Synthesis of Second Compound

### Synthesis Example 5: Synthesis of Compound B-19

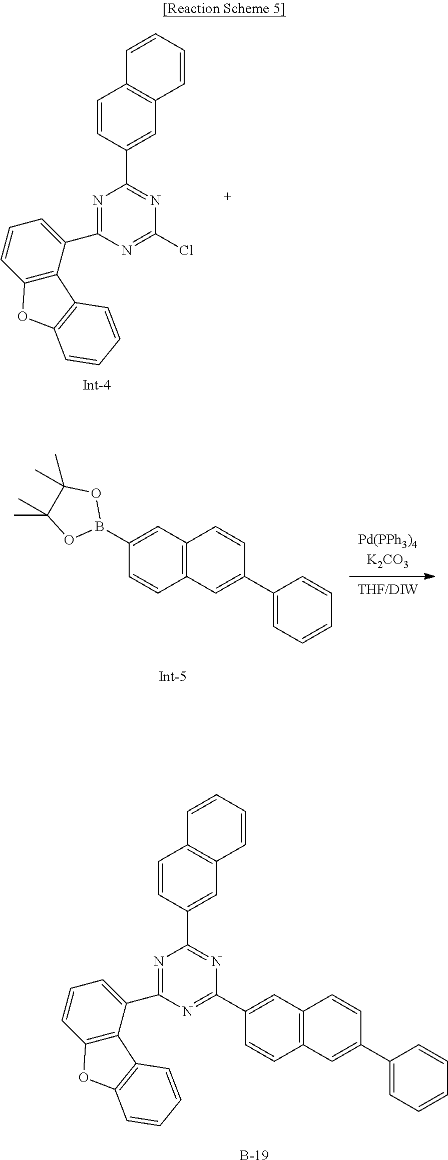

Compound B-19 (Dn=0) was synthesized by using Int-4 (CAS No. 2418528-30-8) and Int-5 (CAS No. 1229235-79-3) with reference to the synthetic method disclosed in Korean Patent Laid-Open Publication No. 10-2024-0052660.

### Synthesis of Third Compound

### Synthesis Example 6: Synthesis of Compound E-1

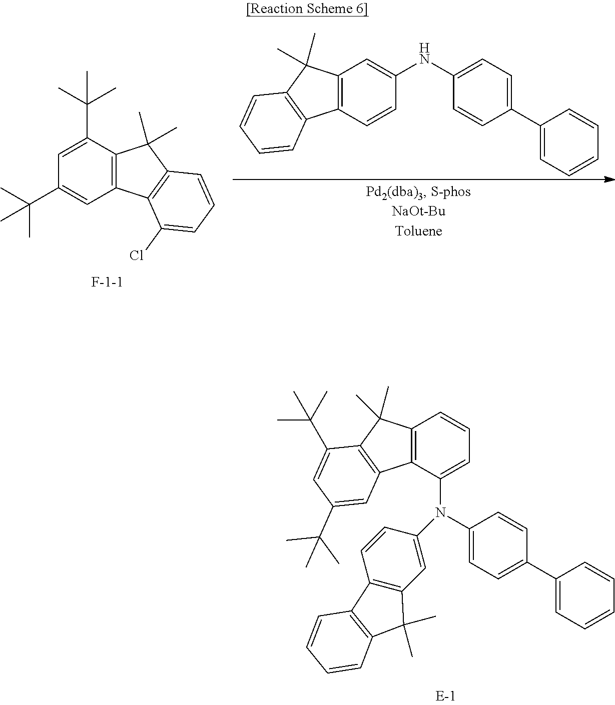 [SMILES: CC(C)(C)c1cc2c(c(C(C)(C)C)c1)C(C)(C)c1cccc(Cl)c1-2 ; CC1(C)c2ccccc2-c2ccc(Nc3ccc(-c4ccccc4)cc3)cc21 ; CC(C)(C)c1cc2c(c(C(C)(C)C)c1)C(C)(C)c1cccc(N(c3ccc(-c4ccccc4)cc3)c3ccc4c(c3)C(C)(C)c3ccccc3-4)c1-2]

In a round-bottomed flask, 410 g (1.203 mol) of Intermediate F-1-1 (CAS No. 2924473-03-8), 435 g (1.082 mol) of an amine intermediate (CAS No. 897674-69-1), and 173 g (1.804 mol) of sodium t-butoxide were added and then dissolved in 4,000 m1 of toluene. Subsequently, 55 g (0.06 mol) of Pd₂(dba)₃ and 74 g (0.18 mol) of SPhos (2-dicyclohexylphosphino-2′,6′-dimethoxybiphenyl) were sequentially added thereto and then stirred under reflux for 6 hours under a nitrogen atmosphere. When a reaction was completed, after removing the toluene solvent, an organic layer, which was extracted with toluene and distilled water, was dried with magnesium sulfate and filtered, and a filtrate therefrom was concentrated under a reduced pressure. A product therefrom was purified by recrystallization with n-hexane/methanol, obtaining 600 g (Yield: 71%) of Compound E-1 (Dn=0).

### Synthesis Example 7: Synthesis of Compound E-21

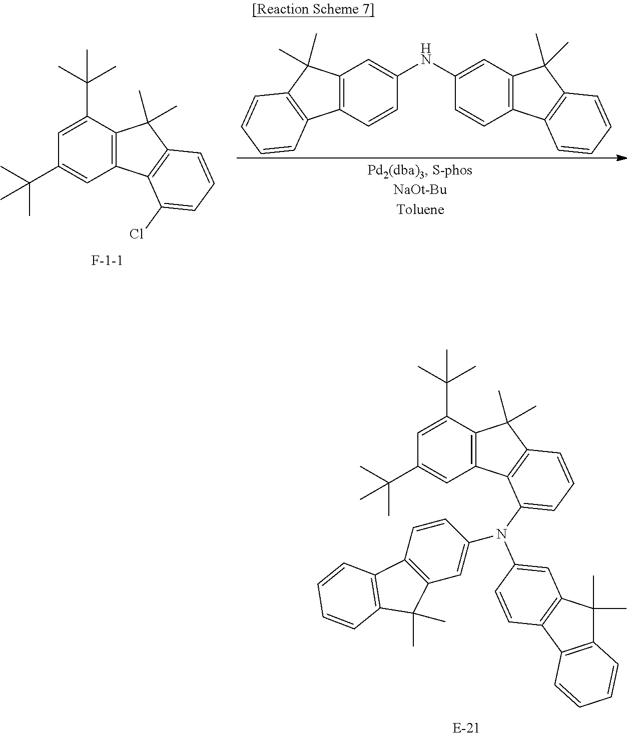 [SMILES: CC(C)(C)c1cc2c(c(C(C)(C)C)c1)C(C)(C)c1cccc(Cl)c1-2 ; CC1(C)c2ccccc2-c2ccc(Nc3ccc4c(c3)C(C)(C)c3ccccc3-4)cc21 ; CC(C)(C)c1cc2c(c(C(C)(C)C)c1)C(C)(C)c1cccc(N(c3ccc4c(c3)C(C)(C)c3ccccc3-4)c3ccc4c(c3)C(C)(C)c3ccccc3-4)c1-2]

Compound E-21 was synthesized using the same method as in Synthesis Example 6 using Intermediate F-1-1 and amine intermediate (CAS No. 500717-23-7).

### Comparative Synthesis Example 1: Synthesis of Compound R-1

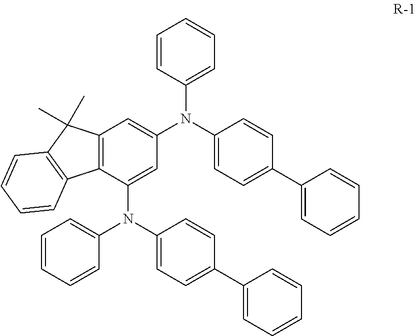 [SMILES: CC1(C)c2ccccc2-c2c(N(c3ccccc3)c3ccc(-c4ccccc4)cc3)cc(N(c3ccccc3)c3ccc(-c4ccccc4)cc3)cc21]

Comparative Compound R-1 was synthesized with reference to Korean Patent Publication No. 10-2023-0059218.

### (Manufacturing of Organic Light Emitting Diode)

### Example 1

A glass substrate coated with a thin film of ITO (indium tin oxide) was ultrasonically cleaned with distilled water. After washing with the distilled water, the glass substrate was ultrasonically washed with isopropyl alcohol, acetone, or methanol and dried and then moved to a plasma cleaner, cleaned by using oxygen plasma for 10 minutes, and moved to a vacuum depositor. This prepared ITO transparent electrode was used as an anode, and Compound A doped with 3% NDP-9 (commercially available from Novaled) was vacuum-deposited on the ITO substrate to form a 100 Å-thick hole injection layer, and a 1,300 Å-thick hole transport layer was formed thereon by depositing Compound A. Compound E-21 obtained in Synthesis Example 7 was deposited on the hole transport layer to a thickness of 650 Å to form a first hole transport auxiliary layer, and Compound B was deposited on the first hole transport auxiliary layer to a thickness of 50 Å to form a second hole transport auxiliary layer. Compound 1-16 of Synthesis Example 1 and Compound B-19 of Synthesis Example 5 were mixed in a weight ratio of 5:5 on the second hole transport auxiliary layer and used simultaneously as a host, and RD was doped at 2 wt % as a dopant to form a 400 Å-thick light emitting layer by vacuum deposition. Then Compound C was deposited on the light emitting layer to form a 50 Å-thick electron transport auxiliary layer, and Compound D and LiQ were simultaneously vacuum deposited at a weight ratio of 1:1 to form a 300 Å-thick electron transport layer. An organic light emitting diode was manufactured by sequentially vacuum-depositing 15 Å of Yb and 1,200 Å of Al on the electron transport layer to form a cathode.

The organic light emitting diode was manufactured with the structure of ITO/Compound A (3% NDP-9 doping, 100 Å)/Compound A (1,300 Å)/first hole transport auxiliary layer (Compound E-21, 650 Å)/Compound B (50 Å)/light emitting layer [Host (Compound 1-16: Compound B-19=50:50): RD=98 wt %: 2 wt %] (400 Å)/Compound C (50 Å)/Compound D: LiQ (300 Å)/Yb (15 Å)/Al (1,200 Å).
Compound A: N-(9,9-diphenyl-9H-fluoren-2-yl)-N,9-diphenyl-9H-carbazol-2-amine
Compound B: 4-[3-(phenanthren-9-yl)phenyl]-N,N-bis(4-phenylphenyl) aniline
Compound C: 4-{4-[3-(9,9-dimethyl-9H-fluoren-4-yl)phenyl]phenyl}-2-phenyl-6-(4-phenylphenyl)pyrimidine
Compound D: 2-(4-{2-[4-(diphenyl-1,3,5-triazin-2-yl)phenyl]naphthalene-1-yl}phenyl)-4,6-diphenyl-1,3,5-triazine

### [RD]

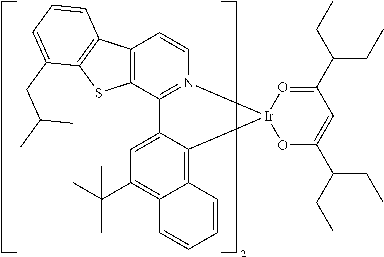

### Examples 2 to 4 and Comparative Example 1

Diodes of Examples 2 to 4 and Comparative Example 1 were manufactured in the same manner as in Example 1, except that the host was changed as described in Table 1.

### Evaluation

The luminous efficiency characteristics of the organic light emitting diodes according to Examples 1 to 4 and Comparative Example 1 were evaluated.

Specific measuring methods are as follows, and the results are shown in Table 1.

### (1) Measurement of Current Density Change Depending on Voltage Change

The obtained organic light emitting diodes were measured regarding a current value flowing in the unit device, while increasing the voltage from 0 V to 10 V using a current-voltage meter (Keithley 2400), and the measured current value was divided by area to provide the results.

### (2) Measurement of Luminance Change Depending on Voltage Change

Luminance was measured by using a luminance meter (Minolta Cs-1000A), while the voltage of the organic light emitting diodes was increased from 0 V to 10 V.

### (3) Measurement of Luminous Efficiency

Luminous Efficiency (cd/A) at the same current density (10 mA/cm²) was calculated by using the luminance and current density from (1) and (2) above and voltage.

The luminous efficiency values of Examples 1 to 4 and Comparative Example 1 were calculated as relative values based on Comparative Example 1 and are listed in Table 1.

TABLE 1

| | | | First hole | |
|---|---|---|---|---|
| | Host | | transport | Luminous |
| | First | Second | auxiliary layer | efficiency |
| No. | compound | compound | Third compound | (%) |
| Example 1 | 1-16 | B-19 | E-21 | 110 |
| Example 2 | 1-27 | B-19 | E-21 | 110 |
| Example 3 | 1-40 | B-19 | E-1 | 108 |
| Example 4 | 1-32 | B-19 | E-21 | 109 |
| Comparative | 1-16 | B-19 | R-1 | 100 |
| Example 1 | | | | |

Referring to Table 1, the organic light emitting diodes to which the composition according to the embodiment is applied exhibited significantly improved luminous efficiency compared to the organic light emitting diode according to the comparative example.

By way of summation and review, some example embodiments may provide an organic optoelectronic device capable of implementing high-efficiency characteristics.

Some example embodiments may provide a display device including the organic optoelectronic device.

High-efficiency organic optoelectronic devices may be realized.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic optoelectronic device, comprising:
an anode and a cathode facing each other,
a light emitting layer between the anode and the cathode,
a hole transport layer between the anode and the light emitting layer, and
a hole transport auxiliary layer between the light emitting layer and the hole transport layer,
wherein the light emitting layer includes a first compound represented by Chemical Formula 1 and a second compound represented by Chemical Formula 2, and
the hole transport auxiliary layer includes a third compound represented by Chemical Formula 3: 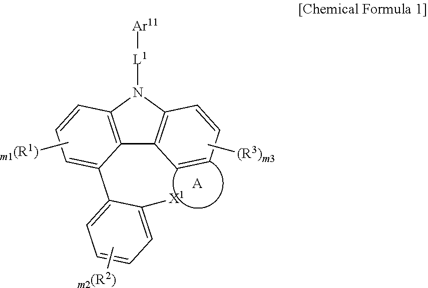
wherein, in Chemical Formula 1,
A is a substituted or unsubstituted benzene ring or a substituted or unsubstituted indole ring,
X¹ is C or N,
L¹ is a single bond or a substituted or unsubstituted C6 to C20 arylene group,
R¹ to R³ are each independently hydrogen, deuterium, a cyano group, a halogen, a substituted or unsubstituted amine group, a substituted or unsubstituted C1 to C30 alkyl group, a substituted or unsubstituted C6 to C30 aryl group, or a substituted or unsubstituted C2 to C30 heterocyclic group,
m1 is an integer of 1 to 3,
m2 is an integer of 1 to 4,
m3 is an integer of 1 or 2,
when m1 is 2 or 3, each R¹ is the same or different from each other,
when m2 is 2, 3, or 4, each R² is the same or different from each other,
when m3 is 2, each R³ is the same or different from each other, and
Ar¹¹ is a substituted or unsubstituted aryl group, a substituted or unsubstituted heterocyclic group, or an amine group represented by Chemical Formula a, 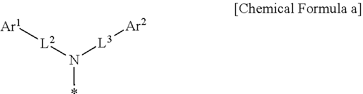
wherein, in Chemical Formula a,
L² and L³ are each independently a single bond or a substituted or unsubstituted C6 to C20 arylene group,
Ar¹ and Ar² are each independently a substituted or unsubstituted C6 to C20 aryl group or a substituted or unsubstituted C2 to C30 heterocyclic group; 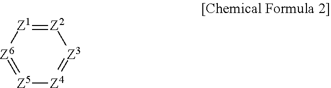
wherein, in Chemical Formula 2,
Z¹ to Z⁶ are each independently N or C-L^{a}-R^{a}, provided that at least two of Z¹ to Z⁶ are N,
each L^{a} is independently a single bond, a substituted or unsubstituted C6 to C20 arylene group, a substituted or unsubstituted C2 to C20 heterocyclic group, or a combination thereof,
each R^{a} is independently hydrogen, deuterium, a cyano group, a halogen, a substituted or unsubstituted C1 to C30 alkyl group, a substituted or unsubstituted C6 to C30 aryl group, or a substituted or unsubstituted C2 to C30 heterocyclic group, a substituted or unsubstituted silyl group, a substituted or unsubstituted amine group, or a combination thereof, and
each R^{a} is separately present or adjacent groups thereof are linked to each other to form a substituted or unsubstituted aliphatic monocyclic or polycyclic ring, a substituted or unsubstituted aromatic monocyclic or polycyclic ring, or a substituted or unsubstituted heteroaromatic monocyclic or polycyclic ring; 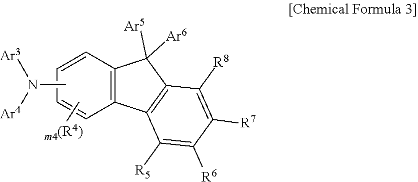
wherein, in Chemical Formula 3,
Ar³ and Ar⁴ are each independently a substituted or unsubstituted C6 to C30 aryl group or a substituted or unsubstituted C2 to C30 heterocyclic group,
Ar⁵ and Ar⁶ are each independently a substituted or unsubstituted C1 to C30 alkyl group or a substituted or unsubstituted C6 to C30 aryl group,
R⁴ to R⁸ are each independently hydrogen, deuterium, a cyano group, a halogen, a substituted or unsubstituted C1 to C30 alkyl group, a substituted or unsubstituted C6 to C30 aryl group, or a substituted or unsubstituted C2 to C30 heterocyclic group,
m4 is an integer of 1 to 3, and
when m4 is 2 or 3, each R⁴ is the same or different from each other.

2. The organic optoelectronic device as claimed in claim 1, wherein:
Chemical Formula 1 is represented by Chemical Formula 1A or Chemical Formula 1B: 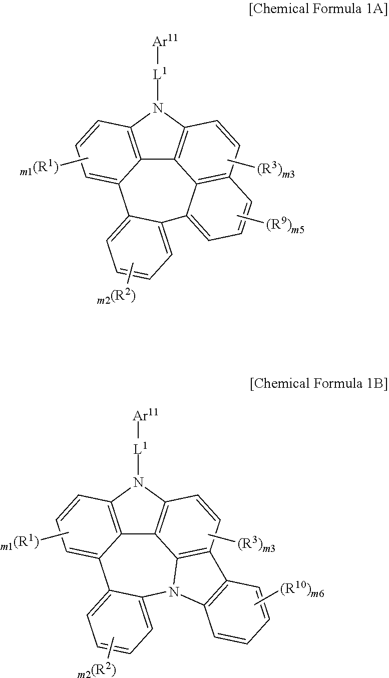
in Chemical Formula 1A and Chemical Formula 1B,
L¹, Ar¹¹, R¹ to R³, and m1 to m3 are defined the same as those of Chemical Formula 1,
R⁹ and R¹⁰ are each independently hydrogen, deuterium, a cyano group, a halogen, a substituted or unsubstituted amine group, a substituted or unsubstituted C1 to C30 alkyl group, a substituted or unsubstituted C6 to C30 aryl group, or a substituted or unsubstituted C2 to C30 heterocyclic group,
m5 is an integer of 1 to 3, and
m6 is an integer of 1 to 4.

3. The organic optoelectronic device as claimed in claim 1, wherein:
Ar¹¹ is a substituted or unsubstituted phenyl group, a substituted or unsubstituted biphenyl group, a substituted or unsubstituted terphenyl group, a substituted or unsubstituted naphthyl group, a substituted or unsubstituted anthracenyl group, a substituted or unsubstituted phenanthrenyl group, a substituted or unsubstituted triphenylene group, a substituted or unsubstituted chrysenyl group, a substituted or unsubstituted fluorenyl group, a substituted or unsubstituted 9,9′-spirobifluorenyl group, a substituted or unsubstituted dibenzofuranyl group, a substituted or unsubstituted dibenzothiophenyl group, or an amine group represented by Chemical Formula a,
in Chemical Formula a, L² and L³ are each independently a single bond, a substituted or unsubstituted phenylene group, or a substituted or unsubstituted biphenylene group, and
in Chemical Formula a, Ar¹ and Ar² are each independently a substituted or unsubstituted phenyl group, a substituted or unsubstituted biphenyl group, a substituted or unsubstituted naphthyl group, a substituted or unsubstituted dibenzofuranyl group, or a substituted or unsubstituted dibenzothiophenyl group.

4. The organic optoelectronic device as claimed in claim 1, wherein:
Chemical Formula 2 is represented by one of Chemical Formula 2A to Chemical Formula 2E: 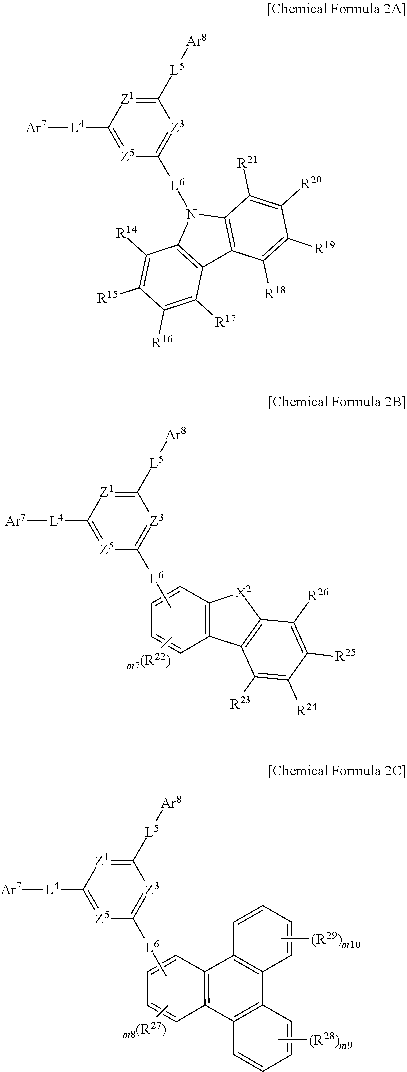 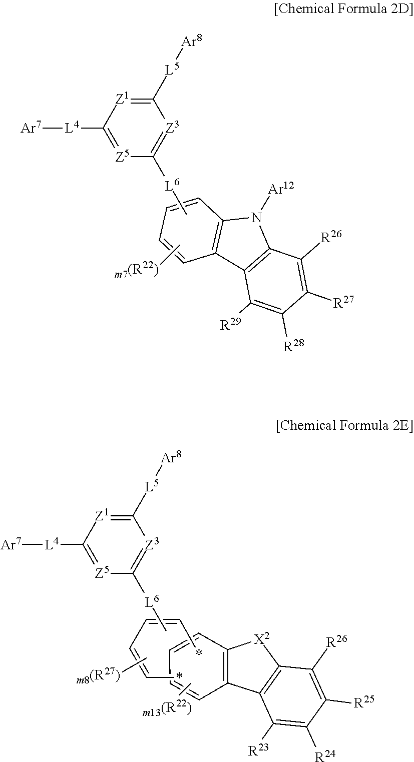
in Chemical Formula 2A to Chemical Formula 2E,
Z¹, Z³, and Z⁵ are each independently N or C-L^{a}-R^{a}, provided that at least two of Z¹, Z³, and Z⁵ are N,
X² is O, S, or NR^{b},
L^{a} and L⁴ to L⁶ are each independently a single bond, a substituted or unsubstituted C6 to C20 arylene group, a substituted or unsubstituted C2 to C20 heterocyclic group, or a combination thereof,
R^{a}, R^{b}, and R¹⁴ to R²⁹ are each independently hydrogen, deuterium, a cyano group, a halogen, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, or a combination thereof,
R¹⁴ to R²¹ are each separately present or adjacent groups thereof are linked to each other to form a substituted or unsubstituted aromatic monocyclic or polycyclic ring,
R²³ to R²⁶ are each separately present or adjacent groups thereof are linked to each other to form a substituted or unsubstituted aromatic monocyclic or polycyclic ring,
Ar⁷, Ar⁸, and Ar¹² are each independently a substituted or unsubstituted C6 to C30 aryl group, a substituted or unsubstituted C2 to C30 heterocyclic group, or a combination thereof,
R^{a}, Ar⁷, and Ar⁸ are each separately present or adjacent groups of R^{a}, Ar⁷, and Ar⁸ are linked to each other to form a substituted or unsubstituted aromatic monocyclic or polycyclic ring or a substituted or unsubstituted heteroaromatic monocyclic or polycyclic ring,
m9 and m10 are each independently an integer of 1 to 4,
m7 and m8 are each independently an integer of 1 to 3, and
m13 is an integer of 1 or 2.

5. The organic optoelectronic device as claimed in claim 4, wherein:
Chemical Formula 2 is represented by Chemical Formula 2B-IV: 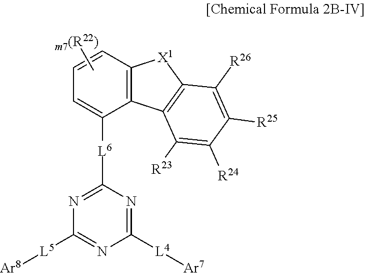
in Chemical Formula 2B-IV,
L⁴ to L⁶ are each independently a single bond, a substituted or unsubstituted phenylene group, a substituted or unsubstituted biphenylene group, a substituted or unsubstituted naphthylene group, a substituted or unsubstituted dibenzofuranylene group, or a substituted or unsubstituted dibenzothiophenylene group,
Ar⁷ and Ar⁸ are each independently a substituted or unsubstituted phenyl group, a substituted or unsubstituted biphenyl group, a substituted or unsubstituted terphenyl group, a substituted or unsubstituted naphthyl group, a substituted or unsubstituted triphenylene group, a substituted or unsubstituted chrysenyl group, a substituted or unsubstituted carbazolyl group, a substituted or unsubstituted dibenzofuranyl group, a substituted or unsubstituted dibenzothiophenyl group, a substituted or unsubstituted naphthobenzofuranyl group, or a substituted or unsubstituted naphthobenzothiophenyl group,
R²² to R²⁶ are each independently hydrogen, deuterium, a substituted or unsubstituted C1 to C10 alkyl group, a substituted or unsubstituted phenyl group, a substituted or unsubstituted naphthyl group, a substituted or unsubstituted dibenzofuranyl group, or a substituted or unsubstituted dibenzothiophenyl group, X² is the same as defined in claim 4, and
m7 is an integer of 1 to 3.

6. The organic optoelectronic device as claimed in claim 1, wherein:
Chemical Formula 3 is represented by Chemical Formula 3-4: 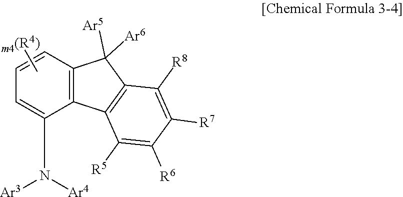
in Chemical Formula 3-4, Ar³ to Ar⁶, R⁴ to R⁸, and m4 are defined the same as those of Chemical Formula 3.

7. The organic optoelectronic device as claimed in claim 6, wherein:
Chemical Formula 3-4 is represented by Chemical Formula 3-4-1: 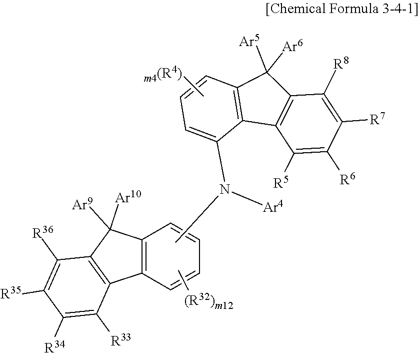
in Chemical Formula 3-4-1,
Ar⁴ to Ar⁶, R⁴ to R⁸, and m4 are defined the same as those of Chemical Formula 3,
Ar⁹ and Ar¹⁰ are each independently a substituted or unsubstituted C1 to C30 alkyl group or a substituted or unsubstituted C6 to C30 aryl group,
R³² to R³⁶ are each independently hydrogen, deuterium, a cyano group, a halogen, a substituted or unsubstituted C1 to C30 alkyl group, a substituted or unsubstituted C6 to C30 aryl group, or a substituted or unsubstituted C2 to C30 heterocyclic group, and
m12 is an integer of 1 to 3.

8. The organic optoelectronic device as claimed in claim 7, wherein:
Chemical Formula 3-4-1 is represented by Chemical Formula 3-4-1b: 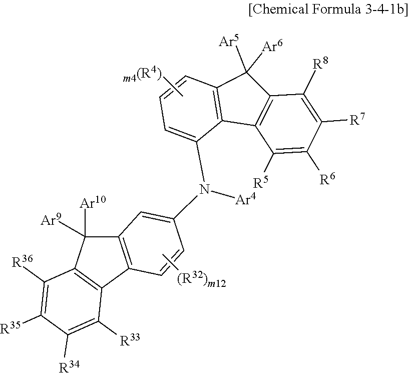
wherein, in Chemical Formula 3-4-1b, Ard to Ar⁶, Ar⁹, Ar¹⁰, R⁴ to R⁸, R³² to R³⁶, m4, and m12 are defined the same as those of Chemical Formula 3-4-1.

9. The organic optoelectronic device as claimed in claim 1, wherein:
the third compound is a compound of Group 3: 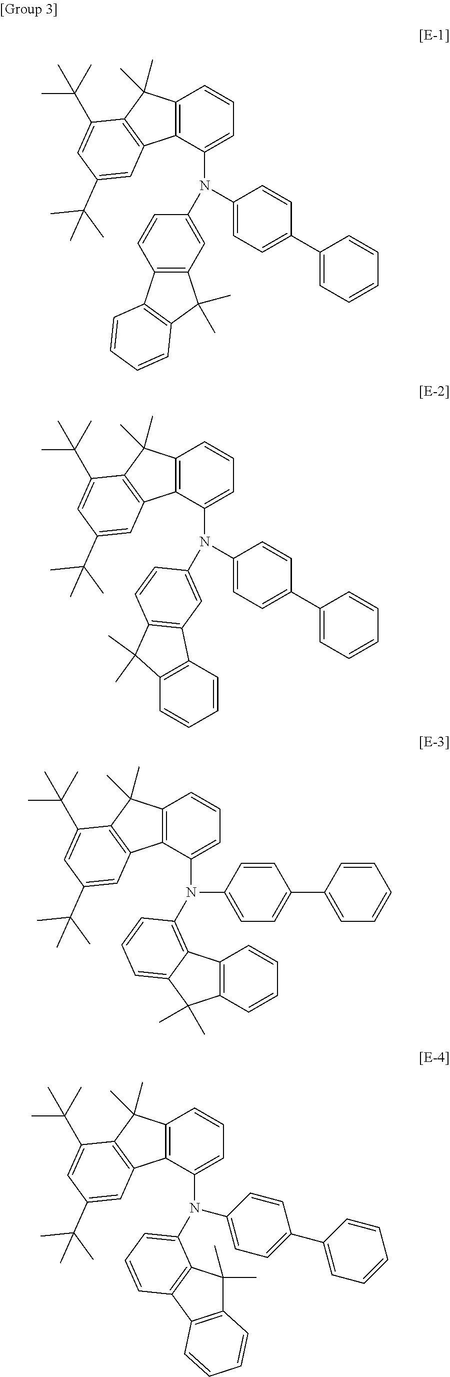 [SMILES: CC(C)(C)c1cc2c(c(C(C)(C)C)c1)C(C)(C)c1cccc(N(c3ccc(-c4ccccc4)cc3)c3ccc4c(c3)C(C)(C)c3ccccc3-4)c1-2 ; CC(C)(C)c1cc2c(c(C(C)(C)C)c1)C(C)(C)c1cccc(N(c3ccc(-c4ccccc4)cc3)c3ccc4c(c3)-c3ccccc3C4(C)C)c1-2 ; CC(C)(C)c1cc2c(c(C(C)(C)C)c1)C(C)(C)c1cccc(N(c3ccc(-c4ccccc4)cc3)c3cccc4c3-c3ccccc3C4(C)C)c1-2 ; CC(C)(C)c1cc2c(c(C(C)(C)C)c1)C(C)(C)c1cccc(N(c3ccc(-c4ccccc4)cc3)c3cccc4c3C(C)(C)c3ccccc3-4)c1-2] 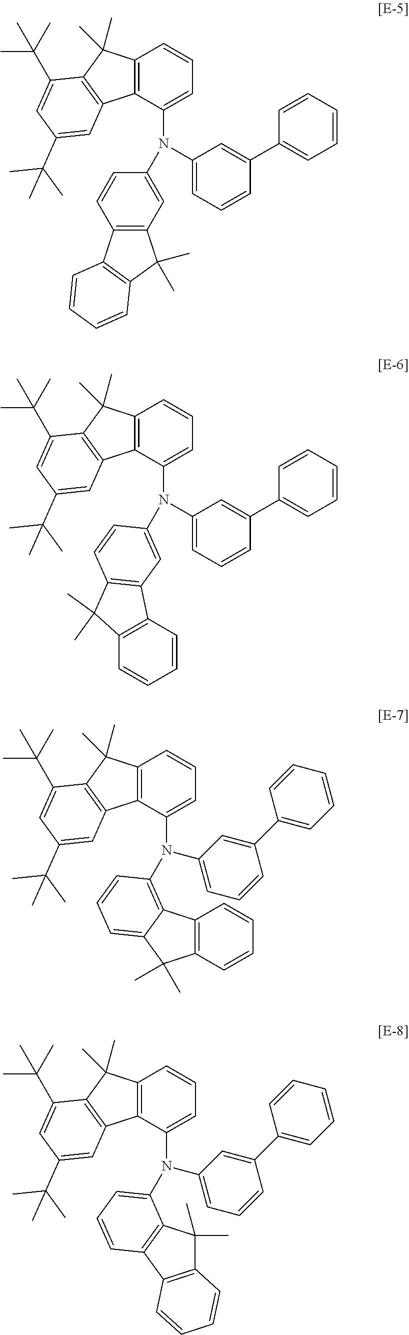 [SMILES: CC(C)(C)c1cc2c(c(C(C)(C)C)c1)C(C)(C)c1cccc(N(c3cccc(-c4ccccc4)c3)c3ccc4c(c3)C(C)(C)c3ccccc3-4)c1-2 ; CC(C)(C)c1cc2c(c(C(C)(C)C)c1)C(C)(C)c1cccc(N(c3cccc(-c4ccccc4)c3)c3ccc4c(c3)-c3ccccc3C4(C)C)c1-2 ; CC(C)(C)c1cc2c(c(C(C)(C)C)c1)C(C)(C)c1cccc(N(c3cccc(-c4ccccc4)c3)c3cccc4c3-c3ccccc3C4(C)C)c1-2 ; CC(C)(C)c1cc2c(c(C(C)(C)C)c1)C(C)(C)c1cccc(N(c3cccc(-c4ccccc4)c3)c3cccc4c3C(C)(C)c3ccccc3-4)c1-2] 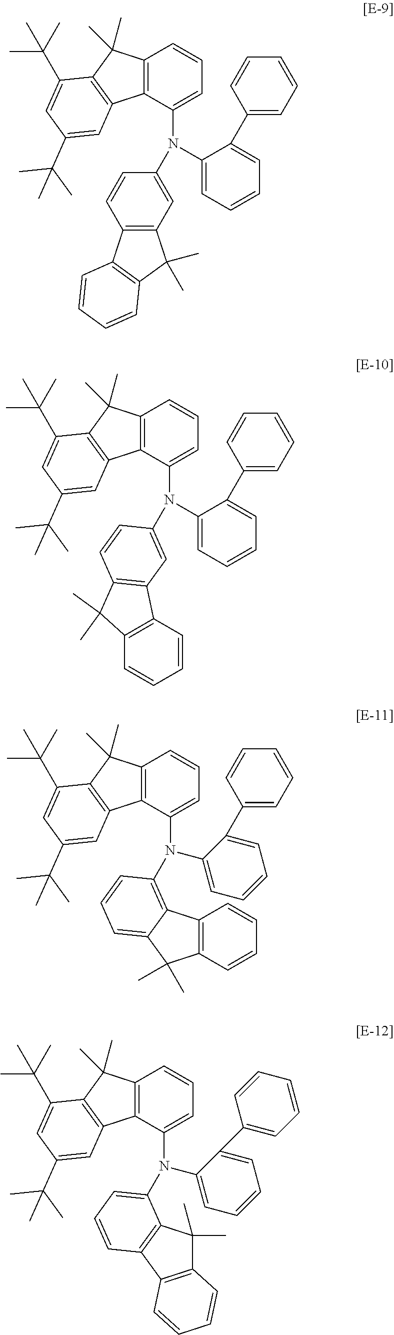 [SMILES: CC(C)(C)c1cc2c(c(C(C)(C)C)c1)C(C)(C)c1cccc(N(c3ccc4c(c3)C(C)(C)c3ccccc3-4)c3ccccc3-c3ccccc3)c1-2 ; CC(C)(C)c1cc2c(c(C(C)(C)C)c1)C(C)(C)c1cccc(N(c3ccc4c(c3)-c3ccccc3C4(C)C)c3ccccc3-c3ccccc3)c1-2 ; CC(C)(C)c1cc2c(c(C(C)(C)C)c1)C(C)(C)c1cccc(N(c3ccccc3-c3ccccc3)c3cccc4c3-c3ccccc3C4(C)C)c1-2 ; CC(C)(C)c1cc2c(c(C(C)(C)C)c1)C(C)(C)c1cccc(N(c3ccccc3-c3ccccc3)c3cccc4c3C(C)(C)c3ccccc3-4)c1-2] 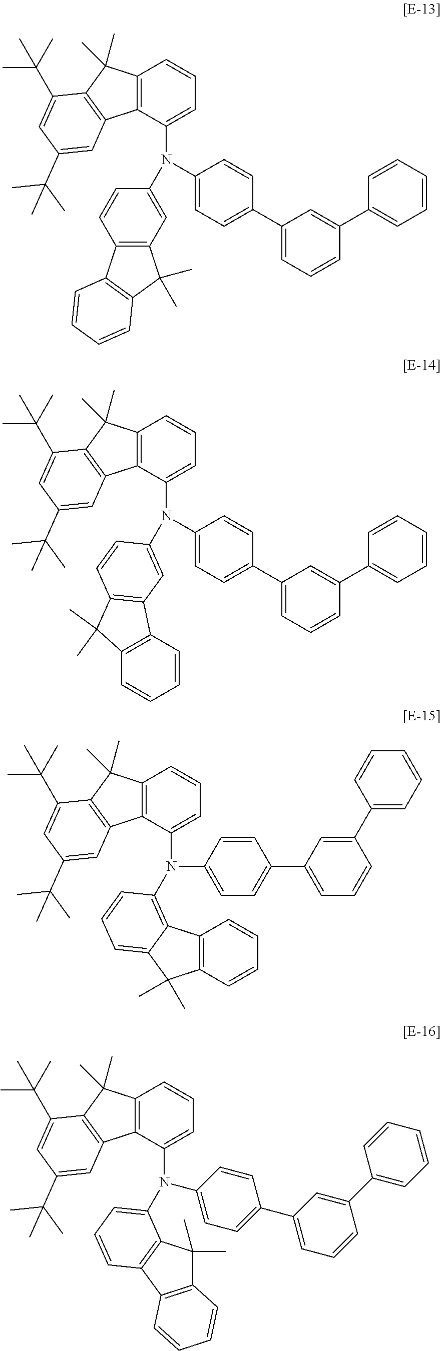 [SMILES: CC(C)(C)c1cc2c(c(C(C)(C)C)c1)C(C)(C)c1cccc(N(c3ccc(-c4cccc(-c5ccccc5)c4)cc3)c3ccc4c(c3)C(C)(C)c3ccccc3-4)c1-2 ; CC(C)(C)c1cc2c(c(C(C)(C)C)c1)C(C)(C)c1cccc(N(c3ccc(-c4cccc(-c5ccccc5)c4)cc3)c3ccc4c(c3)-c3ccccc3C4(C)C)c1-2 ; CC(C)(C)c1cc2c(c(C(C)(C)C)c1)C(C)(C)c1cccc(N(c3ccc(-c4cccc(-c5ccccc5)c4)cc3)c3cccc4c3-c3ccccc3C4(C)C)c1-2 ; CC(C)(C)c1cc2c(c(C(C)(C)C)c1)C(C)(C)c1cccc(N(c3ccc(-c4cccc(-c5ccccc5)c4)cc3)c3cccc4c3C(C)(C)c3ccccc3-4)c1-2] 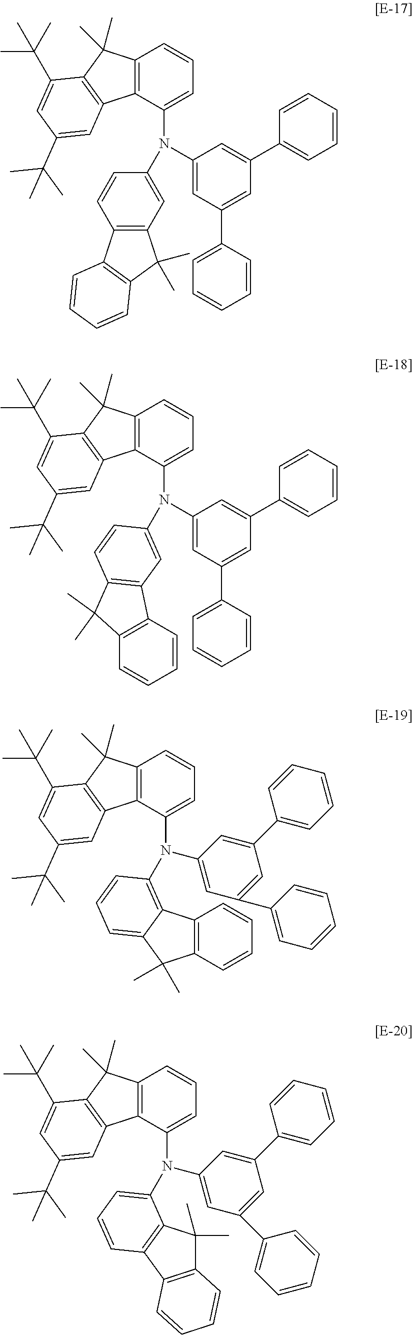 [SMILES: CC(C)(C)c1cc2c(c(C(C)(C)C)c1)C(C)(C)c1cccc(N(c3cc(-c4ccccc4)cc(-c4ccccc4)c3)c3ccc4c(c3)C(C)(C)c3ccccc3-4)c1-2 ; CC(C)(C)c1cc2c(c(C(C)(C)C)c1)C(C)(C)c1cccc(N(c3cc(-c4ccccc4)cc(-c4ccccc4)c3)c3ccc4c(c3)-c3ccccc3C4(C)C)c1-2 ; CC(C)(C)c1cc2c(c(C(C)(C)C)c1)C(C)(C)c1cccc(N(c3cc(-c4ccccc4)cc(-c4ccccc4)c3)c3cccc4c3-c3ccccc3C4(C)C)c1-2 ; CC(C)(C)c1cc2c(c(C(C)(C)C)c1)C(C)(C)c1cccc(N(c3cc(-c4ccccc4)cc(-c4ccccc4)c3)c3cccc4c3C(C)(C)c3ccccc3-4)c1-2] 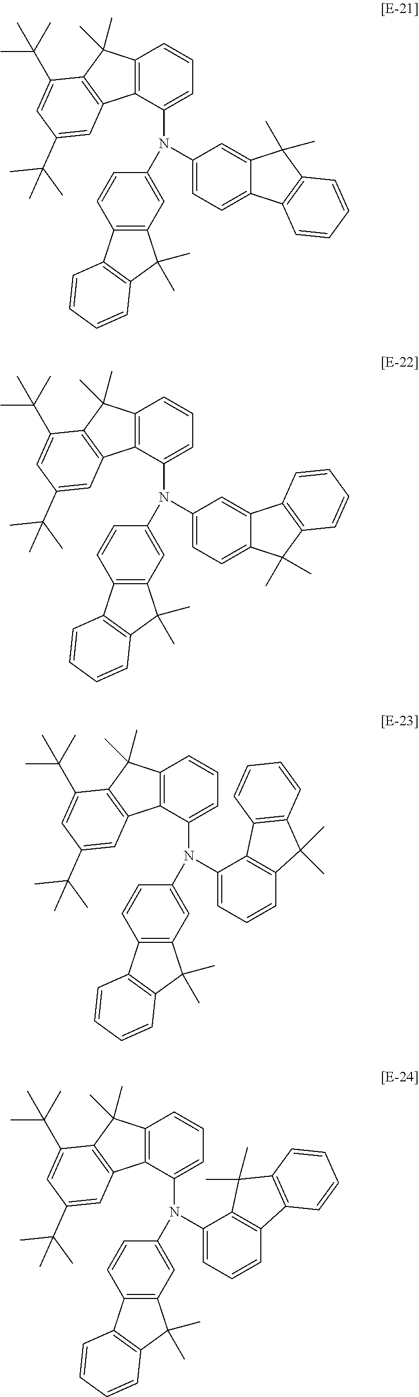 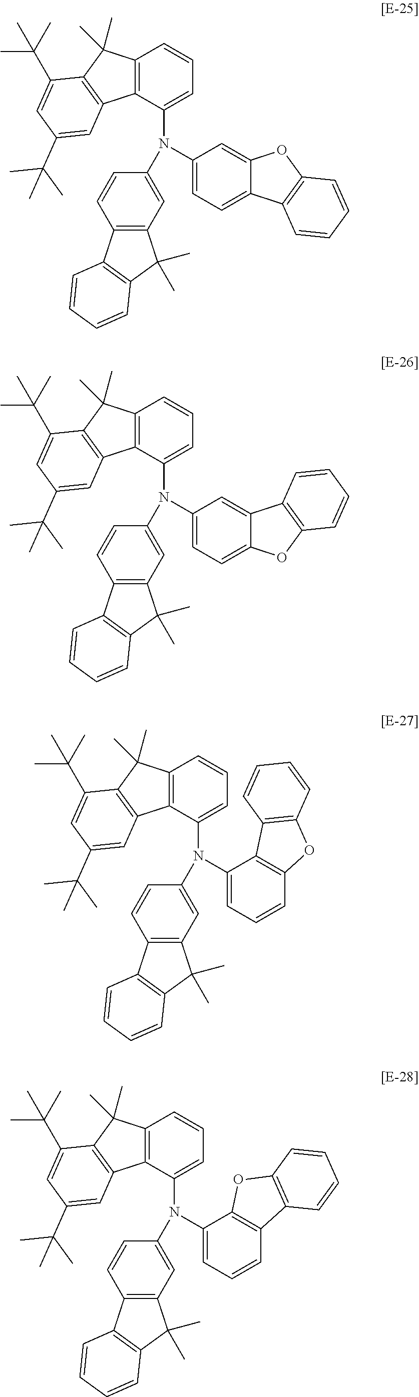 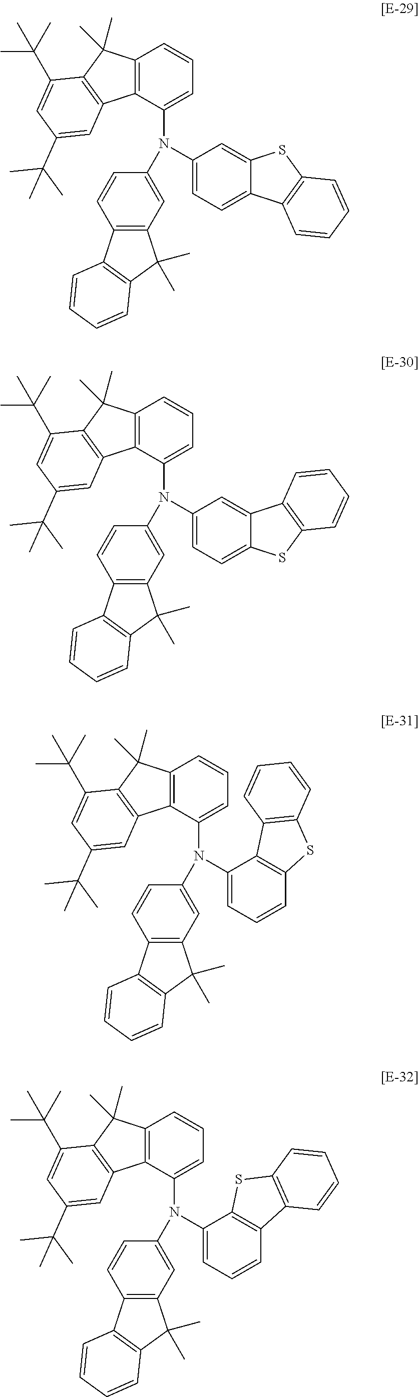 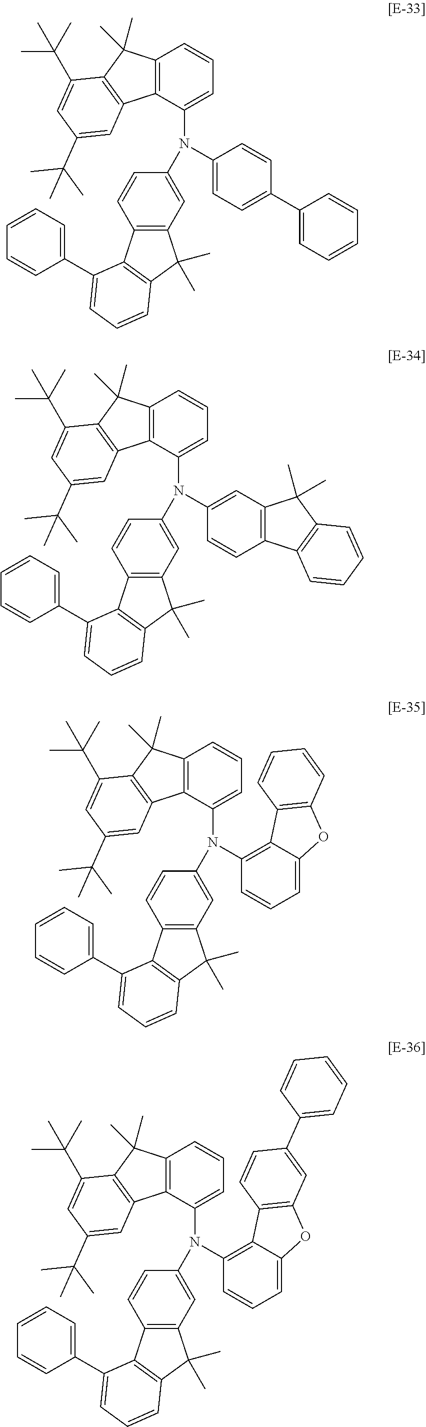 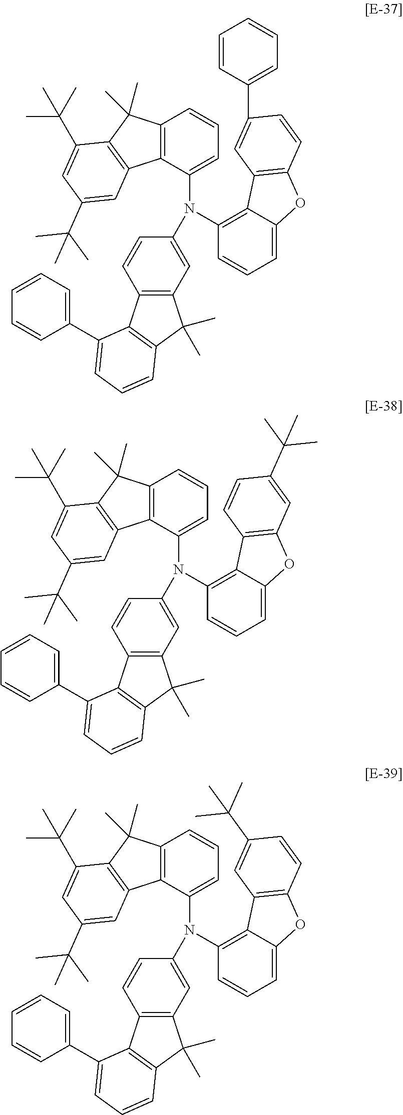 [SMILES: CC(C)(C)c1cc2c(c(C(C)(C)C)c1)C(C)(C)c1cccc(N(c3ccc4c(c3)C(C)(C)c3cccc(-c5ccccc5)c3-4)c3cccc4oc5ccc(-c6ccccc6)cc5c34)c1-2 ; CC(C)(C)c1cc2c(c(C(C)(C)C)c1)C(C)(C)c1cccc(N(c3ccc4c(c3)C(C)(C)c3cccc(-c5ccccc5)c3-4)c3cccc4oc5cc(C(C)(C)C)ccc5c34)c1-2 ; CC(C)(C)c1cc2c(c(C(C)(C)C)c1)C(C)(C)c1cccc(N(c3ccc4c(c3)C(C)(C)c3cccc(-c5ccccc5)c3-4)c3cccc4oc5ccc(C(C)(C)C)cc5c34)c1-2] 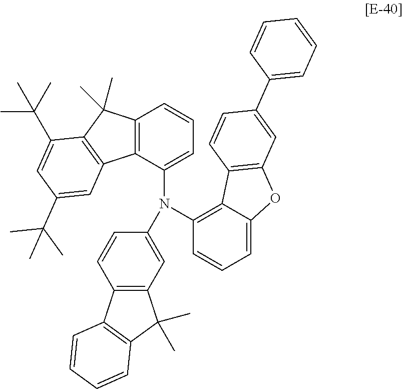 [SMILES: CC(C)(C)c1cc2c(c(C(C)(C)C)c1)C(C)(C)c1cccc(N(c3ccc4c(c3)C(C)(C)c3ccccc3-4)c3cccc4oc5cc(-c6ccccc6)ccc5c34)c1-2] 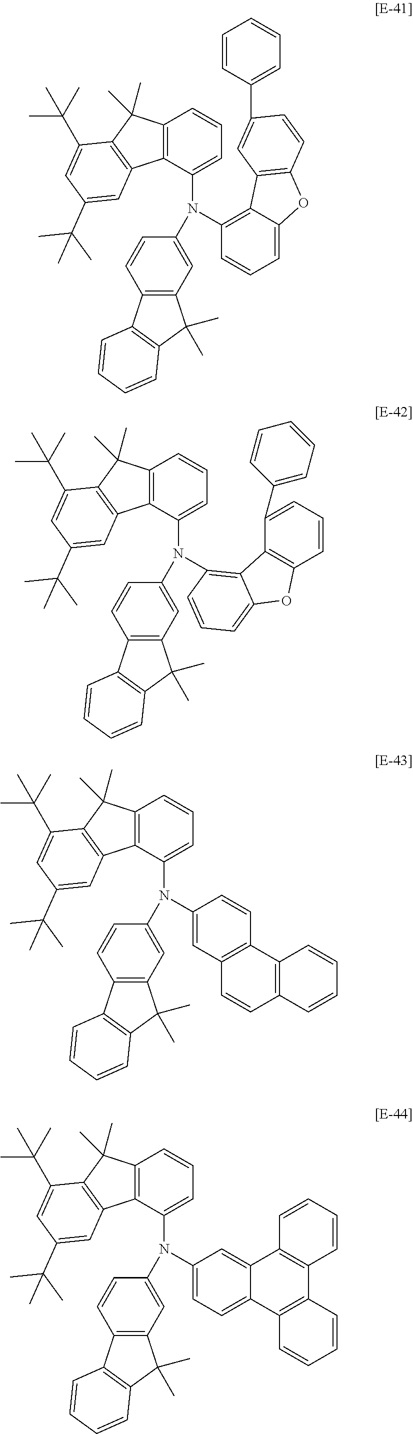 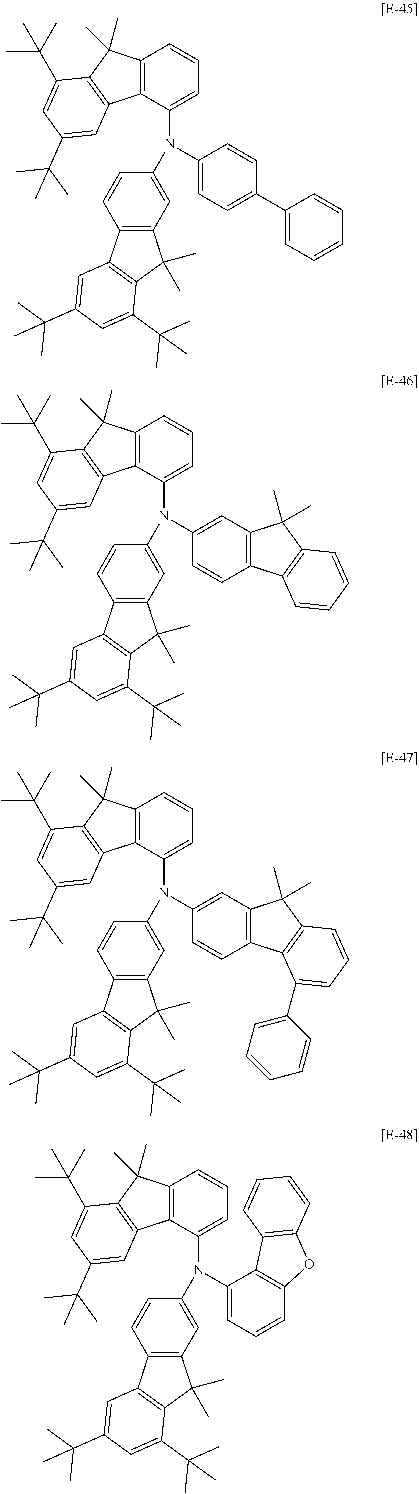 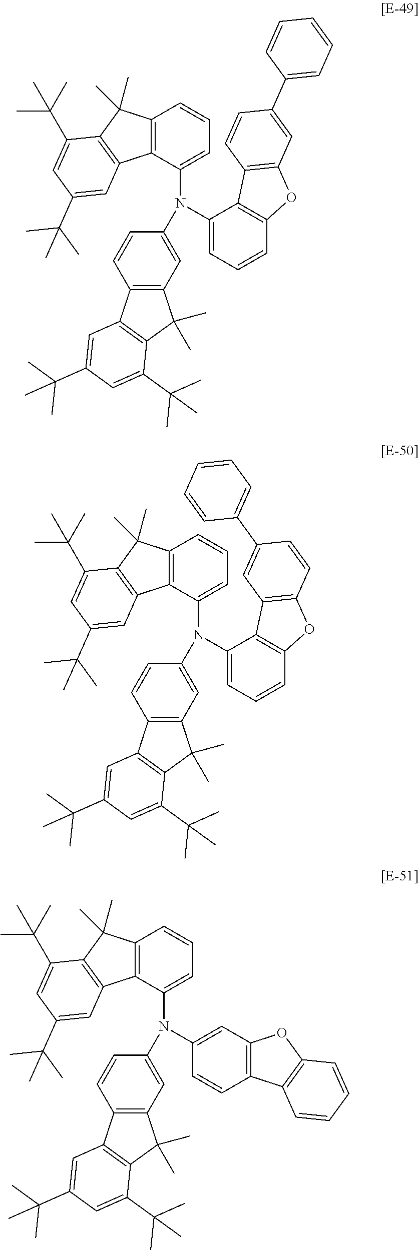 [SMILES: CC(C)(C)c1cc2c(c(C(C)(C)C)c1)C(C)(C)c1cc(N(c3cccc4c3-c3cc(C(C)(C)C)cc(C(C)(C)C)c3C4(C)C)c3cccc4oc5cc(-c6ccccc6)ccc5c34)ccc1-2 ; CC(C)(C)c1cc2c(c(C(C)(C)C)c1)C(C)(C)c1cc(N(c3cccc4c3-c3cc(C(C)(C)C)cc(C(C)(C)C)c3C4(C)C)c3cccc4oc5ccc(-c6ccccc6)cc5c34)ccc1-2 ; CC(C)(C)c1cc2c(c(C(C)(C)C)c1)C(C)(C)c1cc(N(c3ccc4c(c3)oc3ccccc34)c3cccc4c3-c3cc(C(C)(C)C)cc(C(C)(C)C)c3C4(C)C)ccc1-2] 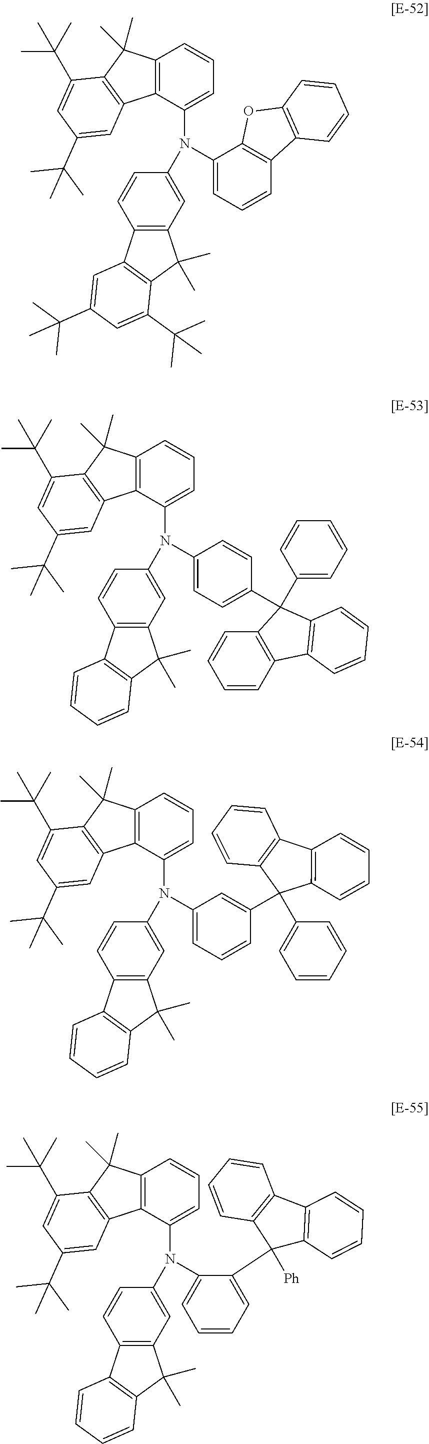 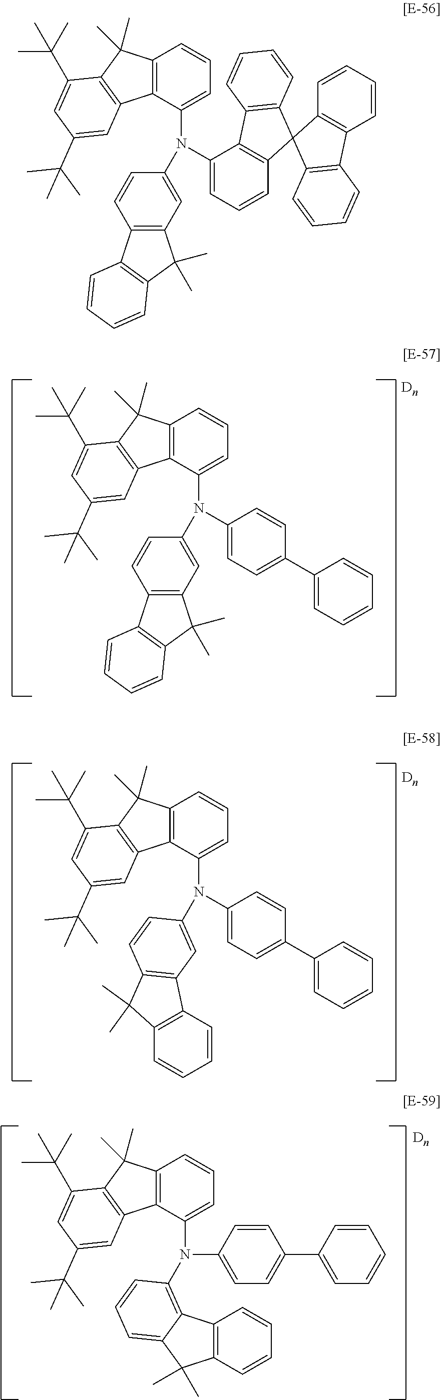 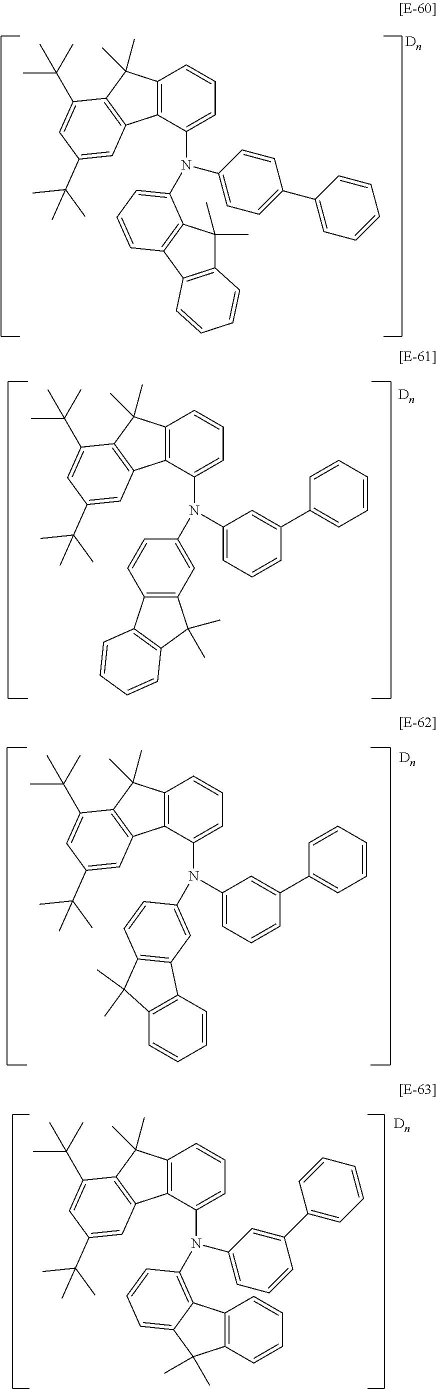 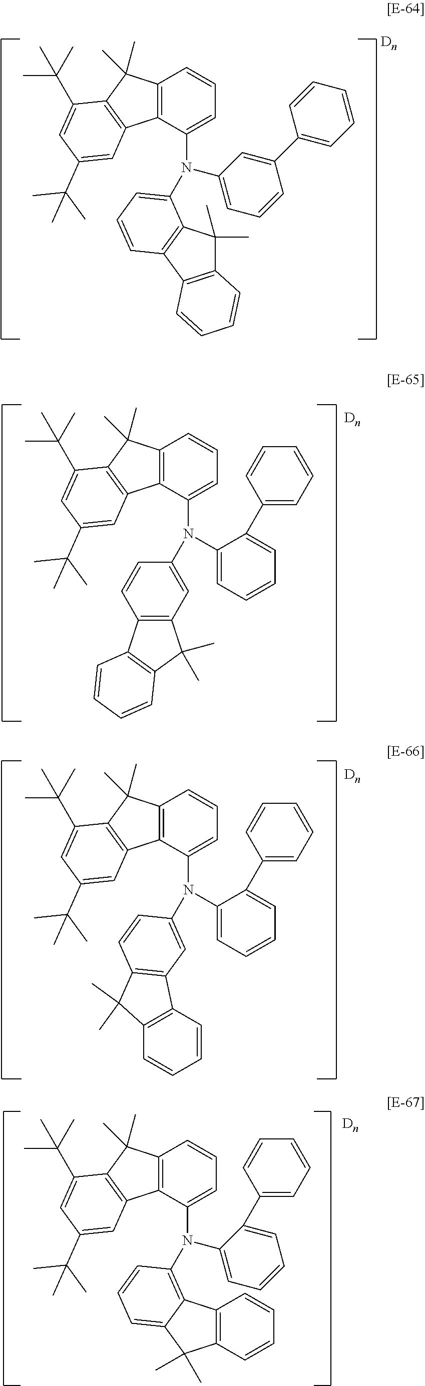 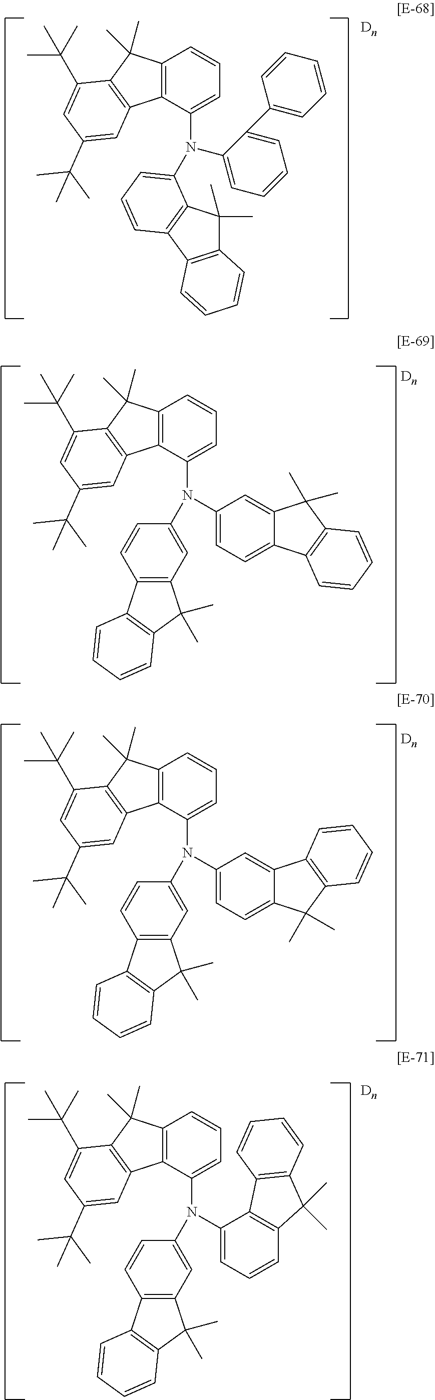 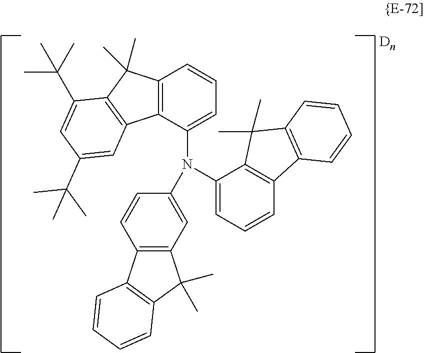
(Dn means the number of deuterium atoms substituted, n is an integer greater than or equal to 0, and the maximum number of n corresponds to the number of substitutable hydrogen positions).

10. The organic optoelectronic device as claimed in claim 1, wherein:
the first compound is represented by Chemical Formula 1A or Chemical Formula 1B,
the second compound is represented by Chemical Formula 2B-IV, and
the third compound is represented by Chemical Formula 3-4-1b: 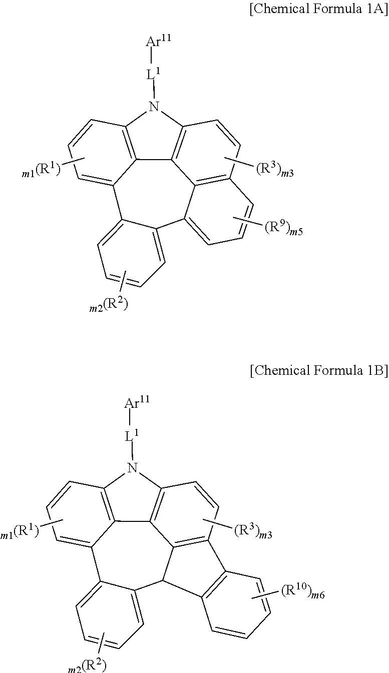
wherein, in Chemical Formula 1A and Chemical Formula 1B,
L¹ is a single bond, a substituted or unsubstituted phenylene group, a substituted or unsubstituted biphenylene group, or a substituted or unsubstituted naphthylenylene group,
Ar¹¹ is a substituted or unsubstituted phenyl group, a substituted or unsubstituted biphenyl group, a substituted or unsubstituted terphenyl group, a substituted or unsubstituted naphthyl group, a substituted or unsubstituted anthracenyl group, a substituted or unsubstituted phenanthrenyl group, a substituted or unsubstituted triphenylene group, a substituted or unsubstituted chrysenyl group, a substituted or unsubstituted fluorenyl group, a substituted or unsubstituted 9,9′-spirobifluorenyl group, a substituted or unsubstituted dibenzofuranyl group, a substituted or unsubstituted dibenzothiophenyl group, or an amine group represented by Chemical Formula a, 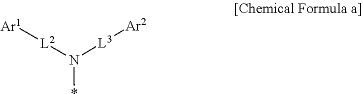
in Chemical Formula a, L² and L³ are each independently a single bond, a substituted or unsubstituted phenylene group, or a substituted or unsubstituted biphenylene group,
in Chemical Formula a, Ar¹ and Ar² are each independently a substituted or unsubstituted phenyl group, a substituted or unsubstituted biphenyl group, a substituted or unsubstituted naphthyl group, a substituted or unsubstituted dibenzofuranyl group, or a substituted or unsubstituted dibenzothiophenyl group,
R¹ to R³ are each independently hydrogen, deuterium, a cyano group, a halogen, a substituted or unsubstituted C1 to C10 alkyl group, or a substituted or unsubstituted C6 to C12 aryl group,
R⁹ and R¹⁰ are each independently hydrogen, deuterium, a cyano group, a halogen, a substituted or unsubstituted amine group, a substituted or unsubstituted C1 to C30 alkyl group, a substituted or unsubstituted C6 to C30 aryl group, or a substituted or unsubstituted C2 to C30 heterocyclic group,
m1 is an integer of 1 to 3,
m2 is an integer of 1 to 4,
m3 is an integer of 1 or 2,
m5 is an integer of 1 to 3, and
m6 is an integer of 1 to 4; 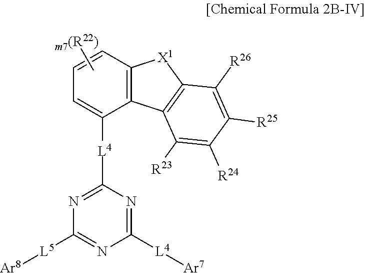
wherein, in Chemical Formula 2B-IV,
L⁴ to L⁶ are each independently a single bond, a substituted or unsubstituted phenylene group, a substituted or unsubstituted biphenylene group, a substituted or unsubstituted naphthylene group, a substituted or unsubstituted dibenzofuranylene group, or a substituted or unsubstituted dibenzothiophenylene group,
X² is O or S,
Ar⁷ and Ar⁸ are each independently a substituted or unsubstituted phenyl group, a substituted or unsubstituted biphenyl group, a substituted or unsubstituted terphenyl group, a substituted or unsubstituted naphthyl group, a substituted or unsubstituted triphenylene group, a substituted or unsubstituted chrysenyl group, a substituted or unsubstituted carbazolyl group, a substituted or unsubstituted dibenzofuranyl group, a substituted or unsubstituted dibenzothiophenyl group, a substituted or unsubstituted naphthobenzofuranyl group, or a substituted or unsubstituted naphthobenzothiophenyl group,
R²² to R²⁶ are each independently hydrogen, deuterium, a substituted or unsubstituted C1 to C10 alkyl group, a substituted or unsubstituted phenyl group, a substituted or unsubstituted dibenzofuranyl group, or a substituted or unsubstituted dibenzothiophenyl group, and
m7 is an integer of 1 to 3; 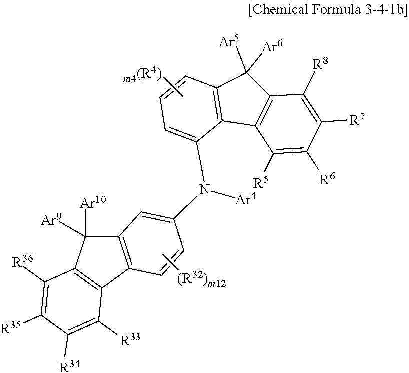
wherein, in Chemical Formula 3-4-1b,
Ar⁴ is a substituted or unsubstituted phenyl group, a substituted or unsubstituted biphenyl group, a substituted or unsubstituted terphenyl group, a substituted or unsubstituted fluorenyl group, a substituted or unsubstituted spirobifluorenyl group, a substituted or unsubstituted triphenylene group, a substituted or unsubstituted dibenzofuranyl group, or a substituted or unsubstituted dibenzothiophenyl group,
Ar⁵ and Ar⁶ are each independently a substituted or unsubstituted C1 to C5 alkyl group or a substituted or unsubstituted C6 to C12 aryl group,
R⁴ to R⁸ are each independently hydrogen, deuterium, or a substituted or unsubstituted tert-butyl group,
Ar⁹ and Ar¹⁰ are each independently a substituted or unsubstituted C1 to C30 alkyl group or a substituted or unsubstituted C6 to C30 aryl group,
R³² to R³⁶ are each independently hydrogen, deuterium, a cyano group, a halogen, a substituted or unsubstituted C1 to C30 alkyl group, a substituted or unsubstituted C6 to C30 aryl group, or a substituted or unsubstituted C2 to C30 heterocyclic group, and
m4 and m12 are each independently an integer of 1 to 3.

11. A display device comprising the organic optoelectronic device as claimed in claim 1.
